(19) United States
(12) Patent Application Publication
(10) Pub. No.: US 2003/0148565 A1
(43) Pub. Date: Aug. 7, 2003

(54) Method for forming thin semiconductor film, method for fabricating semiconductor device, system for executing these methods and electrooptic device

(76) Inventor: Hideo Yamanaka, Kanagawa (JP)

Correspondence Address: SONNENSCHEIN NATH & ROSENTHAL, P.O. BOX 061080, WACKER DRIVE STATION, CHICAGO, IL, 60606-1080, US

(21) Appl. No.: 10/240,439

(22) PCT Filed: Jan. 31, 2002
(86) PCT No.: PCT/JP02/00799

(30) Foreign Application Priority Data
Feb. 1, 2001 (JP) 200124999

(51) Int. Cl. H01L 21/8238

(52) U.S. Cl. 438/200

(57) ABSTRACT

The present invention provides a method capable of easily forming a polycrystalline or monocrystalline semiconductor thin film of polycrystalline silicon with a high degree of crystallization and high quality at low cost, and an apparatus for carrying out the method. In a method of forming a polycrystalline (or monocrystalline) semiconductor thin film, a method of manufacturing a semiconductor device and an apparatus for carrying out these methods, in order to form a large-grain polycrystalline (or monocrystalline) semiconductor thin film (7) such as a polycrystalline silicon film with a high degree of crystallization on a substrate (1) or manufacturing a semiconductor device having the polycrystalline (or monocrystalline) semiconductor thin film (7), a low-crystalline semiconductor thin film (7A) is formed on the substrate (1), and then heated in a molten, semi-molten or non-molten state by laser annealing with ultraviolet rays (UV) or/and deep ultraviolet rays (DUV) and cooled to promote crystallization of the low-crystalline semiconductor thin film (7A), obtaining the polycrystalline (or monocrystalline) semiconductor thin film (7).

### TECHNICAL FIELD

The present invention relates to a method and apparatus for forming a polycrystalline semiconductor thin film of polycrystalline silicon on a substrate by laser annealing or the like, a method and apparatus for manufacturing a semiconductor device having the polycrystalline semiconductor thin film formed on the substrate, and an electrooptic device.

### BACKGROUND ART

In a MOSFET (Metal-Oxide-Semiconductor Field Effect Transistor), for example, a MOSTFT (Thin Film Transistor=thin film gate-type field effect transistor), source, drain and channel regions are conventionally formed by a vapor growth method such as a plasma CVD (CVD: Chemical Vapor Deposition), a low-pressure CVD method, a catalytic CVD method, or the like, a solid growth method, a liquid growth method, an excimer laser annealing method, or the like using a polycrystalline silicon film.

As disclosed in Japanese Unexamined Patent Application Publication No. 7-131030 and 9-116156, and Japanese Examined Patent Application Publication No. 7-118443, an amorphous or microcrystalline silicon film formed by the plasma CVD method, the low-pressure CVD method, or the like is changed to a polycrystalline silicon oxide film by simple high-temperature annealing or excimer laser annealing (ELA) to improve carrier mobility. However, this method has an attainable limit of carrier mobility of about 80 to 120 cm²/V·sec.

However, a MOSTFT using a polycrystalline silicon film obtained by ELA of amorphous silicon formed by the plasma CVD method has an electron mobility of about 100 cm²/V·sec, and can thus comply with higher definition. Therefore, a LCD (Liquid Crystal Display) integrated with driving circuits and comprising a polycrystalline silicon MOSTFT has recently attracted attention (refer to Japanese Unexamined Patent Application Publication No. 6-242433). The excimer laser annealing method is a method in which a sample is irradiated with a short-wavelength and short-pulse laser of an XeCl excimer laser or the like to be melted and crystallized within a short time, and an amorphous silicon film can be made polycrystalline by laser beam irradiation without damage to a glass substrate, thereby expecting a high throughput.

However, in the above-described method of producing a polycrystalline silicon MOSTFT by ELA, the crystallization speed is as high as the n sec order, and thus the diameter of the resultant crystal grains is, at most, about 100 nm. Therefore, even in a method sufficiently removing hydrogen and oxygen, which inhibit crystal growth, by heating the substrate to a temperature of about 400° C. to control the solidification speed, it is difficult to obtain a crystal having a grain diameter of 500 nm or more. Thus, laser irradiation is performed several times, for example, 5 or 30 times or more, to sufficiently apply energy for causing crystal growth, forming a large-grain polycrystalline silicon film. However, there are a lot of the problems of instability of excimer laser output, productivity, an increase in apparatus cost with scaling up, deterioration in yield and quality, etc. Particularly, in a large glass substrate of 1 m×1 m, the problems are made significant to cause further difficulties in improving performance and quality and decreasing the cost.

A method of forming a crystalline silicon film has recently been proposed, in which a catalytic element (Ni, Fe, Co, or the like) for promoting crystallization is diffused in an amorphous silicon film by hating at 450 to 600° C. for 4 to 12 hours, as disclosed in Japanese Unexamined Patent Application Publication No. 11-97353, etc. However, this method causes the catalytic element to remain in the formed crystalline silicon film. Therefore, there have been the proposals of a method of heating in an atmosphere containing a halogen element such as chlorine or the like for removing (gettering) the catalytic element, a method of selectively adding phosphorous to the crystalline silicon film and then heating the film, a method of irradiating the crystalline silicon film containing the catalytic element with a laser beam or strong light to made the catalytic element easy to diffuse, and absorbing the catalytic element by a selectively added element, etc., as disclosed in Japanese Unexamined Patent Application Publication No. 8-339960, etc. However, the process is complicated, the gettering effect is insufficient, and the semiconductor properties of the silicon film deteriorate to deteriorate stability and reliability of an element formed.

Also, the method of producing a polycrystalline silicon MOSTFT by the solid growth method requires annealing at 600° C. or higher for over ten hours and formation of gate SiO₂ by thermal oxidation at about 1000° C., and thus the method must use a semiconductor manufacturing apparatus. Therefore, the limit of the substrate size is a wafer size of 8 to 12 inches φ, and expensive quartz glass having high heat resistance must be used, causing difficulties in decreasing the cost, and limiting application to EVF and a data/AV projector.

In recent years, a catalytic CVD method has been developed as an excellent thermal CVD, in which a polycrystalline silicon film, a silicon nitride film, or the like can be formed on an insulating substrate such as a glass substrate or the like at low temperature (refer to Japanese Examined Patent Application Publication Nos. 63-40314 and 8-250438), and research of practical application of this method has been promoted. In the catalytic CVD method, a carrier mobility of about 30 cm²/V·sec can be obtained without crystallization annealing, but a good MOSTFT device cannot be sufficiently formed. Furthermore, when the polycrystalline silicon film is formed on the glass substrate, a transition layer (thickness of 5 to 10 nm) of initial amorphous silicon is readily formed depending upon the deposition conditions, and desired carrier mobility cannot easily be obtained in a bottom gate MOSTFT. In a LCD using a polycrystalline silicon MOSTFT and integrated with a driving circuit, in general, bottom gate MOSTFTs can easily be produced from the viewpoint of yield and productivity, but the problem of difficulty in obtaining desired carrier mobility is a bottleneck.

An object of the present invention is to provide a method capable of easily forming a polycrystalline or monocrystalline semiconductor thin film of polycrystalline silicon or the like with a high crystallization rate and high quality over a large area at low cost, and an apparatus for carrying out this method.

Another object of the present invention is to provide a method of manufacturing a semiconductor device such as a MOSTFT or the like having a polycrystalline or monocrystalline semiconductor thin film as a component, an apparatus for carrying out the method, and an electrooptic device.

### DISCLOSURE OF INVENTION

The present invention relates to a method of forming a semiconductor thin film or manufacturing a semiconductor device in forming a polycrystalline or monocrystalline semiconductor thin film on a substrate or manufacturing a semiconductor device having a polycrystalline or monocrystalline semiconductor thin film on a substrate, the method comprising the first step of forming a low-crystalline semiconductor thin film on the substrate, and the second step of heating the low-crystalline semiconductor thin film in a molten, semi-molten or non-molten state by laser annealing with ultra-violet rays (abbreviated to “UV” hereinafter) or/and deep ultra-violet rays (abbreviated to “DUV” hereinafter) formed by optical harmonic generation using a non-linear optical effect and cooling the thin film to promote crystallization of the low-crystalline semiconductor thin film.

The present invention also provides an apparatus for forming a polycrystalline semiconductor thin film or an apparatus for manufacturing a semiconductor device as an apparatus for carrying out the method of the present invention, the apparatus comprising first means for forming a low-crystalline semiconductor thin film on the substrate, and second means for heating the low-crystalline semiconductor thin film in a molten state, a semi-molten state or non-molten state by laser annealing with ultraviolet rays (UV) or/and deep ultraviolet rays (DUV) formed by optical harmonic generation using a non-linear optical effect and cooling the thin film to promote crystallization of the low-crystalline semiconductor thin film.

The present invention further provides an electrooptic device comprising a cathode or anode provided below an organic or inorganic electroluminescence layer for each color to be connected to the drain or source of MOSTFT comprising the polycrystalline or monocrystalline semiconductor thin film, wherein the cathode covers active elements including the MOSTFT and a diode, or the common cathode or anode is deposited on the whole surface of the organic or inorganic electroluminescence layer for each color and between the layers of respective colors.

The present invention further provides an electrooptic device comprising a field emission display (FED) having an emitter comprising a n-type polycrystalline semiconductor film or polycrystalline diamond film which is connected to the drain of the MOSTFT comprising the polycrystalline or monocrystalline semiconductor thin film through the polycrystalline or monocrystalline semiconductor thin film, and which is grown on the polycrystalline or monocrystalline semiconductor thin film.

In the present invention, a low-crystalline semiconductor thin film is formed on the substrate, and heated in a molten state, a semi-molten state or non-molten state by annealing with UV or/and DUV laser (referred to as “laser annealing of the present invention” or “the above-described laser annealing” hereinafter) formed by optical harmonic generation using the non-linear optical effect and cooled to promote crystallization of the low-crystalline semiconductor thin film, forming a polycrystalline or monocrystalline semiconductor thin film. Therefore, the following remarked effects (1) to (12) can be obtained.

(1) The low-crystalline semiconductor thin film such as an amorphous silicon film or the like is heated in a molten state, a semi-molten-state or non-molten state by irradiation with a high-output (referred to as “optical harmonic modulated” hereinafter) UV or/and DUV laser beam formed by optical harmonic generation using the non-linear optical effect and cooled to crystallize the thin film. Namely, high irradiation energy is applied to the low-crystalline semiconductor thin film by annealing with the optical harmonic modulated UV or/and DUV laser to heat the semiconductor thin film in a molten, semi-molten or non-molted state and cool the thin film to obtain the polycrystalline silicon or monocrystalline semiconductor thin film having a large grain diameter, high carrier mobility and high quality, thereby significantly improving productivity to permit a significant decrease in cost.

(2) In laser annealing of the present invention, a catalytic element such as Ni or the like after its work of promoting crystallization, which is previously added for promoting crystallization, and other impurity elements are segregated in a high-temperature melting zone by a so-called zone purification method in which the heating zone is moved, and thus these elements can easily be removed. Therefore, the elements do not remain in the film, and thus the polycrystalline semiconductor thin film having a large grain diameter, high carrier mobility and high quality (high purity) can easily be obtained. Furthermore, by a so-called multi-zone purification method comprising continuously repeating a melting zone and a cooling zone by irradiation with a plurality of laser beams, the polycrystalline semiconductor thin film having a larger grain diameter and higher quality (purity) can be obtained. In the high purification method, semiconductor properties do not deteriorate, and thus stability and reliability of an element formed are improved. Also, a simple process such as the zone purification method or multi-zone purification method comprising annealing with an optical harmonic modulated UV or/and DUV laser can efficiently remove the catalytic element after its work of promoting crystallization and other elements to decrease the number of the steps, permitting a decrease in cost.

(3) Since the crystal grains of polycrystalline silicon or the like are oriented in the laser scanning direction, irregularity and stress of the crystal grain boundaries can be decreased when TFT is formed in this direction, and a polycrystalline silicon film or the like having high mobility can be formed.

(4) A low-crystalline silicon film or the like is laminated on a polycrystalline silicon film or the like, which is crystallized by the zone purification method or multi-zone purification method comprising annealing with the optical harmonic modulated UV or/and DUV laser, and laser annealing is again performed to crystallize the low-crystalline silicon film. This method is repeated to permit the lamination of polycrystalline silicon films with a large grain diameter, high carrier mobility and high quality to a thickness of μm unit. This enables the formation of not only MOSLSI but also a bipolar LSI, a CMOS sensor, a CCD area/linear sensor, a solar cell, etc. with high performance and high quality.

(5) The wavelength, irradiation strength and irradiation time, etc. of the optical harmonic modulated UV or/DUV laser can easily be controlled, and the optical harmonic modulated UV or/DUV laser can be converged and shaped in a linear, rectangular or square shape to freely set the laser beam diameter, the laser scanning pitch, etc., thereby permitting an attempt to improve the irradiation strength, i.e., melting efficiency, and throughput, and decreasing cost. Furthermore, by a heating and cooling method comprising (1) scanning a fixed substrate with a laser beam by galvanometer scanning, or (2) moving the substrate relative to a fixed laser beam in a step and repeat manner using a high-precision stepping motor, and a method of synchronously scanning the substrate with a plurality of lasers, a large area (for example, 1 m×1 m) can be annealed within a short time. Therefore, a polycrystalline silicon film or the like having any desired crystal grains and purity can be obtained over a large area, thereby improving productivity and decreasing the cost.

(6) The UV or/and DUV laser formed by harmonic generation using a non-linear optical crystal is obtained by using a high-output semiconductor laser excited YAG (Nd:YAG; neodymium-added yttrium aluminum garnet) laser as a fundamental wave, and thus has safety and ease of maintenance. Therefore, an inexpensive small laser device producing stable high output with low power consumption is realized.

(7) Any desired light at a wavelength of 200 to 400 nm, at which for example, an amorphous silicon film exhibits high absorption efficiency, can be selected for optical harmonic modulated UV or/and DUV laser annealing, and thus high-output single-wavelength laser beam annealing can be performed, thereby decreasing variation in the energy distribution on the irradiation surface, variation in the obtained crystallized semiconductor film, and variation in the element properties of each TFT. Therefore, the cost can be decreased with high throughput and high productivity.

(8) The wavelength and irradiation strength of the optical harmonic modulated UV or/and DUV used in the present invention can be controlled by appropriately selecting the fundamental wave and the non-linear optical crystal, and a combination thereof. For example, a wavelength of 200 to 400 nm at which an amorphous silicon film exhibits high absorption efficiency is arbitrarily selected to enable irradiation with a high-output-single-wavelength laser beam.

(9) Furthermore, the irradiation laser beam can be freely converged and shaped in a linear, rectangular or square shape for laser beam irradiation to decrease variation in the energy distribution of the irradiation plane, variation in the obtained crystallized semiconductor film, and variation in the element properties of each TFT, thereby realizing a decrease in cost with high throughput and high productivity.

(10) For example, when the low-crystalline semiconductor thin film is crystallized by heating with a UV laser beam at a first harmonic generation wavelength of 355 nm and cooling, an infrared laser beam having a fundamental wave at a wavelength of 1064 nm, or a visible laser beam at a second harmonic wavelength of 532 nm, or a mixed laser beam containing the infrared laser beam and the visible laser beam can be simultaneously applied to heat the low-crystalline semiconductor thin film and the glass substrate, thereby sufficiently heating the thin film and the substrate. Therefore, slow cooling can be promoted to easily secure crystallization. Also, the fundamental wave and the second harmonic can be efficiently used without being discarded to decrease power consumption as a whole.

(11) Annealing with the optical harmonic modulated UV or/DUV laser can be performed at a low temperature (200 to 400° C.), and thus low-strain-point glass and a high resistant resin can be used to permit an attempt to decrease the weight and cost.

(12) In bottom gate and dual gate type MOSTFTs as well as a top gate type MOSTFT, a polycrystalline or monocrystalline semiconductor film having high carrier mobility can be obtained, permitting the manufacture of a semiconductor device and an electrooptic device having a high speed and high current density, and the manufacture of a solar cell with high efficiency. For example, a silicon semiconductor device, a silicon semiconductor integrated circuit device, a field emission display (FED) device, a silicon-germanium semiconductor device, a silicon-germanium semiconductor integrated circuit device, a liquid crystal display device, an electroluminescence (organic/inorganic) display device, a luminescent polymer display device, a light emitting diode display device, an optical sensor device, a CCD area/linear sensor device, a CMOS sensor device, a solar cell device, etc. can be manufactured.

In the present invention, the low-crystalline semiconductor thin film mainly has an amorphous-based structure containing microcrystal (generally, grain size of 10 nm or less), and the polycrystalline semiconductor thin film mainly has a polycrystal-based structure having a large grain diameter (generally, grain size of several hundreds nm or more) and containing microcrystal, from which an amorphous component is removed, as defined as described below. The monocrystalline semiconductor film is an idea including monocrystalline semiconductors such as single crystal silicon and the like, as well as single crystal compound semiconductors (for example, single crystal gallium arsenic) and single crystal silicon-germanium, and monocrystallinity is defined as an idea including a single crystal containing sub-boundaries and transition. The polycrystalline diamond film is defined as crystallline diamond containing microcrystalline diamond and polycrystalline diamond, with substantially no amorphous diamond.

### BRIEF DESCRIPTION OF THE DRAWINGS

FIG. 1 is a sectional view showing in turn the steps of a process for manufacturing MOSTFTs according to a first embodiment of the present invention.

FIG. 2 a sectional view showing in turn the steps of the manufacturing process of the first embodiment.

FIG. 3 a sectional view showing in turn the steps of the manufacturing process of the first embodiment.

FIG. 4 a sectional view showing in turn the steps of the manufacturing process of the first embodiment.

FIG. 5 is a schematic sectional view showing a state of a catalytic CVD apparatus used for the manufacturing process of the first embodiment.

FIG. 6 is a schematic sectional view of another state of the same apparatus.

FIG. 7 is a schematic sectional view and a plan view of a principal portion of a laser annealing apparatus used for the manufacturing process.

FIG. 8 is a schematic sectional view and a plan view of a principal portion of a laser annealing apparatus used for the manufacturing process.

FIG. 9 is a schematic sectional view of a principal portion of another example of a laser annealing apparatus used for the manufacturing process.

FIG. 10 is a schematic sectional view of a principal portion of a further example of a laser annealing apparatus used for the manufacturing process.

FIG. 11 is a schematic view showing methods of generating various laser beams for laser annealing.

FIG. 12 is a schematic view of a cluster-system MOSTFT manufacturing apparatus.

FIG. 13 is a schematic view of an inline-system MOSTFT manufacturing apparatus.

FIG. 14 is a schematic view of another example of the cluster-system MOSTFT manufacturing apparatus.

FIG. 15 is a schematic sectional view showing another state of laser annealing.

FIG. 16 is a schematic sectional view showing another example of the laser annealing apparatus.

FIG. 17 is a schematic sectional view showing a further example of the laser annealing apparatus.

FIG. 18 is a schematic sectional view showing a further example of the laser annealing apparatus.

FIG. 19 is a sectional view showing in turn the steps of a process for manufacturing LCD according to a second embodiment of the present invention.

FIG. 20 is a sectional view showing in turn the steps of the manufacturing process of the second embodiment.

FIG. 21 is a sectional view showing in turn the steps of the manufacturing process of the second embodiment.

FIG. 22 is a perspective view showing the schematic layout of the entirety of the LVD.

FIG. 23 is a drawing showing equivalent circuits of the LCD.

FIG. 24 is a sectional view showing in turn the steps of another process for manufacturing LCD.

FIG. 25 is a sectional view showing in turn the steps of the manufacturing process.

FIG. 26 is a sectional view showing various MOSTFTs of the LCD.

FIG. 27 is a sectional view showing in turn the steps of a further process for manufacturing LCD.

FIG. 28 is a schematic view illustrating graphoepitaxial growth.

FIG. 29 is a schematic sectional view showing various step shapes.

FIG. 30 is a sectional view showing in turn the steps of a further process for manufacturing LCD.

FIG. 31(A) is a drawing of equivalent circuits of a principal portion of an organic EL display device according to a third embodiment of the present invention, (B) is an enlarged sectional view of the principal portion, and (C) is a sectional view of the peripheral portion of pixels.

FIG. 32 is a sectional view showing in turn the steps of a process for manufacturing the organic EL display device.

FIG. 33(A) is a drawing of equivalent circuits of a principal portion of another organic EL display device, (B) is an enlarged sectional view of the principal portion, and (C) is a sectional view of the peripheral portion of pixels.

FIG. 34 is a sectional view showing in turn the steps of a process for manufacturing the organic EL display device.

FIG. 35(A) is a drawing of equivalent circuits of a principal portion of a FED according to a fourth embodiment of the present invention, (B) is an enlarged sectional view of the principal portion, and (C) is a schematic sectional view of the principal portion.

FIG. 36 is a sectional view showing in turn the steps of a process for manufacturing the FED.

FIG. 37 is a sectional view showing in turn the steps of the process for manufacturing the FED.

FIG. 38(A) is a drawing of equivalent circuits of a principal portion of another FED, (B) is an enlarged sectional view of the principal portion, and (C) is a schematic sectional view of the principal portion.

FIG. 39 is a sectional view showing in turn the steps of the process for manufacturing the FED.

FIG. 40 is a sectional view showing in turn the steps of the process for manufacturing the FED.

FIG. 41 is a sectional view showing in turn the steps of a process for manufacturing a solar cell according to a fifth embodiment of the present invention.

### BEST MODE FOR CARRYING OUT THE INVENTION

In the present invention, as described above, a ultra-violet (UV) or/and deep ultra-violet (DUV) laser beam formed by optical harmonic generation using the nonlinear optical effect can be used for laser annealing of the present invention. In this case, the laser beam formed by optical harmonic generation is preferably mixed with a fundamental wave before optical harmonic generation.

Also, laser annealing is preferably performed by a zone purification method in which the substrate is irradiated with the laser beam by scanning relative to the substrate, or a multi-zone purification method in which the substrate is successively scanned with a plurality of laser beams relative to the substrate. For example, the laser or the substrate can be moved while the position of the substrate or the laser is fixed.

When the substrate is irradiated with a long-wavelength component of the laser beam before a short-wavelength component or at a position in front of the irradiation position of the short-wavelength component, the low-crystalline semiconductor thin film or the substrate can be pre-heated to decrease variation in crystallization and cause an advantage in promoting crystallization by a slow cooling effect.

In the present invention, the low-crystalline semiconductor thin film may be formed by catalytic CVD, plasma CVD, low-pressure CVD, sputtering, or the like. Examples of raw material gases used for vapor phase growth include silicon hydride or its derivative, a mixture of silicon hydride or its derivative and a gas containing hydrogen, nitrogen, germanium, carbon or tin, a mixture of silicon hydride or its derivative and a gas containing an impurity composed of a III group or V group element of the periodic table, a mixture of silicon hydride or its derivative, a gas containing hydrogen, nitrogen, germanium, carbon or tin, and a gas containing an impurity composed of a III group or V group element of the periodic table, and the like.

For example, at least parts of a hydrogen-based carrier gas and raw material gas are brought into contact with a catalyzer heated to 800 to 2000° C. (less than the melting point), and deposition species such as radicals, ions, etc. produced by catalytic reaction or thermal decomposition reaction are deposited on the substrate heated to 200 to 400° C. to form the low-crystalline semiconductor thin film. Alternatively, the low-crystalline semiconductor thin film is formed on the substrate heated to 200 to 400° C. by deposition by general-purpose plasma CVD, low-pressure CVD or sputtering method, or the like.

In this way, it is possible to form the low-crystalline semiconductor film comprising an amorphous silicon film, a microcrystal silicon-containing amorphous silicon film, a microcrystal silicon (amorphous silicon-containing microcrystal silicon) film, a polycrystalline silicon film containing amorphous silicon and microcrystal silicon, an amorphous germanium film, a microcrystal germanium-containing amorphous germanium film, a microcrystal germanium (amorphous germanium-containing microcrystal germanium) film, a polycrystalline germanium film containing amorphous germanium and microcrystal germanium, an amorphous silicon germanium film represented by SiₓGe₁₋ₓ (0<x<1), an amorphous carbon film, a microcrystal carbon-containing amorphous carbon film, a microcrystal carbon (amorphous carbon-containing microcrystal carbon) film, a polycrystalline carbon film containing amorphous carbon and microcrystal carbon, an amorphous silicon carbon film represented by SiₓC₁₋ₓ (0<x<1), or an amorphous gallium arsenic film represented by GaₓAs₁₋ₓ (0<x<1). The low-crystalline semiconductor thin film contains an amorphous material as a base, and if it contains a microcrystal, the microcrystal having a grain diameter of 10 nm or less is preferably scattered.

When an appropriate amount (total, for example, of 10¹⁷ to 10²⁰ atoms/cc) of at least one catalytic element (Ni, Fe, Co, Ru, Rh, Pd, Os, Ir, Pt, Cu, Au, Ge, Pb, or Sn) is contained in the low-crystalline semiconductor thin film during growth or after growth, and laser annealing is performed in this state containing the catalytic element, crystallization of the low-crystalline semiconductor thin film is promoted, and irregularities present in the crystal grain boundaries of the polycrystalline semiconductor are decreased to decrease film stress, thereby easily obtaining the polycrystalline semiconductor thin film having high carrier mobility and high quality. The catalytic element can be contained as a gas component in the raw material gas, or contained in the low-crystalline semiconductor thin film by ion implantation or ion doping. At this time, the catalytic element after its work of promoting crystallization and other impurity elements can be taken into (segregated) the high-temperature silicon melting zone, semi-melting zone or non-melting zone at the scanning end to form the high-purity polycrystalline semiconductor film containing impurity elements decreased to, for example, 10¹⁵ atoms/cc or less. In this case, crystallization and gettering of the catalytic element and other impurity elements may be further promoted by a so-called multi-zone purification method in which a silicon melting zone and cooling zone are continuously repeated by irradiation with a plurality of laser beams, obtaining higher purity.

The concentration of each of oxygen, nitrogen and carbon of the large-grain polycrystalline or monocrystalline semiconductor film formed in the present invention is 1×10¹⁹ atoms/cc or less, preferably 5×10¹⁸ atoms/cc or less, and the hydrogen content is preferably 0.01 atomic % or more.

In the present invention, the low-crystalline semiconductor thin film of low-crystalline silicon or the like is modified to the polycrystalline semiconductor thin film of large-grain polycrystalline silicon or the like by laser annealing. However, besides this method, the low-crystalline silicon thin film can be modified to the monocrystalline silicon thin film by a method in which a stepped recess having a predetermined shape and dimensions is formed in a region of the substrate, in which a predetermined element is to be formed, and the low-crystalline silicon thin film containing or not containing at least one catalytic element is formed on the substrate including the recess, and then subjected to graphoepitaxial growth by laser annealing of the present invention using the bottom corners of the step of the recess as seeds.

Alternatively, the low-crystalline silicon thin film can be modified to the monocrystalline silicon thin film by a method in which a material layer of crystalline sapphire having good lattice matching with monocrystal silicon is formed in a predetermined region of the substrate, in which an element is to be formed, and the low-crystalline silicon thin film containing or not containing at least one catalytic element is formed on the material layer, and then subjected to hetero epitaxial growth by laser annealing of the present invention using the material layer as a seed.

The laser annealing of the present invention and deposition of the low-crystalline semiconductor thin film may be repeated to laminate films, forming a polycrystalline or monocrystalline semiconductor thick film of μm unit. Namely, the large-grain polycrystalline or monocrystalline semiconductor thin film is formed by first laser annealing of the present invention, and the low-crystalline semiconductor thin film is laminated on the polycrystalline or monocrystalline semiconductor thin film, and then subjected to second laser annealing of the present invention using the underlying large-grain polycrystalline or monocrystalline semiconductor thin film as a seed to laminate a large-grain polycrystalline or monocrystalline film. This step is repeated a necessary number of times to form the large-grain polycrystalline or monocrystalline film having a thickness of μm unit. During lamination, underlying large-grain polycrystalline or monocrystalline films are successively laminated, and thus the crystallization rate and purity of the large-grain polycrystalline or monocrystalline semiconductor film increase nearer to the film surface. In this case, it is important to avoid a low-oxidation film from being formed on the crystallized film surface and contaminants (impurities) from adhering to the surface after each time of laser annealing of the present invention.

In order to prevent the formation of a low-oxidation film and contaminants, and improve productivity, an apparatus preferably comprises the step or means (plasma CVDF, catalytic CVD, sputtering, or the like) for forming the low-crystalline semiconductor thin film, and the laser annealing step or annealer integrated with the above step or means. For example, an inline (continuous chamber) system (linear type or rotational type), a multi-chamber system, a cluster system, or the like is preferably used for continuous or successive processing.

Of these systems, the following cluster system (1) or (2) is more preferred.

(1) A cluster-system integrated apparatus in which the steps of forming a low-crystalline semiconductor thin film in a CVD section, crystallizing the thin film by laser annealing of the present invention in an annealer section, returning the thin film to the CVD section to form a low-crystalline semiconductor thin film on the crystallized film, and again crystallizing the thin film by laser annealing of the present invention in the annealer section are repeated.

(2) A cluster-system integrated apparatus in which the works of forming an underlying protective film (a silicon oxide/silicon nitride laminated film, or the like) in a CVD-1 section, forming a low-crystalline semiconductor thin film in a CVD-2 section, adding a catalytic element in an ion doping/ion implantation section, crystallizing the thin film by laser annealing of the present invention in an annealer section, and further forming a gate insulating film (silicon oxide film, or the like) in a CVD-3 section are continuously performed.

At this time, before laser annealing of the present invention, the low-crystalline semiconductor thin film is preferably treated by plasma discharge with hydrogen or hydrogen-containing gas or treated with hydrogen active species produced by catalytic reaction (i.e., treated with plasma or catalytic AHA (Atomic Hydrogen Anneal)) to clean the surface of the polycrystalline semiconductor thin film and/or remove the low-oxidation film, and then the low-crystalline semiconductor thin film is formed and then subjected to laser annealing. In this case (or other cases), particularly, laser annealing of the present invention is preferably performed in low-pressure hydrogen, low-pressure hydrogen-containing gas, or vacuum.

More specifically, the following condition (1) or (2) is preferred.

(1) Before deposition by CVD, the polycrystalline silicon film formed by first laser annealing of the present invention is treated by plasma AHA only with a hydrogen-based carrier gas without a flow of a raw material gas to clean the interface by removing contaminants (low-oxidation film, moisture, oxygen, nitrogen, carbon dioxide gas, etc.) from the surface, and to etch the remaining amorphous silicon component, thereby forming a polycrystalline silicon film with high crystallization rate. Therefore, the low-crystalline silicon film laminated on the clean interface is laminated as a large-grain polycrystalline or monocrystalline semiconductor film composed of good crystal by laser annealing of the present invention using the underlying film as a seed.

(2) In order to prevent oxidation and nitriding, laser annealing of the present invention is performed in a low-pressure hydrogen or low-pressure hydrogen-based gas atmosphere or vacuum. As this atmosphere, hydrogen or a mixed gas of hydrogen and an inert gas (argon, helium, krypton, xenon, neon, or radon) is used, and the gas pressure is 1.33 Pa to the atmospheric pressure, and preferably 133 Pa to 4×10⁴ Pa. The degree of vacuum is 1.33 Pa to the atmospheric pressure, preferably 13.3 Pa to 1.33×10⁴ Pa. However, when an insulating protective film (silicon oxide film, silicon nitride film, or silicon oxynitride or silicon oxide/silicon nitride laminated film, or the like) is formed on the surface of the low-crystalline semiconductor thin film, or when a continuous work is not carried out, laser annealing may be performed in the air or atmospheric-pressure nitrogen.

In laser annealing of the present invention performed in low-pressure hydrogen or low-pressure hydrogen-containing gas, the gas molecules constituting the atmospheric gas and having a high specific heat capacity and a large thermal cooling effect collide with the surface of the thin film, and absorb heat from the thin film when separating from the thin film to locally form a low-temperature portion, thereby producing crystal nuclei in this portion and promoting crystal growth. In this case, if the atmospheric gas is a hydrogen gas or a mixed gas of hydrogen and an inert gas (He, Ne, Ar, or the like), the gas pressure is 1.33 Pa to the atmospheric pressure, and preferably 133 Pa to 4×10⁴ Pa because the above function and effect can be securely obtained by movement of hydrogen molecules having a high specific heat capacity.

Optical harmonic modulated UV/DUV laser annealing is preferably performed as follows:

(1) The low-crystalline semiconductor thin film is crystallized by heating in a molten state, semi-molten state or non-molten state with a UV laser beam at a third harmonic generation wavelength of 335 nm and cooling.

(2) At the same time, the low-crystalline semiconductor thin film and the glass substrate are heated by irradiation with an infrared laser beam at a fundamental wavelength of 1064 nm, a visible laser beam at a second harmonic wavelength of 532 nm, or a mixed laser beam of the infrared laser beam and the visible laser beam.

(3) At the same time, the low-crystalline semiconductor thin film and the whole of the glass substrate are heated by a resistance heater, an infrared lamp, or the like.

(4) At the same time, the low-crystalline semiconductor thin film and the glass substrate are heated by irradiation with an infrared laser beam at a fundamental wavelength of 1064 nm, a visible laser beam at a second harmonic wavelength of 532 nm, or a mixed laser beam of the infrared laser beam and the visible laser beam, and a resistance heater, an infrared lamp, or the like.

Namely, any one of the following methods is performed.

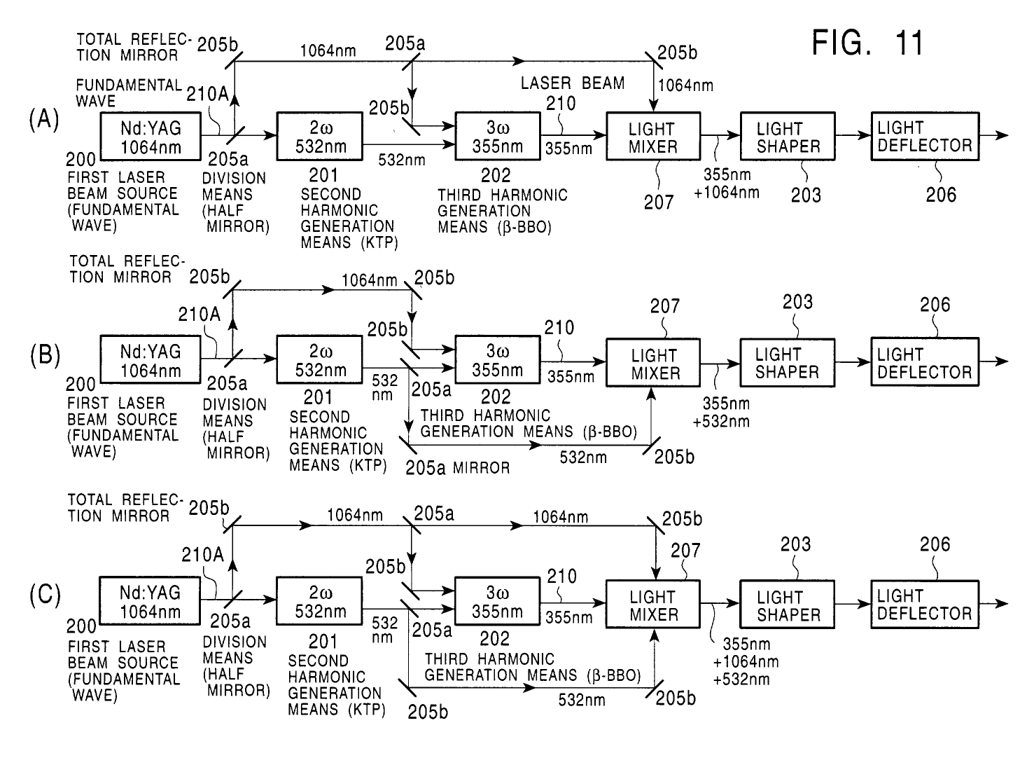

(1) Simultaneous irradiation with a third harmonic UV laser beam (wavelength 355 nm) and an infrared laser beam at a fundamental wavelength of 1064 nm (FIG. 11(A))

(2) Simultaneous irradiation with a third harmonic UV laser beam (wavelength 355 nm) and a second harmonic visible laser beam (wavelength 532 nm) (FIG. 11(B))

(3) Simultaneous irradiation with a third harmonic UV laser beam (wavelength 355 nm), an infrared laser beam at a fundamental wavelength of 1064 nm, and a second harmonic visible laser beam (wavelength 532 nm) (FIG. 11(C))

At this time, in order to efficiently heat and melt the low-crystalline semiconductor thin film and heat the substrate, the following conditions are preferred.

1. A region of fundamental wave or/and second harmonic laser beam irradiation is larger than a region of third harmonic UV laser beam irradiation, and includes the region of third harmonic UV laser beam irradiation.

2. Irradiation with the fundamental wave or/and second harmonic UV laser beam is performed before at least irradiation with the third harmonic UV laser beam.

3. Irradiation with the fundamental wave or/and second harmonic UV laser beam is performed at a position in front of an irradiation position with the third harmonic UV laser beam in the movement direction.

4. The irradiation time of the third harmonic UV laser beam is within the irradiation time of the fundamental wave or/and the second harmonic laser beam, and the irradiation time of the fundamental wave or/and the second harmonic laser beam is ½ or less of the irradiation period.

Namely, local heating with the third harmonic UV laser beam is preferably combined with heating of the whole substrate with the fundamental wave or/and the second harmonic laser beam or/and heating of the whole substrate with the resistance heater, the infrared lamp, or the like.

In conventional excimer laser annealing, in order to remove about 10 to 30% of hydrogen contained in an amorphous silicon film formed by plasma CVD, (1) heating at 400° C. for 1 hour or more, (2) heating with irradiation energy lower than irradiation energy for melting, or (3) a combination of (1) and (2) is performed. If such dehydrogenation is not effected, hydrogen expands and explodes during melting to produce cracks in the film. After such pre-treatment, crystallization is effected by laser beam irradiation with melting energy to deteriorate the efficiency and fail to improve the quality of the obtained semiconductor thin film.

On the other hand, in laser annealing of the present invention, for example, the low-crystalline semiconductor thin film is crystallized by irradiation with melting energy immediately after the region in front of the melting region is dehydrogenated by pre-heating by fundamental wave (infrared rays or visible light rays) irradiation in synchronism with the optical harmonic modulated UV/DUV laser for melting the low-crystalline semiconductor thin film, thereby improving the efficiency of dehydrogenation and decreasing the heating temperature of the whole substrate. Therefore, productivity and quality of the formed polycrystalline semiconductor thin film are improved.

During optical harmonic modulated UV/DUV laser annealing, a hot gas is preferably blown on the substrate. Namely, in order to make the substrate temperature uniform, stabilize the substrate temperature, decrease the stress of the film and the substrate, and promote low cooling, for example, the air or an inert gas (nitrogen gas or the like) of 100 to 400° C. is preferably blown on the back of the substrate. Alternatively, the substrate may be heated to a temperature lower than its strain point by a resistance heater, an infrared lamp, a laser beam, or the like. For example, a glass substrate is heated to 200 to 500° C., preferably 300 to 400° C., and a quartz substrate is heated to 200 to 800° C., preferably 300 to 600° C., depending upon the material of the substrate.

Methods of optical harmonic modulated UV or/and DUV laser annealing include the following:

(1) The substrate is fixed and irradiated with the laser beam converged and shaped in, for example, a line of 300 mm×0.3 mm, while the laser beam is moved with a predetermined amount of overlap. Namely, irradiation annealing is performed by scanning with a so-called galvanometer scanner.

(2) The substrate is irradiated and annealed with the fixed laser beam converged and shaped in, for example, a line of 300 mm×0.3 mm, while being moved with a predetermined amount of overlap in a step and repeat manner with high precision.

Methods of generating a UV laser at a wavelength of 355 nm include the following:

Method of U.S. patent application Ser. No. 5253102:

A laser beam at a wavelength of secondary harmonic generation (SHG) of 532 nm is generated by sun frequency generation (SFG) from Nd:YAG (wavelength 1064 nm) using a first nonlinear optical crystal, and an ultraviolet laser output of 355 nm is obtained by sun frequency generation from the laser beam at 532 nm and the Nd:YAG fundamental wave (wavelength 1064 nm) using a second nonlinear optical crystal.

Method of Japanese Patent No. 3057252:

A laser beam produced by a flash lamp excitation system or laser diode excitation system mode-locked Nd:YAG (wavelength 1064 nm) laser oscillator is input to a first nonlinear optical crystal comprising, for example, KTP (potassium titanophosphate: KTiOPO₄) to produce a second harmonic at an angular frequency 2ω and a fundamental wave at an angular frequency ω. The polarization plane of the second harmonic is rotated by 90° by a ½ wavelength plate to mix the second harmonic and the fundamental wave, and thus the mixed wave is input to a second nonlinear optical crystal comprising, for example, BBO (β-BaB₂O₄: barium borate) to produce a third harmonic at an angular frequency 3ω by sun frequency generation. The third harmonic has a wavelength of λ/3=355 nm.

As the nonlinear optical crystal, any of LBO (LiB₃O₅: lithium borate), BBO (β-BaB₂O₄: barium borate), KDP (potassium dihydrogen phosphate), and KTP (potassium titanophosphate: KTiOPO₄) can be used.

With respect to the specifications of the optical harmonic modulated UV laser obtained by the nonlinear optical crystal, even if the wavelength of the UV laser is determined, the level of crystallization by UV laser irradiation and carrier mobility depend upon the thickness and material of the low-crystalline semiconductor film, the substrate temperature, the scanning speed, etc. An example of the specifications is given below.

Example) UV laser wavelength: 355 nm

UV laser average output: 20 W

Laser beam size: 200×1 mm

Repetition frequency: 20 kHz (pulsed)

An apparatus for annealing with the optical harmonic modulated UV/DUV laser obtained by the nonlinear optical crystal may be a known apparatus, and known technique may be used for other systems such as a line beam homogenizer optical system (waveform forming), a laser annealer operation process, a transfer, a load/unload multi-chamber system, a measurement system, a control system, etc.

Preferably, an insulating protective film, for example, such as a silicon oxide film, a silicon nitride film, a silicon oxynitride film, a silicon oxide/silicon nitride laminated film or the like is formed in an appropriate thickness on the low-crystalline semiconductor thin film, and then laser annealing is performed in this state.

For example, in laser annealing of the low-crystalline semiconductor thin film formed on the substrate or coated with the protective insulating film according to the present invention, laser beam irradiation is preferably performed from the upper surface or the lower surface, or both the upper and lower surfaces at the same time (the substrate is transparent (transmitting light at a wavelength of 400 nm or less) except in the case of irradiation from the upper surface).

In this case, it is preferable that the low-crystalline semiconductor thin film or the low-crystalline semiconductor thin film coated with the protective insulating film is islanded, and laser beam irradiation is performed in atmospheric-pressure nitrogen or the air, or in a low-pressure hydrogen gas, a low-pressure hydrogen-containing gas, or a vacuum (this applies to laser beam irradiation under other conditions).

In order to decrease a temperature rise of the substrate, decrease film stress, prevent the occurrence of cracks in the film due to momentary expansion of the contained gas (hydrogen or the like), and increase the grain diameter due to slow cooling, the low-crystalline semiconductor thin film or the low-crystalline semiconductor thin film coated with the insulating protective film is preferably islanded by patterning, and then subjected to laser annealing.

Laser annealing is preferably performed under the action of a magnetic field and/or an electric field.

In laser annealing of the present invention, when the substrate is heated to a temperature lower than its strain point, preferably 300 to 400° C., it is possible to dehydrogenate the low-crystalline semiconductor thin film, homogenize crystallinity, decrease the stress of the film and the substrate, improve the efficiency of irradiation energy, improve the throughput, etc.

The polycrystalline or monocrystalline semiconductor thin film obtained by laser annealing of the present invention can be used for forming channel, source and drain regions of a MOSTFT, a diode, wiring, a resistor, capacitor, or an electron emitter. In this case, after the channel, source and drain regions, the diode, the resistor, the capacitor, the wiring, or the electron emitter is formed, laser annealing of the present invention is performed to crystallize the film and active n-type or p-type impurities in the film. Also, when laser annealing of the present invention is performed after patterning (islanding) of the above regions, it is possible to prevent damage (cracking, breaking, etc.) to the substrate due to a temperature rise, and prevent cracking of the film due to a rapid temperature rise.

The present invention is preferred for forming thin films of a silicon semiconductor device, a silicon semiconductor integrated circuit device, a silicon-germanium semiconductor device, a silicon-germanium semiconductor integrated circuit device, a compound semiconductor device, a compound semiconductor integrated circuit device, a silicon carbide semiconductor device, a silicon carbide semiconductor integrated circuit device, a polycrystalline diamond semiconductor device, a polycrystalline diamond semiconductor integrated circuit device, a liquid crystal display device, an organic or inorganic electroluminescence (EL) display device, a filed emission display (FED) device, a luminescence polymer display device, a light emitting diode display device, a CCD area/linear sensor device, a CMOS or MOS sensor device, and a solar cell device.

For example, a top gate type, bottom gate type or dual gate type MOSTFT is formed by using the thin film, and a liquid crystal display device, an organic EL display device and FED display device, in which a peripheral driving circuit, a video signal processing circuit, etc. are incorporated, can be obtained by using the MOSTFT.

In this case, in manufacturing a semiconductor device, an electrooptic display device, a solid-state image device, etc. each comprising an internal and peripheral circuit, the channel, source and drain regions of the MOSTFT constituting at least one of the circuits may be formed by using the polycrystalline or monocrystalline semiconductor thin film, the device may be formed in a structure into which a peripheral driving circuit, a video signal processing circuit, a memory, etc. are incorporated.

Also, an EL element may be formed in a structure in which a cathode or anode is formed below an organic or inorganic electroluminescence layer (EL layer) for each color to be connected to the drain or source of the MOSTFT.

In this case, when active elements such as the MOSTFT and a diode are coated with the cathode, the emission area in a structure comprising the anode formed in an upper portion can be increased, and the light shielding function of the cathode can prevent the occurrence of a leakage current due to incidence of emitted light on the active elements. Also, when the cathode or anode is provided over the entire surface of the organic or inorganic EL layer for each color and between the layers for respective colors, the entire surface is covered with the cathode or anode to prevent deterioration in the organic EL layer weak against moisture, and oxidation of electrodes, achieving a long life, high quality and high reliability. Also, coating with the cathode increases a heat radiation effect to decrease a structural change (melting or recrystallization) of the organic EL thin film due to the generated heat, thereby achieving high precision, long life, high quality and high reliability. Furthermore, a full-color organic EL layer with high precision and high quality can be formed with high productivity to decrease the cost.

Furthermore, when a black mask layer of chromium, chromium dioxide, or the like is formed between the organic or inorganic EL layers for respective colors, light leakage between the respective colors or pixels can be prevented to improve contrast.

When the present invention is applied to a field emission display (FED) device, preferably, an emitter (field emission cathode) is formed by using a n-type polycrystalline semiconductor film or polycrystalline diamond film connected to the MOSTFT through the polycrystalline or monocrystalline semiconductor thin film, and grown on the polycrystalline semiconductor thin film.

In this case, a metal shielding film (preferably formed in the same step using the same material as a gate leading electrode of the FED in order to simplify the process) at a grounding potential is formed on the active elements such as the MOSTFT and a diode through an insulating film. This can prevent the phenomenon that a gas contained in an airtight container is positively ionized by electrons emitted from the emitter and charged-up on the insulating layer to form an inversion layer unnecessary to the active elements below the insulating layer due to the positive charge, and an excessive current flows through the inversion layer to cause a runaway of an emitter current. It is also possible to prevent the phenomenon that when a fluorescent material emits light due to collision of the electrons emitted from the emitter, the emitted light produces electrons and holes in the gate channel of the MOSTFT, causing a leakage current.

The present invention will be described in further detail below with reference to preferred embodiments.

### First Embodiment

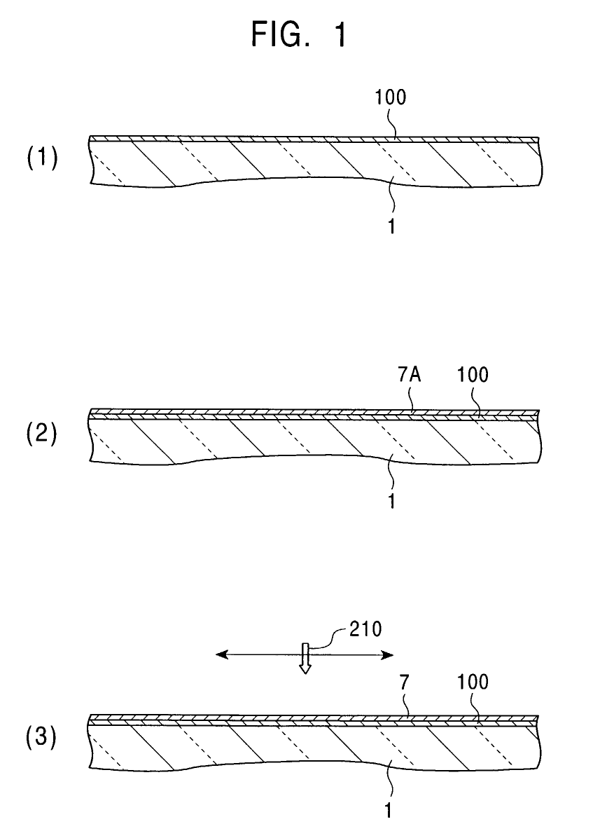

A first embodiment of the present invention is described with reference to FIGS. 1 to 16.

In this embodiment, the present invention is applied to a top gate-type polycrystalline silicon CMOS (Complementary MOS) TFT.

<Method and Apparatus for Catalytic CVD>

The catalytic CVD method used in this embodiment is first described. In the catalytic CVD method, a reaction gas comprising a hydrogen-based carrier gas and a raw material gas such as a silane gas or the like is put into contact with a heated catalyzer of tungsten or the like to supply high energy to the produced deposition species such as radicals, or precursors thereof, or hydrogen-based active species such as active hydrogen ions, thereby causing vapor phase growth of a low-crystalline semiconductor thin film of amorphous silicon-containing microcrystal silicon or the like on a substrate.

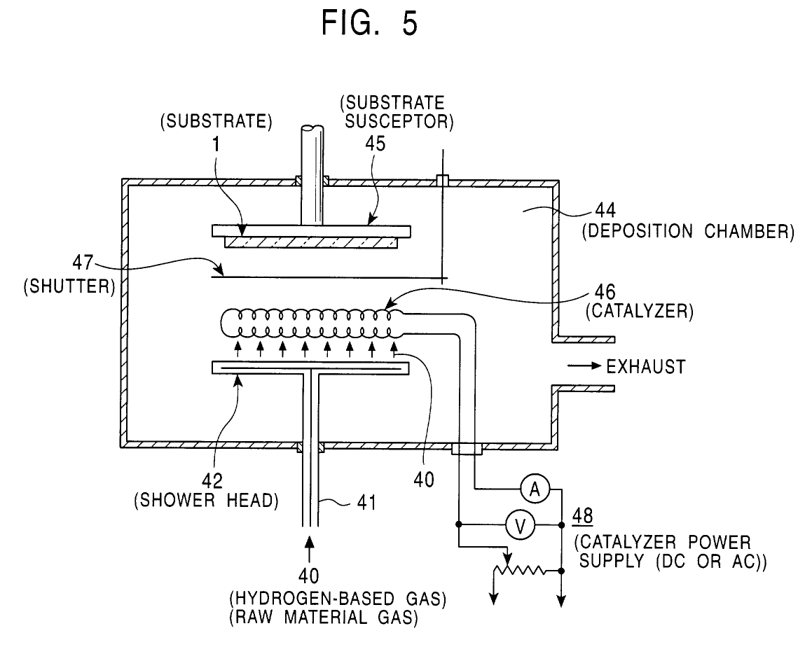

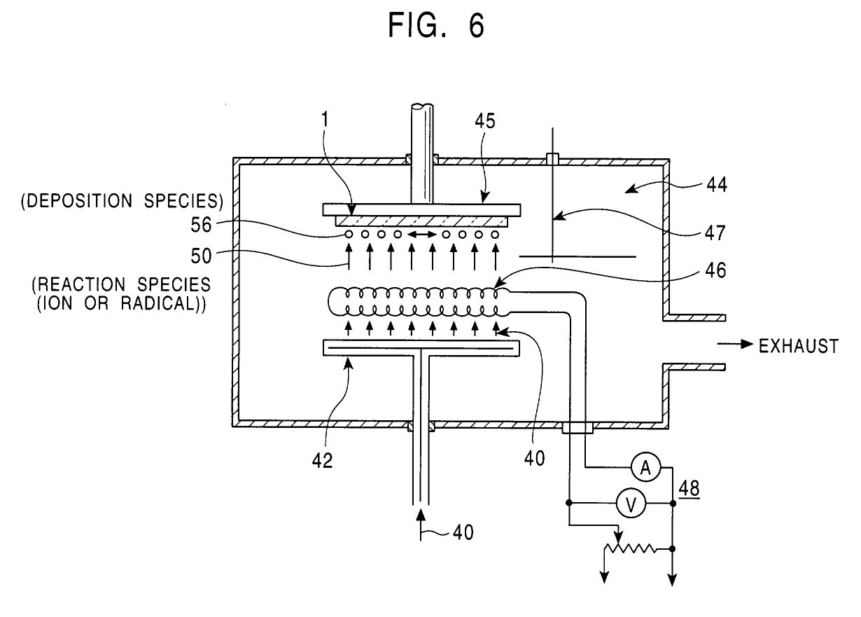

The catalytic CVD method is carried out by using such an apparatus shown in FIGS. 5 and 6.

In this apparatus, a gas comprising the hydrogen-based carrier gas and a raw material gas 40 (containing a doping gas such as B₂H₆, PH₃, SnH₄, or the like according to demand) such as silicon hydride (for example, monosilane) is introduced into a deposition chamber 44 from a supply conduit 41 through a supply port (not shown) of a shower head 42. In the deposition chamber 44, a susceptor 45 for supporting a substrate 1 made of glass or the like, the shower head 42 with good heat resistance (preferably made of a material having the same melting point as or a lower melting point than a catalyzer 46), the catalyzer 46 comprising, for example, a tungsten coil, and a shutter 47 which can be opened and closed are disposed. Although not shown in the drawings, a magnetic seal is provided between the susceptor 45 and the deposition chamber 44, and the deposition chamber 44 is connected to a front chamber for pre-treatment and evacuated by a turbo-molecular pump or the like through a valve.

The substrate 1 is heated by heating means such as a heater wire or the like provided in the susceptor 45, and the catalyzer 46 comprises a resistance wire and is activated by heating to a temperature lower than the melting point (particularly, 800 to 2000° C., and about 1600 to 1800° C. in the case of tungsten). Both ends of the catalyzer 46 are connected to a DC or AC catalyzer power supply 48 so that the catalyzer 46 is heated to a predetermined temperature by a current supplied from the power supply.

In order to carry out the catalytic CVD method, in the state shown in FIG. 5, the degree of vacuum in the deposition chamber 44 is set to 1.33×10⁻⁴ to 1.33×10⁻⁶ Pa, and for example, the hydrogen-based carrier gas is supplied at 100 to 200 SCCM. After the catalyzer is activated by heating to the predetermined temperature, the reaction gas 40 comprising 1 to 20 SCCM of silicon hydride (for example, monosilane) gas (containing an appropriate amount of a doping such as B₂H₆, PH₃, or the like according to demand) is introduced from the supply conduit 41 through the supply port 43 of the shower head 42 to set a gas pressure of 0.133 to 13.3 Pa, for example, 1.33 Pa. As the hydrogen-based carrier gas, any one of hydrogen and gases containing hydrogen and an appropriate amount of inert gas, such as hydrogen+argon, hydrogen+helium, hydrogen+neon, hydrogen+xenon, hydrogen+krypton, and the like, may be used (this applies hereinafter).

As shown in FIG. 6, when the shutter 47 is opened to bring at least a portion of the raw material gas 40 into contact with the catalyzer 46, the gas 40 is catalytically decomposed to form a group of reaction species (i.e., deposition species or precursors thereof, and radical hydrogen ions) such as silicon ions and radicals having high energy by catalytic deposition reaction or thermal decomposition reaction. The reaction species 50 such as the produced ions and radicals are deposited by vapor phase growth to form a predetermined film of amorphous silicon-containing microcrystal silicon on the substrate kept at 200 to 800° C. (for example, 300 to 400° C.) with high energy.

In this way, high energy is applied to the reaction species by the catalytic function of the catalyzer 46 and the high energy possessed thereby without the occurrence of plasma, and thus the reaction gas can be efficiently changed to the reaction species and uniformly deposited on the substrate 1 by thermal CVD.

Also, even when the substrate temperature is decreased, an intended good film can be obtained because of the high energy of the deposition species. Therefore, the substrate temperature can be further decreased, and thus an inexpensive large insulating substrate (a glass substrate of borosilicate glass, aluminosilicate glass, or the like, a heat-resistant resin substrate of polyimide or the like) can be used, thereby decreasing the cost.

Of course, since plasma does not occur, damage by plasma does not occur to obtain a produced film with low stress, and realize a simple and inexpensive apparatus as compared with a plasma CVD method.

In this case, the operation can be performed under reduced pressure (for example, 0.133 to 1.33 Pa) or atmospheric pressure, but the atmospheric pressure type can realize a simple and inexpensive apparatus, as compared with the low-pressure type. Even with the atmospheric type, a high-quality film having good density, uniformity and adhesion can be obtained, as compared with a conventional atmospheric CVD method. In this case, the throughput and productivity of the atmospheric type are higher than those of the low-pressure type, thereby permitting a decrease in cost.

In the above-described catalytic CVD method, the temperature of the substrate is increased by radiant heat of the catalyzer 46, but a substrate heating heater 51 may be provided according to demand, as described above. Although the catalyzer 46 comprises a coil (a mesh, a wire, or a porous plate may be used), the catalyzer 46 may be provided in a plurality of stages (for example, two or three stages) in the gas flow direction to increase the area of contact with the gas. In this CVD method, the substrate 1 is disposed on the lower surface of the susceptor 45 above the shower head 42, and thus the particles produced in the deposition chamber 44 neither drop nor adhere to the substrate 1 or the film on the substrate 1.

<Optical Harmonic Modulated UV or/and DUV Laser Annealing and an Apparatus Therefor>

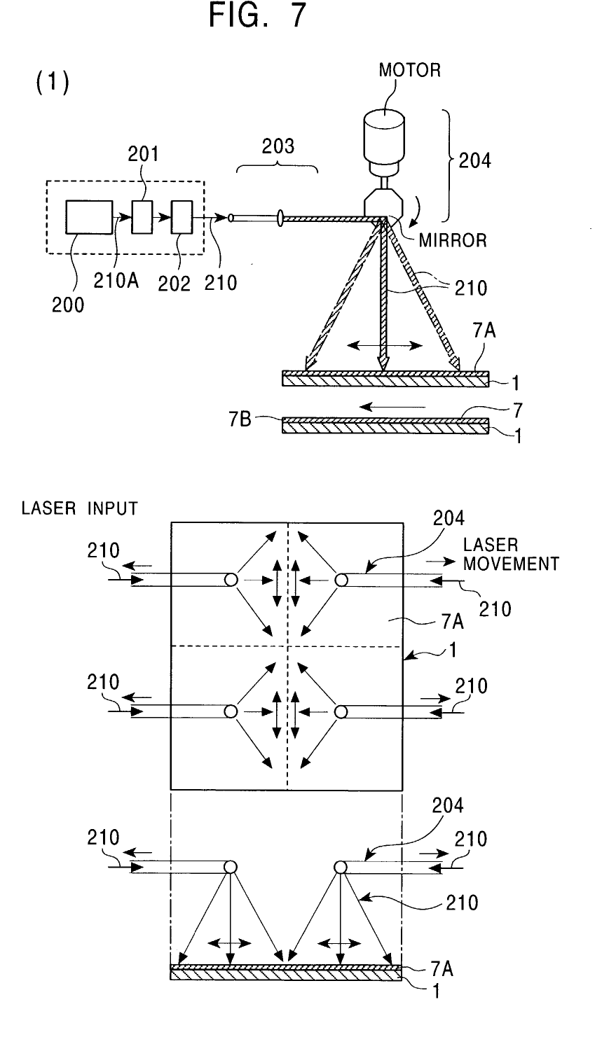

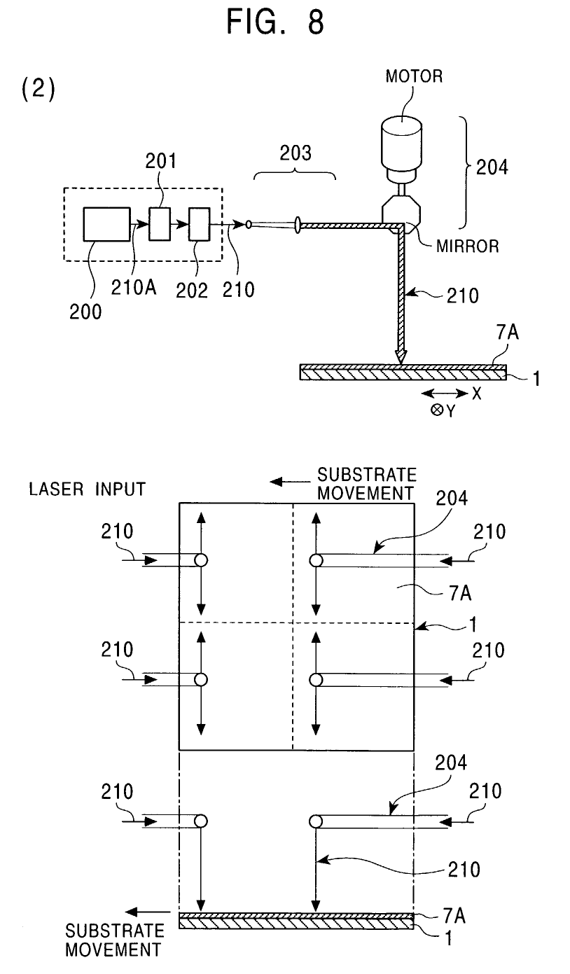

FIGS. 7 and 8 respectively show examples of the principal portion of the apparatus (annealer) for laser annealing of the present invention. In the examples, in an inert gas (nitrogen or the like), a laser beam 210A emitted from a Nd:YAG (1064 nm) laser rod 200 is subjected to ⅓ harmonic modulation using nonlinear optical crystals 201 and 202 to obtain a UV laser beam 210 at a wavelength of 355 nm, and an amorphous silicon or microcrystal silicon film 7A on the substrate 1 is put into a molten or semi-molten state by irradiation with the UV laser beam 210 with an irradiation energy density of 300 to 500 mJ/cm².

In this case, for example, the following two methods can be used.

(1) As shown in FIG. 7, the laser irradiation beam 210 is incident on a galvanometer scanner 204 through a lens system 203 so that the fixed substrate 1 is scanned at an appropriate speed using the galvanometer scanner 204. The substrate 1 is scanned with the laser beam 210 by rotation of the scanner 204, as shown by a solid line and a virtual line.

(2) As shown in FIG. 8, the substrate 1 is moved at an appropriate speed relative to the fixed laser irradiation beam 210 by using a high-precision stepping motor. Namely, the substrate 1 is moved laterally and/or longitudinally in the X and Y directions shown in the drawing (step and repeat).

In this case, the laser beam 210 may be converged and shaped in a linear shape {for example, (200 to 600 mm)×(1 to 10 mm)}, a rectangular shape {for example, (10 to 100 mm)×(200 to 300 mm)}, or a square shape {for example, 100×100 mm) for irradiation to decrease variation in irradiation strength and improve the melting efficiency and throughput, thereby improving productivity. The substrate 1 may be pre-heated to a temperature lower than it strain point by a heater (not shown) provided in the susceptor (not shown).

In this method of moving a silicon melting zone in the thin film 7A (for example, a so-called zone purification method in which the silicon melting zone is moved at an appropriate speed from the source region to the gate region and the drain region to crystallize the thin film by natural cooling from the source region), a large-grain polycrystalline silicon film 7 is formed.

In this case, as shown in FIG. 7, the catalytic element after the work of promoting crystallization, and other impurity elements are gettered by absorption (segregation) in the high-temperature silicon melting zone or semi-melting zone 7B at the end of scanning to form a high-purity large-grain polycrystalline silicon film having a catalytic element and impurity element concentration decreased to 1×10¹⁵ atoms/cc or less.

At this time, a so-called multi-zone purification method in which silicon melting or semi-melting and cooling are continuously repeated by irradiation of a plurality of optical harmonic modulated UV laser beams may be used to further promote crystallization and gettering of the catalytic element and other impurity elements, further increasing purity. Since the crystal axis of polycrystalline silicon is oriented in the laser scanning direction, irregularity less occurs in crystal grain boundaries, and thus the carrier mobility can be increased.

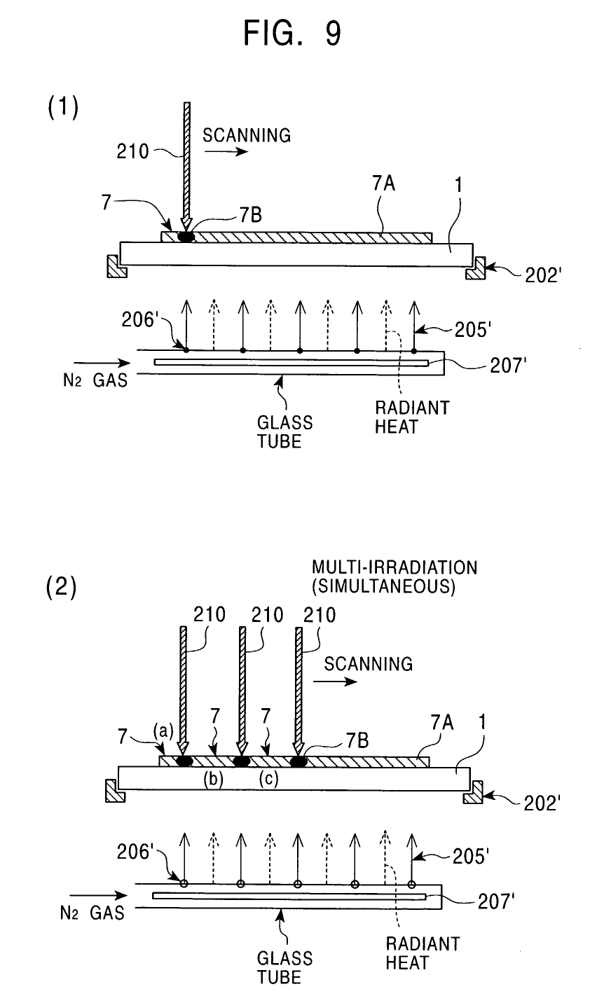

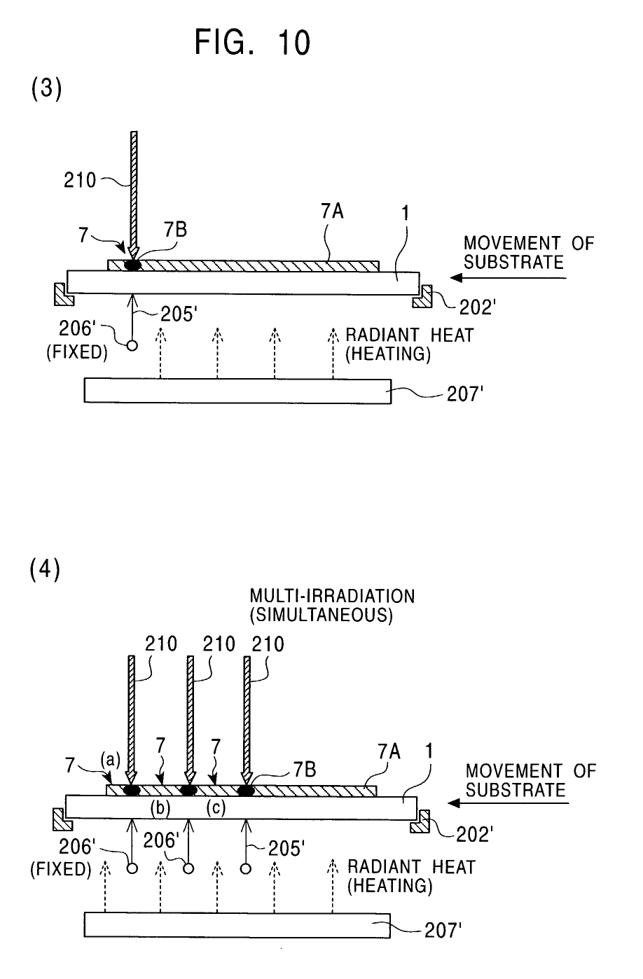

Similarly, in a zone purification method (FIGS. 9(1) and FIG. 10(3)) or a multi-zone purification method (FIG. 9(2) and FIG. 10(4)) comprising continuously repeating silicon melting or semi-melting and cooling by irradiation with a plurality of laser beams, the silicon melting zone or semi-melting zone is moved by moving the laser irradiation beam 210 at an appropriate speed relative to the substrate fixed to a support 202′, as shown in FIG. 9, or moving the substrate 1 at an appropriate speed relative to the fixed laser irradiation beam 210 as shown in FIG. 10. In this case, in order to homogenize the crystallized film by making uniform the substrate temperature and stabilizing the substrate temperature, decrease the stress of the crystallized film and the substrate, decrease the laser irradiation power, and promote slow cooling, the substrate 1 is preferably heated by blowing a hot gas 205′ such as the air or inert gas (nitrogen gas or the like) of room temperature to 400° C., preferably 200 to 300° C., on the back of the substrate from a nozzle 206′, or heating by an infrared lamp (halogen lamp, or the like) 207′, or a combination of these methods. The irradiation light 210 and the hot gas 205′ are preferably applied synchronously at symmetrical positions in the vertical direction. In the multi-zone purification method, crystallization and gettering of the catalytic element and other impurity elements are further promoted to achieve high purity, and the degree of crystallization and purity of the crystallized zone 7 increase in the order of (c), (b) and (a) shown in the drawing.

As the optical harmonic modulated laser, an ultraviolet laser (UV) at 300 to 400 nm or a deep ultraviolet laser (DUV) at 200 to 300 nm may be used. Examples of the ultraviolet laser include a ⅓ harmonic at 355 nm of Nd:YAG (wavelength 1064 nm), a ½ harmonic at 316.4 nm of He—Ne (wavelength 632.8 nm), a ⅓ harmonic at 383.3 nm of He:Ne (wavelength 1.15 μm), a ½ harmonic at 347.2 nm of ruby (wavelength 694.3 nm), and the like. Examples of the deep ultraviolet laser include ½ harmonics at 257.8 nm and 244 nm of Ar (wavelength 514.5 nm and 488 nm), ½ harmonics at 260.4 nm and 238.1 nm of Kr (wavelength 520.8 nm and 476.2 nm), a ½ harmonic at 220.8 nm of He—Cd (wavelength 441.6 488 nm), and the like.

Generally, the wavelength of a laser beam and the wavelength of a harmonic have the relation according to equation [1] below. Namely, when a laser beam at wavelength λ1 and a laser beam at wavelength λ2 are incident on a nonlinear optical crystal to obtain a laser beam at wavelength λ3 by wavelength conversion by the nonlinear optical crystal, the wavelengths λ1 λ2 and λ3 have the relationship according to equation [I].

1/λ1+1/λ2=1/λ3 [I]

For example, as shown in FIG. 11(A), when the wavelength of a laser beam 210A of a Nd:YAG solid-state pulse laser (wavelength 1064 nm) is converted by a first nonlinear optical crystal (KTP: potassium titanophosphate), λ1=λ2=1064 nm are substituted into the above equation to obtain λ3=532 nm. Next, when the beam at the wavelength of 532 nm and the laser beam at a wavelength of 1064 nm introduced by a mirror 205 are input to a second nonlinear optical crystal (BBO: barium borate) for wavelength conversion, λ1=1064 nm, and λ2=532 nm are substituted into the above equation to obtain harmonic light at λ3=355 nm. At this time, the laser beam remaining unconverted and the harmonic light are separated by a wavelength separation mirror not shown in the drawing so that only the harmonic light at λ3=355 nm is incident on a mechanism for determining a processed shape.

The harmonic light λ3 is shaped into a laser beam having any desired shape such as a band, rectangular or square shape and desired dimensions by a light shaper 203 serving as the mechanism for determining a processed shape, and further incident on a light deflector 206, for example, an optical scanning unit of a galvanometer scanner system 204, to perform beam scanning based on a scanning command. In this case, the harmonic light at λ3=355 nm may be mixed with the fundamental wave at λ1=1064 nm introduced from the mirror 205 by using a mixer 207.

Furthermore, as shown in FIGS. 11(B) and 11(c), a laser beam having any of various wavelength components can be obtained by mixing the appropriately selected harmonic light and fundamental wave.

As described above, the high-output UV (or DUV) laser formed by optical harmonic modulation has higher irradiation energy than a conventional solid-state pulse laser at substantially the same wavelength, and is thus suitable for melting an amorphous silicon film and the like.

In annealing with any of the optical harmonic modulated UV or DUV lasers, when the laser beam is converged and shaped in a linear (for example, 500 to 600 mm×10 μm to 1 mm), rectangular (for example, 10 to 100 mm×200 to 300 mm) or square (for example, 100×100 mm) for irradiation, the irradiation strength, i.e., the melting efficiency and throughput, can be improved.

For example, with a large-area glass substrate of 1000×1000 mm, the area may be divided into four parts so that each of the parts is irradiated with a plurality of optical harmonic modulated UV or DUV lasers, as shown in FIGS. 7 and 8. Examples of the laser irradiation method include a method in which the fixed substrate surface is divided into four parts, and the four areas are scanned at an appropriate speed with laser beams synchronously by using the galvanometer scanner (FIG. 7), and a method in which the substrate is moved synchronously at an appropriate speed relative to four fixed laser beams by using the high-precision stepping motor (FIG. 8).

In this way, the substrate or the laser may be moved at an appropriate speed to control the rate of heat melting and cooling, forming the polycrystalline silicon film having any crystal grain diameter and any purity.

The conditions (the wavelength, the irradiation strength, the irradiation time, etc.) for optical harmonic modulated UV or DUV annealing may be properly optimized according to the thickness of the amorphous silicon film, the glass heat resistance temperature, and the crystal grain diameter (carrier mobility). For the laser beam, which is mainly UV or DUV, of course, any of various wavelength components such as a mixed beam of UV and DUV, a mixed beam with the fundamental wave, etc. may be selected.

Also, in optical harmonic modulated UV or DUV laser annealing, in order to make the substrate temperature uniform and stabilize the substrate temperature to form a homogeneous crystallized film, decrease the stress of the crystallized film and the substrate, decrease the laser power, and promote slow cooling, the substrate is preferably heated (an infrared lamp, a ceramic heater, or the like) to a temperature lower than its strain point, for example, room temperature to 500° C., preferably 200 to 400° C.

<Continuous Processing of Catalytic CVD (or Plasma CVD) and Optical Harmonic Modulated UV or/and DUV Laser Annealing>

In order to prevent contamination and improve productivity, an integrated apparatus for the step or means (plasma CVD, catalytic CVD, sputtering, or the like) for forming the low-crystalline semiconductor thin film, and laser annealing of the present invention or annealer is preferably used for continuously or successively performing these processes, for example, in an inline (continuous chamber) system (linear type or rotational type), a multi-chamber system, a cluster system, or the like.

The following cluster system (1) or (2) is more preferred.

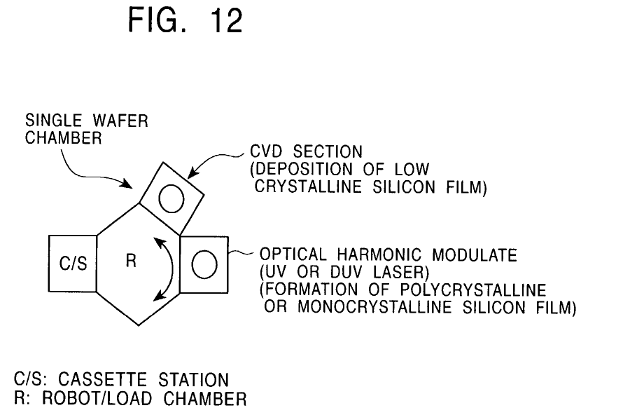

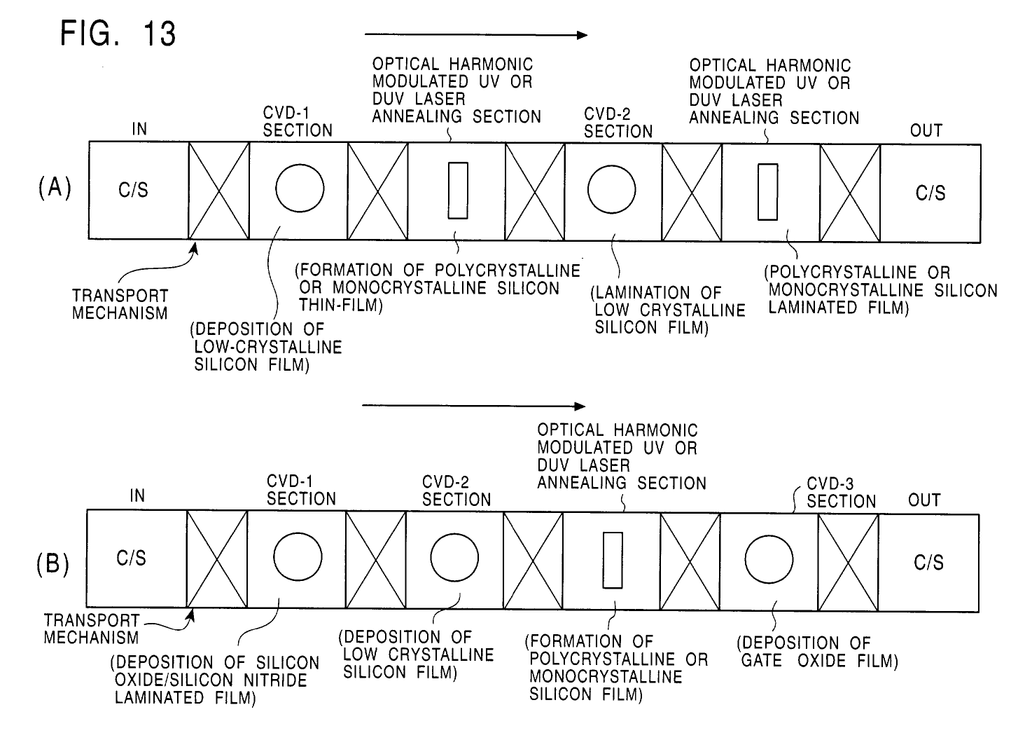

(1) For example, in such a cluster-system integrated apparatus as shown in FIG. 12, the steps of forming a low-crystalline semiconductor thin film in a CVD section, crystallizing the thin film by laser annealing of the present invention in an annealer section, returning the crystallized film to the CVD section for forming a low-crystallized semiconductor thin film on the crystallized film, and again crystallizing the thin film by laser annealing of the present invention in the annealer section are repeated. FIG. 13(A) shows an inline system of these steps.

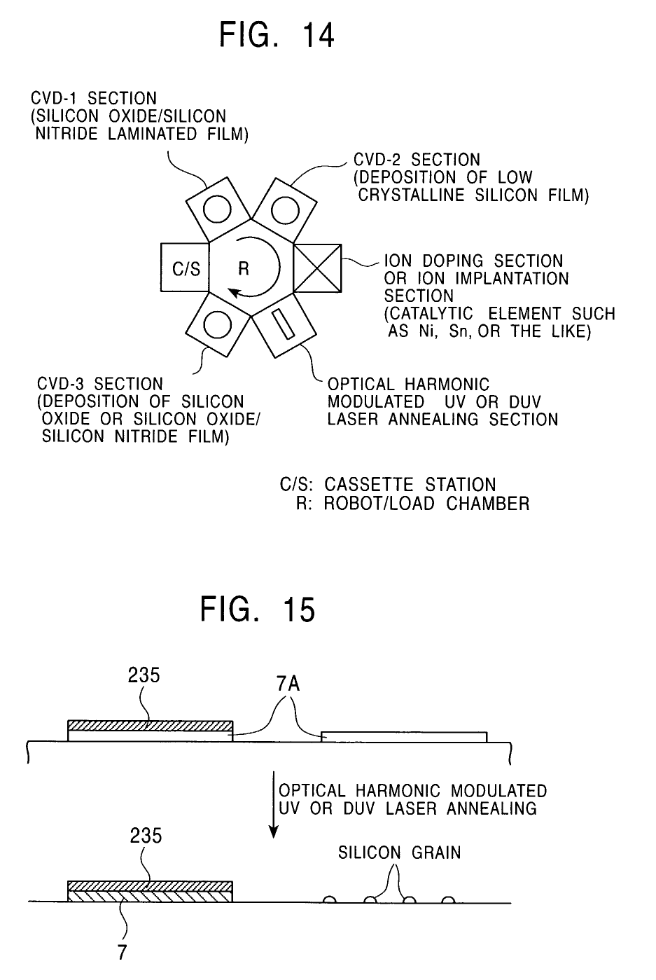

(2) In such a cluster-system integrated apparatus as shown in FIG. 14, the works of forming an underlying protective film (silicon oxide/silicon nitride laminated film) in a CVD-1 section, forming a low-crystalline semiconductor thin film in a CVD-2 section, adding an appropriate amount of a IV group element in an ion doping/ion implantation section according to demand, crystallizing the thin film by laser annealing of the present invention in an annealer section, and further forming a gate insulating film (silicon oxide film or the like) in a CVD-3 section are continuously performed. FIG. 13(B) shows an inline system of these works.

The silicon oxide/silicon nitride laminated film formed in the CVD-1 section may be used as an underlying protective film of a top gate-type MOSTFT, or a bottom gate insulating protective film of a bottom gate-type MOSTFT, and the silicon oxide film or silicon oxide/silicon nitride laminated film formed in the CVD-3 section may be used as a gate insulating film of a top gate-type MOSTFT or a protective film of a bottom gate-type MOSTFT.

CVD may be catalytic CVD or plasma CVD, and sputtering may be performed in place of catalytic CVD or plasma CVD. In CVD, plasma treatment or catalytic AHA treatment may be performed before deposition. For example, plasma AHA (Atomic Hydrogen Anneal) treatment is performed only with the hydrogen-based carrier gas without a flow of the raw material gas before deposition by plasma CVD to clean the surface of the formed polycrystalline silicon film by removing contaminants (a low oxidation film, moisture, oxygen, nitrogen, carbon dioxide, etc.) and etch the remaining amorphous silicon component, thereby forming the polycrystalline silicon film having a high rate of crystallization. Therefore, the low-crystalline silicon film laminated on the clean interface using the underlying layer as a seed is laminated as a large-grain polycrystalline or monocrystalline semiconductor film having a good crystal by next laser annealing.

In order to prevent oxidation and nitriding, laser annealing is preferably performed in low-pressure hydrogen, a low-pressure hydrogen gas atmosphere or a vacuum. A hydrogen gas or a mixed gas of hydrogen and an inert gas (argon, helium, krypton, xenon, neon, or radon) is preferably used, and the gas pressure is 1.33 Pa to the atmospheric pressure, preferably 133 Pa to 4×10⁴ Pa, and the degree of vacuum is 1.33 Pa to the atmospheric pressure, preferably 13.3 Pa to 1.33×10⁴ Pa. However, when the insulating protective film (a silicon oxide film, silicon nitride film, silicon oxynitride film, or silicon oxide/silicon nitride laminated film) is formed on the low-crystalline semiconductor thin film, or when the works are not continuously carried out, laser annealing may be performed in the air or atmospheric-pressure nitrogen.

Since catalytic CVD and laser annealing of the present invention can be performed without the occurrence of plasma, damage by plasma does not occur, and thus a produced film with low stress can be obtained. Also, a simple and inexpensive apparatus can be realized, as compared with the plasma CVD method.

When the surface of the low-crystalline silicon film 7A is coated with the insulating protective film such as a silicon oxide film, silicon nitride film, silicon oxynitride film, or silicon oxide/silicon nitride laminated film, as shown in FIG. 15, the low-crystalline semiconductor thin film effectively absorbs the laser beam and is heat-melted due to a reflection decreasing effect during laser annealing of the present invention, thereby securely forming the intended polycrystalline silicon thin film 7. However, when the low-crystalline silicon film 7A is not coated, in some cases, molten silicon is scattered, or silicon grains remain due to surface tension to fail to form the polycrystalline silicon film.

Furthermore, in crystallization of the low-crystalline semiconductor thin film by laser annealing of the present invention, when a magnetic field, an electric field or a magnetic field and an electric field are applied so that annealing is performed under the action of the magnetic field or electric field, crystal grains can be oriented.

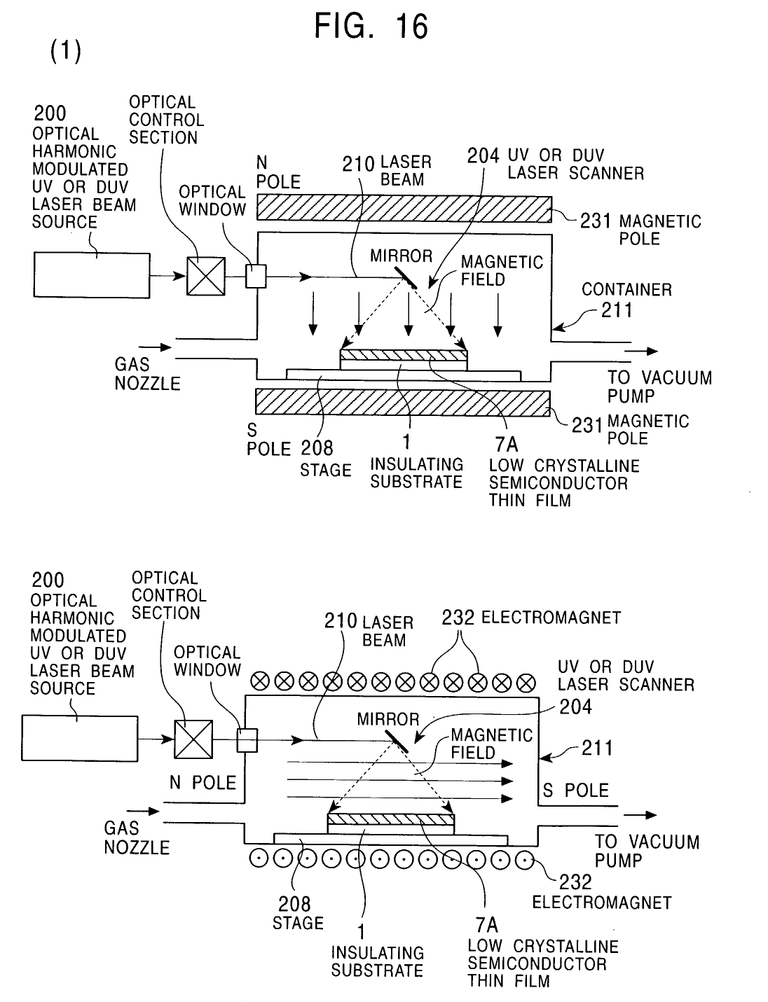

For example, when a magnetic field is applied, a permanent magnet 231 or an electromagnet 232 is provided around a vacuum container 211 containing the UV or DUV laser scanner 204 and the substrate 1 so that laser annealing of the present invention is performed under the action of the magnetic field, as shown in FIG. 16.

For example, when the low-crystalline silicon thin film 7A is subjected to laser annealing of the present invention under the action of the magnetic field, the electron spins of silicon atoms of the molten silicon thin film 7A are oriented in a constant direction by interaction with the magnetic field, and then the crystal orientations of silicon are arranged by cooling solidification from the molten state. The crystal orientations of the thus-crystallized film are substantially arranged, and thus the electron potential barrier possessed by grain boundaries is decreased to increase carrier mobility. In this case, it is important to arrange the crystal orientations in a constant direction. The crystal orientations are arranged in the vertical direction or the horizontal direction of the obtained polycrystalline silicon thin film 7 depending upon the structure of the outer shell orbit of silicon atoms. When the crystal grains are oriented, the polycrystalline silicon thin film has no surface irregularity, and thus the surface of the thin film is planarized, thereby improving the interfacial state between the thin film and the gate insulating film formed in contact therewith and improving carrier mobility.

Since the scanner 204 used for laser annealing of the present invention under the action of the magnetic field is contained in the vacuum container 211, the efficiency of irradiation is high, and the above-described function peculiar to laser scanning can be most effectively exhibited.

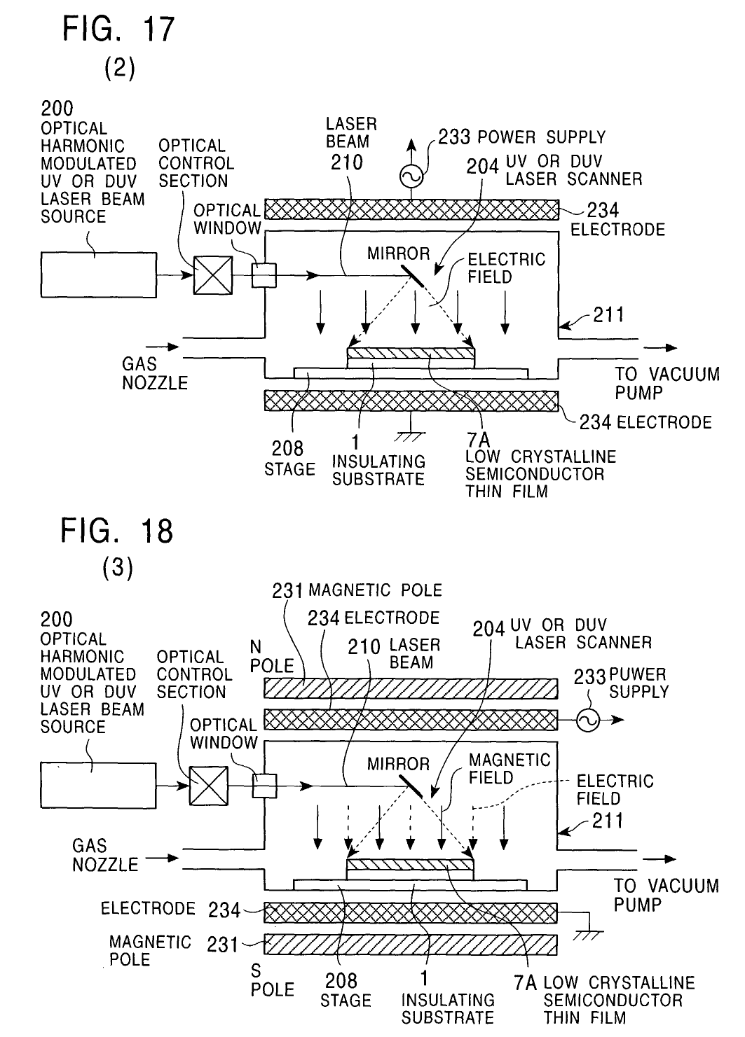

FIG. 17 shows an example in which an electric field is applied from a power supply 233 instead of the magnetic field. In this case, an electrode 234 is provided around the vacuum container 211 containing the scanner 204 and the substrate 1, for applying a high-frequency voltage (or a DC voltage or both) so that laser annealing is performed under the action of the electric field.

At this time, the electron spins of silicon atoms in the molten low-crystalline silicon thin film 7A are oriented in a constant direction by interaction with the electric field, and then crystallization takes place with constant orientation during cooling solidification from the molten state. In this case, like in the case of application of the magnetic field, crystal grains are oriented in a constant direction to improve carrier mobility and decrease surface irregularity. Also, the irradiation efficiency of the laser beam 210 is high.

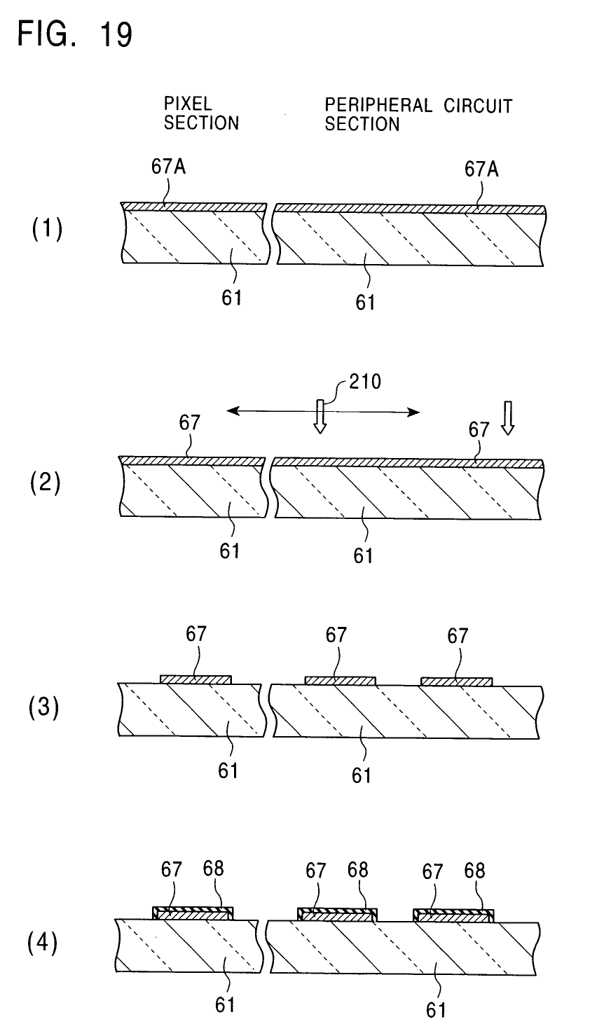

FIG. 18 shows an example in which both the magnetic field and the electric field are applied. In this case, laser annealing is performed under the actions of the magnetic field produced by the permanent magnet 231 (or an electromagnet) provided around the vacuum container 211 containing the scanner 204 and the substrate 1 and the electric field produced by the electrode 234 for applying a high-frequency voltage (or a DC voltage or both).

At this time, the electron spins of silicon atoms in the molten low-crystalline silicon thin film 7A are oriented in a constant direction by interaction with the magnetic field and the electric field, and then crystallization takes place with further sufficient orientation due to the synergistic effect of the magnetic field and the electric field during cooling solidification from the molten state. Therefore, the crystal grains are more easily oriented in a constant direction to further improve carrier mobility and further decrease surface irregularity. Furthermore, the irradiation efficiency of the laser beam 210 is high.

<Manufacture of Top Gate-Type CMOSTFT>

A description will now be made of an example of manufacture of a top gate-type CMOSTFT using optical harmonic modulated UV laser annealing according to this embodiment.

First, as shown in FIG. 1(1), an underlying protective film 100 comprising a protective laminated film of a silicon nitride film and a silicon oxide film is formed at least in a MOSTFT formation region of the insulating substrate 1 made of borosilicate glass, aluminosilicate glass, quartz glass, crystallized glass, or the like by the vapor phase growth method such as plasma CVD, catalytic CVD, low-pressure CVD, or the like under the conditions below (this applies hereinafter).

In this case, the glass material is selected according to the process temperature for forming the MOSTFT.

Low temperature of 200 to 500° C.: A glass substrate (500×600×0.5 to 1.1 μm thickness) of borosilicate glass, aluminosilicate glass, or the like, or a heat-resistant resin substrate may be used.

High temperature of 600 to 1000° C.: A heat-resistant glass substrate (6 to 12 inch φ, 700 to 800 μm thickness) of quartz glass, crystallized glass, or the like may be used. The silicon nitride film serving as the protective film is formed for stopping Na ions from the glass substrate, but it is unnecessary when synthetic quartz glass is used.

In use of catalytic CVD, the same apparatus as shown in FIGS. 5 and 6 can be used. However, in order to prevent oxidative deterioration of the catalyzer, the catalyzer must be heated to a predetermined temperature (about 1600 to 1800° C., for example, about 1700° C.) with the hydrogen-based carrier gas supplied, and then cooled to a temperature causing no problem after deposition, and then the hydrogen-based carrier gas must be cut.

As the deposition conditions, the hydrogen-based carrier gas (hydrogen, argon+hydrogen, helium+hydrogen, neon+hydrogen, or the like) is constantly flowed in the chamber, and the flow rate and pressure, and the susceptor temperature are controlled to the following predetermined values:

Pressure in the chamber: about 0.1 to 10 Pa, for example, 1 Pa

Susceptor temperature: 350° C.

Flow rate of the hydrogen-based carrier gas (in the case of a mixed gas, hydrogen is 80 to 90 molar %): 100 to 200 SCCM

The silicon nitride film is formed in a thickness of 50 to 200 nm under the following conditions:

H₂ is used as the carrier gas, and ammonia (NH₃) is mixed with monosilane (SiH₄) at an appropriate ratio to form the raw material gas.

H₂ flow rate: 100 to 200 SCCM

SiH₄ flow rate: 1 to 2 SCCM

NH₃ flow rate: 3 to 5 SCCM

The silicon oxide film is formed in a thickness of 50 to 200 nm under the following conditions:

H₂ is used as the carrier gas, and O₂ diluted with He is mixed with monosilane (SiH₄) at an appropriate ratio to form the raw material gas.

H₂ flow rate: 100 to 200 SCCM

SiH₄ flow rate: 1 to 2 SCCM

Flow rate of O₂ diluted with He: 0.1 to 1 SCCM

In the case of FR plasma CVD deposition, the conditions are as follows:

The silicon oxide film is formed at a SiH₄ flow rate of 5 to 10 SCCM, a N₂O flow rate of 1000 SCCM, and a gas pressure of 50 to 70 Pa, and with a RF power of 1000 W and a substrate temperature of 350° C.

The silicon nitride film is formed at a SiH₄ flow rate of 50 to 100 SCCM, a NH₃ flow rate of 200 to 250 SCCM, a N₂ flow rate of 700 to 1000 SCCM, and a gas pressure of 50 to 70 Pa, and with a RF power of 1300 W and a substrate temperature of 250° C.

Next, as shown in FIG. 1(2), the low-crystalline silicon film 7A doped with 10¹⁸ to 10²⁰ atoms/cc of catalytic element, for example, tin or nickel, is formed in a thickness of 50 nm by catalytic CVD, plasma CVD or sputtering. However, doping with tin or nickel is not always necessary (this applies hereinafter). Then, a silicon oxide film for protecting and decreasing reflection is formed in a thickness of 10 to 30 nm.

In this case, low-crystalline silicon doped with, for example, tin or nickel is vapor-grown to form the low-crystalline semiconductor thin film by the above catalytic CVD using the apparatus shown in FIGS. 5 and 6 under the conditions below. In doping with tin, tin can be supplied as a gas, as described below, while in doping with nickel, doping may be performed by ion implantation or ion doping after formation of the thin film.

Deposition of amorphous silicon-containing microcrystal silicon by catalytic CVD:

H₂ is used as the carrier gas, and monosilane (SiH₄) and tin hydride (SnH₄) are mixed at an appropriate ratio to form the raw material gas. The H₂ flow rate is 150 SCCM, the SiH₄ flow rate is 15 SCCM, and the SnH₄ flow rate is 15 SCCM. At this time, an appropriate amount of n-type phosphorus, arsenic or antimony may be mixed with the silane gas (silane, disilane or trisilane) as the raw material gas, or an appropriate amount of p-type boron or the like may be mixed to form a tin-containing silicon film having any desired n- or p-type impurity carrier concentration.

N type: phosphine (PH₃), arshin (ASH₃), stibine (SbH₃)

type: diborane (B₂H₆)

When the above films are formed in the same chamber, the hydrogen-based carrier gas may be constantly supplied, and the catalyzer may be heated to the predetermined temperature to be put on standby, followed by the processing below.

Monosilane and ammonia are mixed at an appropriate ratio to form the silicon nitride film having a predetermined thickness, and then the raw material gas is sufficiently exhausted. Then, monosilane and O₂ diluted with He are mixed at an appropriate ratio to form the silicon oxide film having a predetermined thickness, and then the raw material gas is sufficiently exhausted. Then, monosilane and SnH₄ are mixed at an appropriate ratio to form the amorphous silicon-containing microcrystal silicon film containing tin and having a predetermined thickness, and then the raw material gas is sufficiently exhausted. Then, monosilane and O₂ diluted with He are mixed at an appropriate ratio to form the silicon oxide film having a predetermined thickness. After deposition, the raw material gas is cut, the catalyzer is cooled to a temperature with no problem, and the hydrogen-based carrier gas is cut. In this case, the raw material gas for forming the insulating film may be gradually decreased or increased to form a graded-junction composite or laminated insulating film, for example, a silicon oxide/silicon nitride laminated film.

When the films are respectively formed in independent chambers, the hydrogen-based carrier gas may be supplied to each of the chambers, and the catalyzer may be heated to a predetermined temperature to be put on standby, followed by the processing below. In chamber A, monosilane and ammonia are mixed at an appropriate ratio to form the silicon nitride film having a predetermined thickness. Next, in chamber B, monosilane and O₂ diluted with He are mixed at an appropriate ratio to form the silicon oxide film. Next, in chamber C, monosilane and SnH₄ are mixed at an appropriate ratio to form the amorphous silicon-containing microcrystal silicon film containing tin. Next, in chamber B, monosilane and O₂ diluted with He are mixed at an appropriate ratio to form the silicon oxide film. After deposition, the raw material gas is cut, the catalyzer is cooled to a temperature with no problem, and the hydrogen-based carrier gas is cut. In this case, the hydrogen-based carrier gas and each of the raw material gases may be constantly supplied to each of the chambers to put the chamber into a standby state.

The conditions for depositing the low-crystalline silicon film by RF plasma CVD include a SiH₄ flow rate of 100 SCCM, a H₂ flow rate of 100 SCCM, a gas pressure of 1.33×10⁴ Pa, a RF power of 100 W and a substrate temperature of 350° C.

Next, as shown in FIG. 1(3), laser annealing of the present invention is performed. For example, as shown in FIG. 7, the amorphous silicon or microcrystal silicon film 7A is molten or semi-molten by irradiation with the UV laser beam 210 at a wavelength of 355 nm formed by ⅓ optical harmonic modulation of Nd:YAG (1064 nm) using the nonlinear optical crystal in an atmospheric-pressure nitrogen gas with an irradiation energy density of 300 to 500 mJ/cm², and then slowly cooled to form the large-grain polycrystalline silicon film 7 which has a high rate of crystallization and a thickness of 50 nm, from which the catalytic element is removed.

In this case, as shown in FIG. 7, the catalytic element after the work of promoting crystallization, and other impurity elements are gettered by absorption (segregation) in the high-temperature silicon molting or semi-melting zone at the end of scanning to decrease the concentration of the catalytic element and impurity elements to 1×10¹⁵ atoms/cc or less in the formed high-purity large-grain polycrystalline silicon film.

By the multi-zone purification method in which silicon melting or semi-melting and cooling are continuously repeated by irradiation with a plurality of optical harmonic modulated UV lasers, crystallization and gettering of the catalytic element and other impurity elements can be promoted to increase purity. Since the crystal axis of polycrystalline silicon is oriented in the laser scanning direction, irregularity less occurs in the crystal grain boundaries, thereby decreasing the carrier mobility.

Also, the film 7A is preferably doped with the catalytic element (nickel or the like) by ion implantation or ion doping before laser annealing of the present invention. When the protective silicon oxide film, silicon nitride film, silicon oxynitride film or silicon oxide/silicon nitride laminated film is present on the surface of the low-crystalline silicon film, it is possible to prevent scattering of molten silicon or formation of silicon crystal grains (lumps) due to surface tension during laser annealing of the present invention, thereby obtaining a good polycrystalline silicon film.

Furthermore, even when laser annealing of the present invention is performed after the low-crystalline silicon film is islanded or the low-crystalline silicon film coated with the protective silicon oxide film is islanded in order to decrease a temperature rise of the substrate temperature and promote crystallization, a good polycrystalline silicon film can be obtained.

When laser annealing is performed under proper conditions after the gate channel, source and drain regions described below are formed, crystallization is promoted, and at the same time, the n-type or p-type carrier impurity (phosphorus, arsenic, boron, or the like) implanted into the gate channel, source and drain regions is activated, thereby improving productivity in some cases.

Next, the MOSTFT comprising the gate channel, source and drain regions formed by using the polycrystalline silicon film 7 is manufactured.

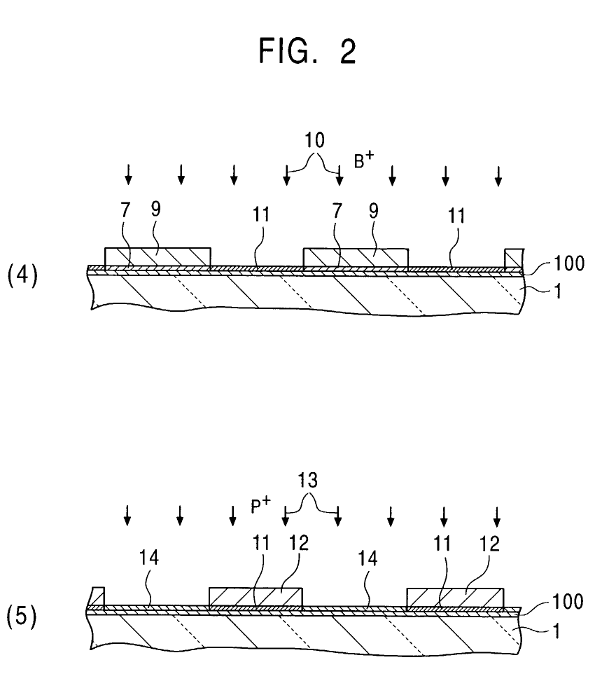

Namely, as shown in FIG. 2(4), the silicon oxide film for protecting and decreasing reflection is removed by general-purpose photolithography and etching techniques, and then the polycrystalline silicon thin film 7 is islanded. Then, in order to optimize the threshold value (Vₜₕ) by controlling the impurity concentration of the channel regions for nMOSTFTs, PMOSTFT sections are masked with a photoresist 9, and the silicon film 7 is doped with a p-type impurity ion (for example, boron ion) 10 with a dose of, for example, 5×10¹¹ atoms/cm² by ion implantation or ion doping to set the acceptor concentration to 1×10¹⁷ atoms/cc, forming p-conduction type polycrystalline silicon films 14 in the polycrystalline silicon film 7.

Next, as shown in FIG. 2(5), in order to optimize the threshold value (Vₜₕ) by controlling the impurity concentration of the channel regions for pMOSTFTs, nMOSTFT sections are masked with a photoresist 12, and the silicon film 7 is doped with a n-type impurity ion (for example, phosphorus ion) 13 with a dose of, for example, 1×10¹² atoms/cm² by ion implantation or ion doping to set the donor concentration to 2×10¹⁷ atoms/cc, forming n-conduction type polycrystalline silicon films 14 in the polycrystalline silicon film 7.

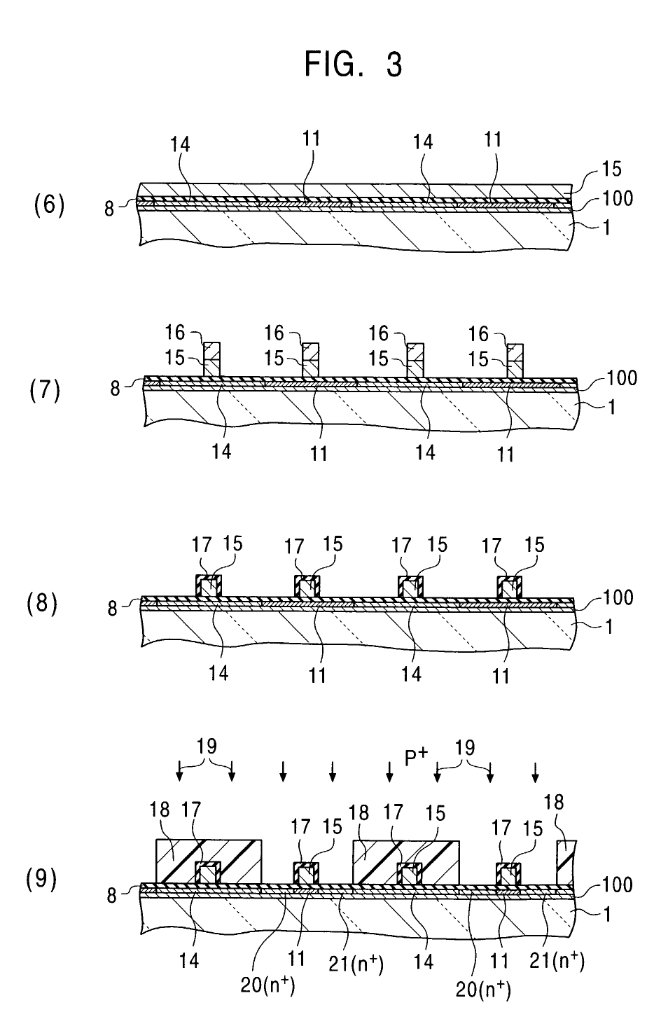

Next, as shown in FIG. 3(6), a silicon oxide film serving as the gate insulating film 8 is formed in a thickness of 50 nm by catalytic CVD or the like, and then a phosphorus-doped polycrystalline film 15 is deposited to a thickness of 400 nm by the same catalytic CVD method as described above under supply of, for example, 2 to 20 SCCM of PH₃ and 20 SCCM of SiH₄.

Next, as shown in FIG. 3(7), a photoresist 16 is formed in a predetermined pattern, and the phosphorus-doped polycrystalline film 15 is patterned in a gate electrode shape by using the photoresist 16 as a mask. Furthermore, the photoresist 16 is removed, and then a silicon oxide film 17 is formed to a thickness of 20 nm by, for example, catalytic CVD, as shown in FIG. 3(8).

Next, as shown in FIG. 3(9), the pMOSTFT sections are masked with a photoresist 18, and the silicon film 7 is doped with a n-type impurity, for example, phosphorus ion 19 with a dose of 1×10¹⁵ atoms/cm² by ion implantation or ion doping to set the donor concentration to 2×10²⁰ atoms/cc, forming n⁺-type source regions 20 and drain regions 21 of nMOSTFTs.

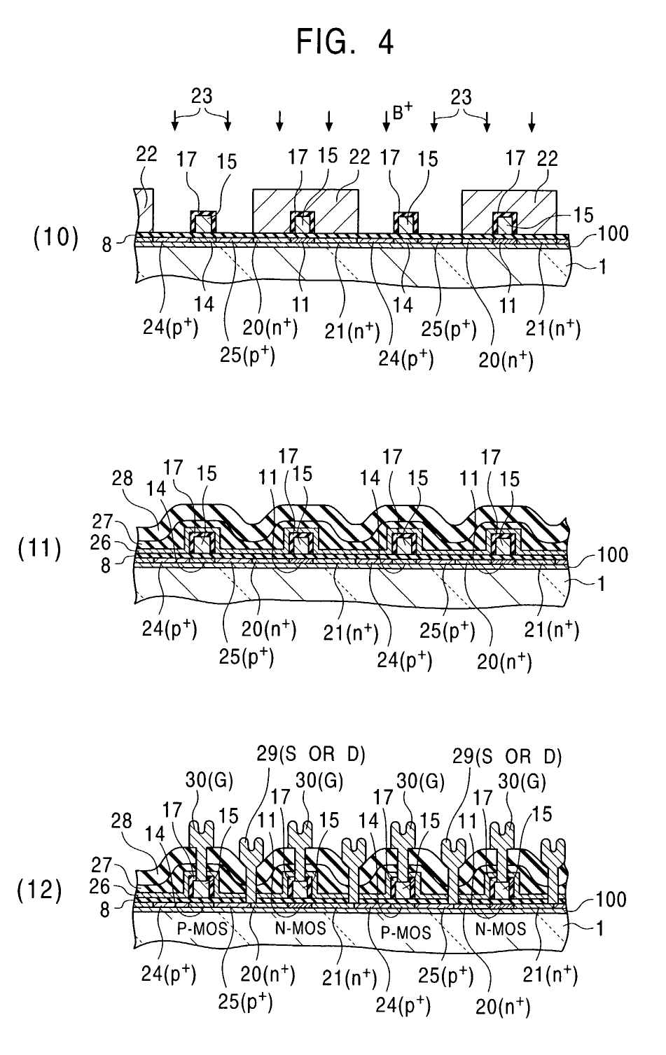

Next, as shown in FIG. 4(10), the nMOSTFT sections are masked with a photoresist 22, and the silicon film 7 is doped with a p-type impurity, for example, boron ion 23 with a dose of 1×10¹⁵ atoms/cm² by ion implantation or ion doping to set the acceptor concentration to 2×10²⁰ atoms/cc, forming p⁺-type source regions 24 and drain regions 25 of pMOSTFTs. Then, the doping impurity ions in each of the regions are activated by annealing at about 900° C. for about 5 minutes in N₂ to set the set impurity carrier concentration of each region.

Although the gate, source and drain regions are formed as described above, these regions can also be formed another method.

Namely, the low-crystalline silicon film 7A is islanded into the pMOSTFT and nMOSTFT regions after the step shown in FIG. 1(2). This is performed by removing the silicon oxide film for protecting and decreasing reflection by the general-purpose photolithography and etching techniques using a fluoric acid etchant, selectively removing the amorphous silicon-containing microcrystal silicon film by plasma etching with CF₄, SF₆, or the like, and separating the photoresist by an organic solvent or the like. Since cracks easily occur in the formed polycrystalline silicon film due to the stress during silicon melting and cooling when the temperature rapidly increases by laser beam irradiation in laser annealing of the present invention, islanding is an important point for decreasing a temperature rise of the substrate temperature. Therefore, islanding before laser annealing of the present invention is aimed at slowing down cooling of the silicon melting zone by decreasing heat radiation to promote crystal growth, and decreasing an increase in the substrate temperature in the unnecessary silicon melting zone.

After the low-crystalline silicon film 7A is subjected to laser annealing of the present invention as described above, the silicon oxide film for protecting and decreasing reflection is removed, and the pMOSTFT regions are doped with a n-type impurity, for example, phosphorus ion, with a dose of 1×10¹² atoms/cm² by ion implantation or ion doping using a photoresist mask to set the donor concentration to 2×10¹⁷ atoms/cc in the same manner as describe above. Also, the nMOSTFT regions are doped with a p-type impurity, for example, boron ion, with a dose of 5×10¹¹ atoms/cm² by ion implantation or ion doping using a photoresist mask to set the acceptor concentration to 1×10¹⁷ atoms/c, controlling the impurity concentration of each channel region, thereby optimizing Vₜₕ.

Next, the source and drain regions are formed by the general-purpose photolithography technique using a photoresist mask. In the case of nMOSTFT, doping with a n-type impurity, for example, arsenic or phosphorus ion is performed with a dose of 1×10¹⁵ atoms/cm² by ion implantation and ion doping to set the donor concentration to 2×10²⁰ atoms/cc, while in the case of pMOSTFT, doping with a p-type impurity, for example, boron ion is performed with a dose of 1×10¹⁵ atoms/cm² by ion implantation and ion doping to set the acceptor concentration to 2×10²⁰ atoms/cc.

Then, in order to activate the n-type or p-type impurity in the polycrystalline silicon film, the impurity ions of the gate and channel regions, and the source and drain regions are activated by heat treatment at about 1000° C. for about 30 seconds by laser annealing of the present invention with lower irradiation energy than crystallization, or RTA (Rapid Thermal Anneal) with an infrared lamp such as a halogen lamp or the like. Then (or before activation of impurity), the silicon oxide film is formed as the gate insulating film, but the silicon nitride film and the silicon oxide film are continuously formed according to demand. Namely, O₂ diluted with He is mixed with the hydrogen-based carrier gas and monosilane at an appropriate ratio to form the silicon oxide film 8 having a thickness of 40 to 50 nm by the catalytic CVD method, NH₃ is mixed with the hydrogen-based carrier gas and monosilane at an appropriate ratio to form the silicon nitride film having a thickness of 10 to 20 nm according to demand, and the silicon oxide film is further laminated to a thickness of 40 to 50 nm under the same conditions as described above.

Next, as shown in FIG. 4(11), a silicon oxide film 26 is formed in a thickness of, for example, 50 nm under supply of 1 to 2 SCCM of O₂ diluted with helium gas and 15 to 20 SCCM of monosilane, a phosphine silicate glass (PSG) film 28 is formed in a thickness of, for example, 400 nm under supply of 1 to 20 SCCM of PH₃, 1 to 2 SCCM of O₂ diluted with helium, and 15 to 20 SCCM of monosilane, and a silicon nitride film 27 is laminated to a thickness of, for example, 200 nm under supply of 50 to 60 SCCM of NH₃ and 15 to 20 SCCM of monosilane. These films are formed over the entire surface by the same catalytic CVD method as described above using 150 SCCM of common hydrogen-based carrier gas.

Next, as shown in FIG. 4(12), contact holes are formed at predetermined positions of the laminated insulating films. Namely, holes for the gate, source and drain electrodes of nMOSTFTs and pMOSTFTs are formed by the general-purpose photolithography and etching techniques using a photoresist pattern. The silicon nitride film for passivation is etched with plasma of CF₄, SF₆, or the like, the silicon oxide film and the PSG film are etched with a fluoric acid etchant. Then, the photoresist is cleaned off with an organic solvent or the like to expose the gate, source and drain regions of the nMOSTFTs and pMOSTFTs.

Next, an electrode material such as aluminum containing 1% of Si is deposited to a thickness of 1 μm over the entire surface including the contact holes by sputtering at 150° C., and then patterned to form the source or drain regions 29 (S or D) of the pMOSTFTs and nMOSTFTs, and gate leading electrodes or wiring 30 (G), forming the top gate-type CMOSTFTs. Then, hydrogenation and sintering are performed in a forming gas at 400° C. for 1 hour. In this case, an aluminum compound gas (for example, AlCl₃) may be supplied to form aluminum by the catalytic CVD method.

Instead of the above method for forming the gate electrodes, a heat-resistant metal such as a MO—Ta alloy or the like may be formed in a thickness of 100 to 500 nm over the entire surface by sputtering, and then the gate electrodes of the nMOSTFTs and pMOSTFTs may be formed by the general-purpose photolithography and etching techniques.

A description will now be made of an example of manufacture of a top gate-type polycrystalline silicon CMOSTFT by liquid phase growth of a silicon alloy melt and laser annealing of the present invention. First, after the underlying protecting film is formed, an amorphous silicon-containing microcrystal silicon film containing or not containing tin is (deposited) grown by any one of the methods below, and then a low-melting-point metal film of tin or the like formed on the silicon layer is removed.

Coating a low-melting-point metal melt of tin containing silicon, and then cooling.

Dipping in a low-melting-point metal melt of tin containing silicon, and then cooling by pulling up.

Heat-melting a low-melting-point metal film of tin containing silicon, and then cooling.

Forming a low-melting-point metal film of tin on a silicon film, heat-melting the films, and then cooling.

Forming a silicon film on a low-melting-point metal film of tin, heat-melting the films, and then cooling.

Next, the amorphous silicon-containing microcrystal silicon film containing or not containing tin is islanded to be divided into pMOSTFT sections and nMOSTFT sections, and then Vₜₕ is optimized by controlling the impurity concentration of the channel regions by ion implantation or ion doping (according to the above-described conditions).

Next, laser annealing of the present invention is performed for promoting crystallization and activating ions (according to the above-described conditions). Although the silicon oxide film is continuously formed as the gate insulating film by catalytic CVD, the silicon nitride film and silicon oxide film are continuously formed as occasion demands (according to the above-described deposition conditions). The subsequent processes are the same as the above. The method using the liquid phase growth method may be applied to the bottom gate-type and dual gate-type CMOSTFTs described below, etc.

A description will be made of an example of manufacture of a top gate-type polycrystalline silicon CMOSTFT by laser annealing of the low-crystalline silicon film formed by the sputtering method according to the present invention. First, the underlying protective film is formed by sputtering. Namely, a silicon nitride target is sputtered in vacuum under an argon gas pressure of 0.133 to 1.33 Pa to form a silicon nitride film in a thickness of 50 to 200 nm over the entire surface of the insulating substrate, and then a silicon oxide target is sputtered in vacuum under an argon gas pressure of 0.133 to 1.33 Pa to laminate a silicon oxide film in a thickness of 100 to 200 nm over the entire surface of the silicon nitride film.

Next, a silicon target containing or not containing, for example, 0.1 to 1 at % of tin is sputtered in vacuum under an argon gas pressure of 0.133 to 1.33 Pa to form an amorphous silicon film containing or not containing tin in a thickness of 50 nm at least in the TFT formation regions of the insulating substrate.

Next, a silicon oxide target is sputtered in vacuum under an argon gas pressure of 0.133 to 1.33 Pa to form a silicon oxide film in a thickness of 10 to 30 nm over the entire surface of the amorphous silicon film.

These films may be continuously laminated by sputtering a common silicon target using argon gas+nitrogen gas (5 to 10 molar %) for the silicon nitride film, argon gas+oxygen gas (5 to 10 molar %) for the silicon oxide film, argon gas for the amorphous silicon film, and argon gas+oxygen gas (5 to 10 molar %) for the silicon oxide film.

Next, the thus-formed amorphous silicon film containing or not containing tin is islanded to be divided into the PMOSTFT sections and the nMOSTFT sections (according to the conditions for vapor phase growth). Then, the gate channel, source and drain regions are formed by ion implantation or ion doping (according to the conditions for vapor phase growth).

Next, the amorphous silicon film containing or not containing tin is laser-annealed. By laser annealing, the polycrystalline silicon film is formed, and at the same time, the n-type or p-type impurity added by ion implantation or ion doping is activated to obtain the optimum carrier impurity concentrations of the gate channel, source and drain regions. As described above, laser annealing for crystallization, and RTA treatment for ion activation may be separately performed.

Next, the silicon oxide film for protecting and decreasing reflection is removed, and the silicon oxide film is formed as the gate insulating film. However, the silicon nitride film and silicon oxide film are continuously formed according to demand. Namely, the silicon oxide film of 40 to 50 nm in thickness, the silicon nitride film of 10 to 20 nm in thickness and the silicon oxide film of 40 to 50 nm in thickness are continuously formed by the catalytic CVD method or the like (according to the above-described deposition conditions).

The subsequent processes are the same as the above. The method using the sputtered films may be applied to the bottom gate-type and dual gate-type CMOSTFTs described below, etc.

By repeating the formation of the low-crystalline silicon film and laser annealing of the present invention a necessary number of times, a large-grain polycrystalline silicon thick film close to monocrystalline silicon with high crystallinity and high purity can be formed, and thus the thick film is suitable for devices such as a CCD area/linear sensor, a bipolar LSI, a solar cell, etc. Namely, a large-grain polycrystalline silicon thin film of, for example, 200 to 300 nm in thickness is formed by first laser annealing of the present invention. Then, a low-crystalline silicon film is laminated to a thickness of 200 to 300 nm on the polycrystalline silicon thin film. Then, a large-grain polycrystalline silicon thin film of, for example, 200 to 300 nm in thickness is laminated by second laser annealing of the present invention using the underlying film as a seed to form a large-grain polycrystalline silicon film of about 400 to 600 nm in thickness. These steps are repeated a necessary number of times to laminate the large-grain polycrystalline silicon thick film having a thickness of μm unit. This thick film is also included in the idea of “polycrystalline silicon thin film” of the present invention.

In such lamination, the underlying large-grain polycrystalline silicon thin film serves as a crystal nucleus (seed) for laser annealing of the present invention to laminate a polycrystalline silicon thin film having larger grains. It is thus possible to form the large-grain polycrystalline silicon thick film close to monocrystal silicon in which crystallinity and purity increase in the direction nearer to the surface of the thick film. Therefore, the thick film is preferred not only for MOSLSI but also devices requiring a thick film, such as a CCD area/linear sensor, a bipolar LSI, a solar cell, etc., in each of which the surface of the thick film is used for active and passive element regions.

[I] When laser annealing of the present invention is performed after islanding as described above, any one of the following processes (1) to (4) is preferably carried out.

(1) In low-temperature process (A), a low-crystalline silicon film (for example, an amorphous silicon film) with a silicon oxide (SiO₂)/silicon nitride (SiNₓ) laminated film is islanded by patterning. Then, laser annealing of the present invention is performed to form a polycrystalline silicon film, and then only the SiNₓ film is separated. A SiO₂ or SiO₂/SiNₓ film is laminated to form a SiO₂ or SiO₂/SiNₓ/SiO₂ laminated film as the gate insulating film. The low-temperature process means a process using low-strain-point glass such as borosilicate glass, aluminosilicate glass, or the like for the substrate (this applies hereinafter). Also, the silicon nitride film is formed by low-temperature deposition such as plasma CVD or the like, and thus the silicon nitride film is represented by SiNₓ, not a complete formula Si₃N₄ (this applies hereinafter).

(2) In low-temperature process (B), an amorphous silicon film with a SiO₂ (or SiNₓ) film is islanded by pattering, and then changed to a polycrystalline silicon film by laser annealing of the present invention. After only the SiO₂ (or SiNₓ) film is separated, a SiO₂ or SiO₂/SiNₓ/SiO₂ laminated film is formed as the gate insulating film.

(3) In low-temperature process (C), an amorphous silicon film is islanded by pattering. Then, laser annealing of the present invention is performed, and a SiO₂ or SiO₂/SiNₓ/SiO₂ laminated film is formed as the gate insulating film.

(4) In high-temperature process (A), an amorphous silicon film is islanded by patterning, and then subjected to laser annealing of the present invention. Then, the surface of the obtained polycrystalline silicon film is oxidized by thermal oxidation at a high temperature (1000° C., 30 minutes) to form the gate insulating film. The high-temperature process means a process using quartz glass (this applies hereinafter).

[II] When laser annealing of the present invention is performed before islanding, any one of the following processes (1) to (4) is preferably carried out.

(1) In low-temperature process (D), an amorphous silicon film with a SiO₂/SiNₓ laminated film is islanded by patterning after laser annealing of the present invention. Then, only the SiNₓ film is separated, and a SiO₂ or SiO₂/SiNₓ film is laminated to form a SiO₂ or SiO₂/SiNₓ/SiO₂ laminated film as the gate insulating film.

(2) In low-temperature process (E), an amorphous silicon film with a SiO₂ (or SiNₓ) film is islanded by pattering after laser annealing of the present invention. Then, the SiO₂ (or SiNₓ) film is separated, and a SiO₂ or SiO₂/SiNₓ/SiO₂ laminated film is formed as the gate insulating film.

(3) In low-temperature process (F), an amorphous silicon film is islanded by pattering after laser annealing of the present invention. Then, a SiO₂ or SiO₂/SiNₓ/SiO₂ laminated film is formed as the gate insulating film.

(4) In high-temperature process (B), an amorphous silicon film is islanded by patterning after laser annealing of the present invention. Then, the surface of the obtained polycrystalline silicon film is oxidized by thermal oxidation at a high temperature (1000° C., 30 minutes) to form the gate insulating film (using quartz glass).

In both cases [I] and [II], SiO₂ for the low-temperature process is formed by catalytic CVD, plasma CVD, TEOS-system plasma CVD, or the like, and SiNₓ is formed by catalytic CVD, plasma CVD, or the like. As described above, the high-temperature process comprises thermally oxidizing the polycrystalline silicon film by high-temperature thermal oxidation to form a SiO₂ film of high quality. Therefore, it is necessary to form the thick polycrystalline silicon film.

As described above, this embodiment has the following excellent function effects (a) to (1).

(a) The low-crystalline semiconductor thin film such as an amorphous silicon film or the like is heated in a molten, semi-molten, or non-molten state by irradiation with the high-output UV or/and DUV laser beam produced by optical harmonic generation using the nonlinear optical effect, and then cooled to undergo crystallization. Namely, high irradiation energy is applied to the low-crystalline semiconductor thin film by optical harmonic modulated UV or/and DUV laser annealing to heat the thin film in a molten, semi-molten or non-molten state and then cool the film. As a result, a large-grain polycrystalline or monocrystalline semiconductor thin film comprising a polycrystalline silicon film having high carrier mobility and high quality, or the like can be obtained, and productivity is significantly improved to decrease the cost.

(b) In the so-called zone purification method in which the melting zone is moved during laser annealing of the present invention, the catalytic element after its work, which is previously added for promoting crystallization, and other impurity elements are segregated in the high-temperature melting zone, and can easily be removed, and thus these elements do not remain in the film. Thus, a large-grain polycrystalline semiconductor thin film with high carrier mobility and high quality can easily be obtained. Furthermore, in the so-called multi-zone purification method in which the melting zone and cooling zone are continuously repeated by irradiation with a plurality of laser beams, a larger-grain polycrystalline semiconductor thin film with higher quality can be obtained. This purification method can improve stability and reliability of the formed element without deteriorating semiconductor characteristics. Also, the catalytic element after its work of promoting crystallization, and other impurity elements can be effectively removed by the simple zone purification method or multi-zone purification method comprising optical harmonic modulated UV or/and DUV laser annealing, and thus the number of the steps can be decreased to decrease the cost.

(c) Since the crystal grains of polycrystalline silicon or the like are oriented in the laser scanning direction, irregularities in the crystal grain boundaries and stress of the film are decreased when TFTs are formed in this direction, and a polycrystalline silicon film with high carrier mobility can be formed.

(d) The method comprising laminating a low-crystalline silicon film on a polycrystalline silicon film formed by crystallization by the zone purification or multi-zone purification method comprising optical harmonic modulated UV or/and DUV laser annealing, and then crystallizing the low-crystalline silicon film by laser annealing is repeated to laminate a large-grain polycrystalline silicon film having high carrier mobility, high quality and a thickness of μm unit. This enables the formation of not only MOSLSI but also a high-performance and high-quality bipolar LSI, CMOS sensor, CCD area/linear sensor, solar cell, etc.

(e) The optical harmonic modulated UV or/DUV laser can be converged and shaped in a linear, rectangular or square shape, and the laser beam diameter and laser scanning pitch can freely be set by controlling the wavelength, the irradiation strength, the irradiation time, etc. of the laser, thereby improving the irradiation strength, i.e., the melting efficiency and throughput, to decrease cost. Furthermore, a large area (for example, 1 m×1 m) can be annealed by a heat-melting and cooling method (1) in which the fixed substrate is scanned with a laser beam by using a galvanometer scanner, or (2) in which the substrate is moved relative to the fixed laser beam in a step and repeat manner by using a high-precision stepping motor, and further using a plurality of lasers for simultaneous scanning. In this case, a polycrystalline silicon film having any crystal grain diameter and purity can be obtained in a large area, thereby increasing productivity and decreasing cost.

(f) Examples of a light source satisfying the ultraviolet region include a He—Cd (helium-cadmium) laser, an Ar (argon) laser, an excimer laser (argon fluoride (ArF), krypton fluoride (KrF), xenon chloride (SeCl), xenon fluoride (XeF), or the like), and the like. Any one of these lasers has a short wavelength in the ultraviolet region and oscillated by gas discharge. Particularly, the excimer laser uses a dangerous halogen gas with high reactivity as a raw material gas, and thus has the problem of maintenance and handling, etc. Also, the excimer laser has a high exchange rate of the raw material gas and the problem of running cost and work efficiency, consumes much electric power due to its large size, and is expensive. On the other hand, the UV or/DUV laser produced by optical harmonic generation using the nonlinear optical crystal uses, for example, a high-output semiconductor laser excited YAG (Nd:YAG; neodymium-added yttrium aluminum garnet) laser as the fundamental wave, and thus an inexpensive laser device having safety and ease of maintenance, exhibiting stable high output, and consuming less electric power due to its small size can be realized. For example, an annealing device using a laser beam at 355 nm produced by optical harmonic generation from a semiconductor excited solid-state laser such as YAG or the like is more inexpensive than an excimer laser oscillator of an xenon chloride (XeCl: wavelength 308 nm) excimer laser annealing device which is a main stream at present, significantly decreasing cost.

(g) Annealing with an excimer laser of XeCl, KrF, or the like uses a pulse oscillation laser on the nsec order, and thus has the problem of output stability, and causes variations in the energy distribution of the irradiation plane, variations in the obtained semiconductor film, and variations in the element characteristics of TFT. Therefore, a method is used, in which an excimer laser pulse is applied several times such as 5 times, 30 times, or the like under application of a temperature of about 400° C. However, this method also causes variations in the crystallized semiconductor film and the element characteristics of TFT due to variations in irradiation, and deterioration in productivity due to a decrease in throughput, thereby increasing the cost. However, in optical harmonic modulated UV or/and DUV laser annealing, for example, a wavelength of 200 to 400 nm at which an amorphous silicon film exhibits a high efficiency of light absorption can be arbitrarily selected to permit irradiation with a laser beam at a single wavelength with high output, thereby decreasing variations in the energy distribution of the irradiation plane, variations in the obtained semiconductor film, and variations in the element characteristics of TFT. Therefore, productivity can be improved due to high throughput, and the cost can thus be decreased.

(h) The wavelength, the irradiation strength, etc. of the optical harmonic modulated UV or DUV laser used in the present invention can easily be controlled by selecting the fundamental wave and the nonlinear optical crystal, and a combination thereof, and thus, for example, a wavelength of 200 to 400 nm at which an amorphous silicon film exhibits a high efficiency of light absorption can be arbitrarily selected to permit irradiation with a laser beam at a single wavelength with high output. Usable optical harmonic modulated lasers include a near ultraviolet (UV) at 300 to 400 nm, and a deep ultraviolet (DUV) at 200 to 300 nm. In this case, the UV or/and DUV may be generated by optical harmonic modulation using as, the fundamental wave, a laser oscillated by a semiconductor solid-state laser or gas discharge. Examples of near ultraviolet lasers include a ⅓ harmonic at 355 nm of Nd:YAG (wavelength 1064 nm), a ½ harmonic at 316.4 nm of He—Ne (wavelength 632.8 nm), a ⅓ harmonic at 383.3 nm of He—Ne (wavelength 1.15 μm), a ½ harmonic at 347.2 nm of ruby (wavelength 694.3 nm), and the like. Examples of the deep ultraviolet laser include ½ harmonics at 257.8 nm and 244 nm of Ar (wavelengths of 514.5 nm and 488 nm), ½ harmonics at 260.4 nm and 238.1 nm of Kr (wavelengths of 520.8 nm and 476.2 nm), a ½ harmonic at 220.8 nm of He—Cd (wavelength 441.6 nm), and the like.

(i) Furthermore, the irradiation beam can be freely converged and shaped in a linear, rectangular or square shape for laser beam irradiation to decrease variations in the energy distribution of the irradiation plane, variations in the obtained semiconductor film, and variations in the element characteristics of TFT, thereby improving productivity due to a high throughput, and decreasing the cost.

(j) When the low-crystalline semiconductor thin film is crystallized by melting and cooling, for example, with a UV laser beam at a wavelength of 355 nm produced by third harmonic generation, the low-crystalline semiconductor thin film and the substrate can be heated by irradiation with an infrared laser beam as the fundamental wave at a wavelength of 1064 nm, a visible laser beam at a wavelength of 532 nm produced by second harmonic generation, or a mixed laser of the infrared laser beam and the visible laser beam. Therefore, the semiconductor film and the substrate can be sufficiently heated to facilitate secured crystallization. Also, the fundamental wave and the second harmonic can be efficiently used without being discarded, and thus the electric power for heating the substrate by resistance heating or a halogen lamp can be decreased to decrease the power consumption as a whole.

(k) Since optical harmonic modulated UV or/and DUV laser annealing can be performed at a low temperature (200 to 400° C.), low-strain-point glass and a heat-resistant resin, which are inexpensive and can easily realize a large size, can be used, thereby decreasing the weight and cost.

(l) In a bottom gate type or dual gate type MOSTFT as well as a top gate type, a polycrystalline semiconductor film or monocrystalline semiconductor film having high carrier mobility can be obtained. This semiconductor film with high performance can be used for manufacturing a high-speed and high-current-density semiconductor device, an electrooptic device, and a high-efficiency solar cell, etc. Examples of such devices include a silicon semiconductor device, a silicon semiconductor integrated circuit device, a field emission display (FED) device, a silicon-germanium semiconductor device, a silicon-germanium semiconductor integrated circuit device, a liquid crystal display device, an electroluminescence (organic/inorganic) display device, a luminous polymer display device, a light emitting diode display device, an optical sensor device, a CCD area/linear sensor device, a CMOS sensor device, a solar cell device, etc.

### Second Embodiment

<Example 1 of Manufacture of LCD>

In this embodiment, the present invention is applied to a LCD (liquid crystal display) using a polycrystalline silicon MOSTFT formed by the high-temperature process. Examples of the manufacture are described below.

As shown in FIG. 19(1), an underlying protective film 100 (not shown in the drawing) is first formed in the pixel section and the peripheral circuit section of a main surface of a heat-resistant insulating substrate 61 (strain point: 800 to 1100° C., thickness: 50 micron to several mm) made of quartz glass, crystallized glass, or the like by the above-described catalytic CVD method. Then, a low-crystalline silicon film 67A is formed on the underlying protective film 100 by the catalytic CVD method. Furthermore, a silicon oxide film for protecting and decreasing reflection is formed to a thickness of 10 to 30 nm according to demand.

Next, as shown in FIG. 19(2), the low-crystalline silicon film 67A is subjected to the above-described laser annealing to form a polycrystalline silicon film 67 of 50 nm in thickness.

Next, as shown in FIG. 19(3), the silicon oxide film for protecting and decreasing reflection is removed, and then the polycrystalline silicon film 67 is patterned (islanded) by general-purpose photolithography and etching to form active layers for active elements such as transistors, diodes, etc., and passive elements such as resistors, capacitors, inductors, etc. Although the process for manufacturing TFTs is described below, of course, the processes for manufacturing other elements are the same as this process.

Next, in order to optimize Vₜₕ by controlling the impurity concentration of each channel region, the polycrystalline silicon film 67 is doped with a predetermined impurity ion of boron or phosphorus by ion implantation or ion doping, as described above. Then, as shown in FIG. 19(4), a silicon oxide film 68 for a gate insulating film is formed to a thickness of, for example, 50 nm on the surface of the polycrystalline silicon film 67 by the same catalytic CVD method as described above. When the silicon oxide film 68 for the gate insulating film is formed by the catalytic CVD method, the substrate temperature and catalyzer temperature are the same as described above, but the flow rate of O₂ diluted with He may be 1 to 2 SCCM, the flow rate of monosilane may be 15 to 20 SCCM, and the flow rate of the hydrogen-based carrier gas may be 150 SCCM.

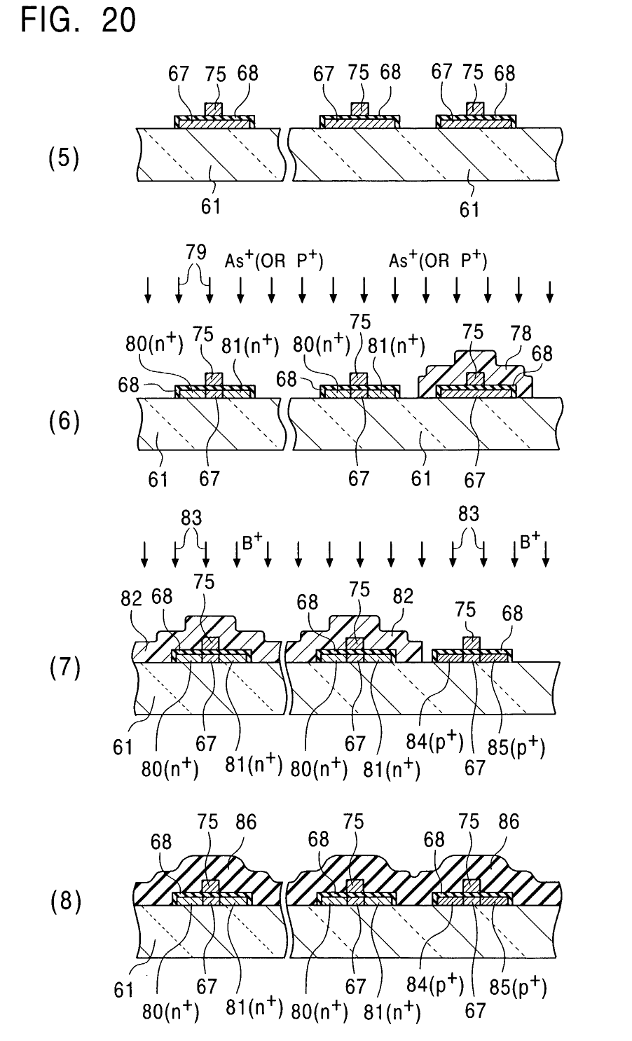

Next, as shown in FIG. 20(5), for example, a Mo—Ta alloy is deposited as a material for gate electrodes and gate lines to a thickness of, for example, 400 nm by sputtering, or a phosphorus-doped polycrystalline silicon film is deposited to a thickness of, for example, 400 nm by the same catalytic CVD method as described above under supply of 150 SCCM of hydrogen-based carrier gas, 2 to 20 SCCM of PH₃, and 20 SCCM of monosilane gas. Then, the gate electrode material layer is patterned in the shapes of gate electrodes 75 and gate lines by general-purpose photolithography and etching. In the case of the phosphorus-doped polycrystalline silicon film, a photoresist mask is removed, and then, a silicon oxide film is formed on the phosphorus-doped polycrystalline silicon film 75 by oxidation at 900° C. for 60 minutes in O₂.

Next, as shown in FIG. 20(6), pMOSTFT sections are masked with a photoresist 78, and doping with a n-type impurity, for example, an arsenic (or phosphorus) ion 79, is performed with a dose of, for example, 1×10¹⁵ atoms/cm² by ion implantation or ion doping to set the donor concentration to 2×10²⁰ atoms/cc, forming n⁺-type source regions 80 and drain regions 81 of nMOSTFT sections.

Then, as shown in FIG. 20(7), the nMOSTFT sections are masked with a photoresist 82, and doping with a p-type impurity, for example, a boron ion 83, is performed with a dose of, for example, 1×10¹⁵ atoms/cm² by ion implantation or ion doping to set the acceptor concentration to 2×10²⁰ atoms/cc, forming p⁺-type source regions 84 and drain regions 85 of the pMOSTFT sections. Then, the doping impurity ion in each of the regions is activated by annealing at about 900° C. for about 5 minutes in N₂ to set each impurity carrier ion.

Next, as shown in FIG. 20(8), by the same catalytic CVD method as described above using 150 SCCM of hydrogen-based carrier gas in common, a silicon oxide film is formed to a thickness of, for example, 50 nm over the entire surface under supply of 1 to 2 SCCM of O₂ diluted with He and 15 to 20 SCCM of monosilane gas, and furthermore a phosphine silicate glass (PSG) film is formed to a thickness of, for example, 400 nm under supply of 1 to 20 SCCM of PH₃, 1 to 2 SCCM of O₂ diluted with He, and 15 to 20 SCCM of monosilane gas. Furthermore, a silicon nitride film is formed to a thickness of, for example, 200 nm under supply of 50 to 60 SCCM of NH₃, and 15 to 20 SCCM of monosilane gas. These insulating films are laminated to form an interlayer insulating film 86. Such an interlayer insulating film may be formed by another conventional method, for example, plasma CVD or the like.

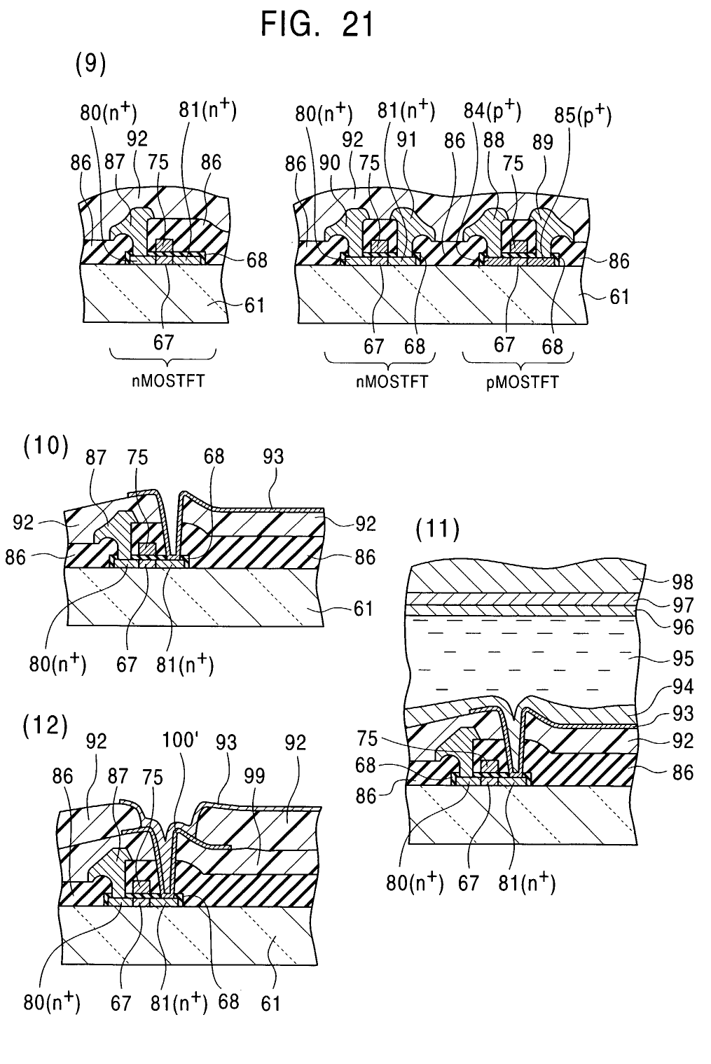

Next, as shown in FIG. 21(9), contact holes are formed at predetermined positions of the insulating film 86, and an electrode material such as aluminum or the like is deposited to a thickness of 1 μm over the entire surface including the contact holes by sputtering or the like. The electrode material is then patterned to form source electrodes 87 of nMOSTFTs and data lines of the pixel section, source electrodes 88 and 90 and drain electrodes 89 and 91 of pMOSTFTs and nMOSTFTs, and wiring in the peripheral circuit section. In this case, aluminum may be deposited by the catalytic CVD method.

Next, an interlayer insulating film 92 such as a silicon oxide film is formed on the surface by CVD, and then hydrogenated and sintered in forming gas at 400° C. for 30 minutes. Next, as shown in FIG. 21(10), contact holes are formed in the interlayer insulating films 92 and 86 in the drain regions of the nMOSTFTs in the pixel section. Then, for example, ITO (Indium Tin Oxide: a transparent electrode material composed of a indium oxide compound doped with tin) is deposited over the entire surface by vacuum deposition or the like, and patterned to form transparent pixel electrodes 93 connected to the drain regions 83 of the nMOSTFTs in the pixel section. Thereafter, heat treatment (at 200 to 250° C. for 1 hour in a forming gas) is performed to decrease contact resistance and improve ITO transparency.

An active matrix substrate (referred to as a “TFT substrate” hereinafter) is manufactured as described above, and a transmissive LCD can be manufactured. The transmissive LCD has a structure in which an alignment film 94, a liquid crystal 95, an alignment film 96, a transparent electrode 97 and a counter substrate 98 are laminated on the pixel electrodes 93, as shown in FIG. 21(11).

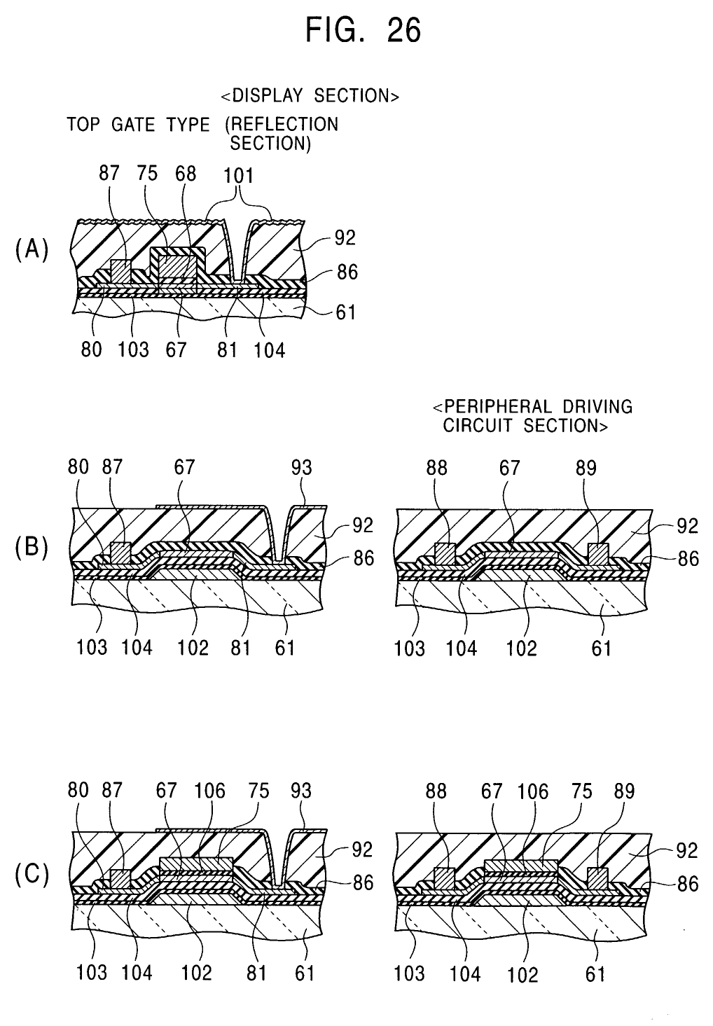

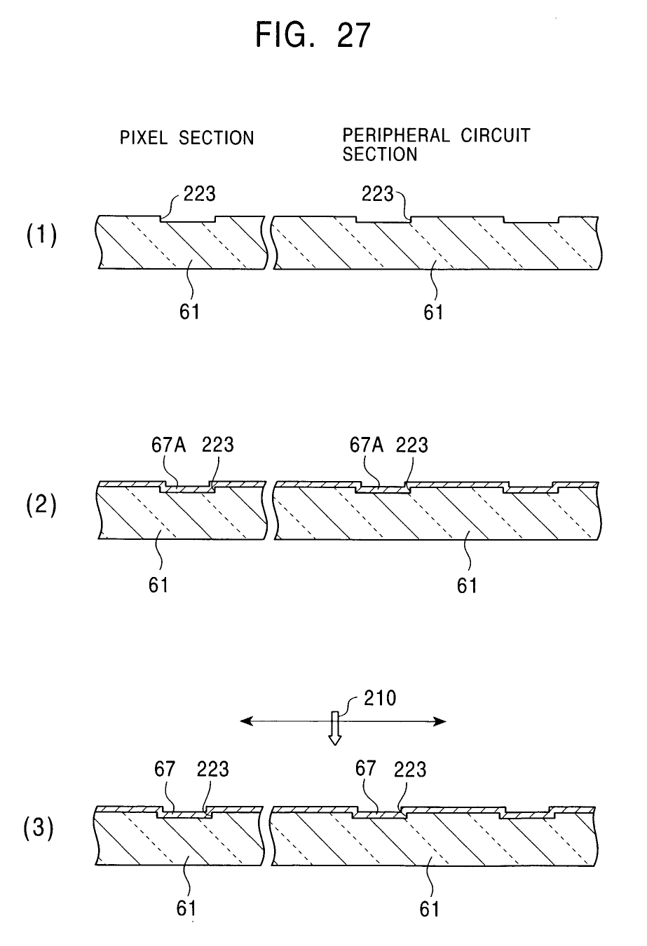

The above-described steps can be applied to the manufacture of a reflective LCD. FIG. 26(A) shows an example of the reflective LCD. In this figure, reference numeral 101 denotes a reflecting film deposited on the roughened insulating film 92, and connected to the drains of the MOSTFTs.

In forming a liquid crystal cell of the LCD by double-face assembly (suitable for a medium/large liquid crystal panel of a 2-inch size), first, polyimde alignment films 94 and 96 are respectively formed on the element formation surfaces of the TFT substrate 61 and the solid counter substrate 98 comprising the ITO (Indium Tin Oxide) electrode 97 provided over the entire surface. The polyimide alignment films are formed to a thickness of 50 to 100 nm by roll coating, spin coating, or the like, and then cured at 180° C. for 2 hours.

Next, each of the TFT substrate 61 and the counter substrate 98 is rubbed or subjected to light orientation. As the rubbing buff material, cotton, rayon, or the like can be used, but cotton is stable from the viewpoint of buff residues (dust) and retardation. Light orientation is a technique for orienting liquid crystal molecules by non-contact linearly polarized ultraviolet irradiation. For orientation, besides rubbing, a polymer alignment film can be formed by oblique incidence of polarized light or unpolarized light (such polymer compounds include polymethyl methacrylate polymers having azobenzene, and the like).

Next, after cleaning, a common agent is coated on the TFT substrate 61, and a sealing agent is coated on the counter substrate 98. The rubbing buff residues are removed by cleaning with water or IPA (isopropyl alcohol). As the common agent, an acryl, epoxyacrylate or epoxy adhesive containing a conductive filler may be used, and as the sealing agent, an acryl, epoxyacrylate or epoxy adhesive may be used. Although any of heat curing, ultraviolet irradiation curing, ultraviolet irradiation curing +heat curing can be used, the ultraviolet irradiation curing/heat curing type is preferred from the viewpoint of purification of alignment, and workability.

Next, in order to obtain a predetermined gap, spacers are scattered on the counter substrate 98, and the TFT substrate 61 and the counter substrate 98 are combined together. After the alignment mark of the TFT substrate 61 is precisely aligned with the alignment mark of the counter substrate 98, the sealing agent is temporarily cured by ultraviolet irradiation, and then fully heat-cured.

Next, a single liquid crystal panel comprising the TFT substrate 61 and the counter substrate 98 bonded together is formed by scriber breaking.

Next, the liquid crystal 95 is injected into the gap between both substrates 61 and 98, and then the injection hole is sealed with an ultraviolet adhesive, followed by IPA cleaning. Any type of liquid crystal can be used, but for example, a TN (twisted nematic) mode using a nematic liquid crystal is generally used.

Next, the liquid crystal 95 is oriented by heating and rapid cooling.

Then, flexible wiring is connected to the panel electrode leading section of the TFT substrate 61 by thermal compression bonding of an anisotropic conductive film, and a polarizer is further bonded to the counter substrate 98.

In a single-face assembly liquid crystal panel (suitable for a small liquid crystal panel of a 2-inch size or less), the polyimide alignment films 94 and 96 are formed on the element formation surfaces of the TFT substrate 61 and the counter substrate 98 by the same method as described above, and both substrates are rubbed or subjected to light orientation by non-contact linearly polarized ultraviolet light.

Next, the TFT substrate 61 and the counter substrate 98 are divided into single panels by dicing or scriber breaking, and then cleaned with water or IPA. Then, the common agent is coated on the TFT substrate 61, and the sealing agent containing spacers is coated on the counter substrate 98. Both substrates are bonded together, and the subsequent process is performed according to the above-described process.

In the LCD, the counter substrate 98 is a CF (color filter) substrate comprising a color filter layer (not shown) provided below the ITO electrode 97. Light incident on the counter substrate 98 may be efficiently reflected by, for example, the reflecting film 93 to be emitted from the counter substrate 98.

On the other hand, when a TFT substrate comprising an on-chip color filter (OCCF) structure in which a color filter is provided on the TFT substrate 61 is used as the TFT substrate 61, the ITO electrode (an ITO electrode with a black mask) is formed on the entire surface of the counter substrate 98.

In the transmissive LCD, the on-chip color filter (OCCF) structure and the on-chip black (OCB) structure can be manufactured as follows.

Namely, as shown in FIG. 21(12), after holes are formed in the drain sections of the phosphine silicate glass/silicon oxide insulating film 86, and an aluminum embedded layer for the drain electrodes is formed, a photoresist 99 in which a pigment for each of R, G and B colors is dispersed in each segment is formed in a predetermined thickness (1 to 1.5 μm). Then, the photoresist 99 is patterned by general-purpose photolithography to leave a predetermined portion (each pixel section), forming color filter layers 99 (R), 99 (G) and 99(B) for respective colors (the on-chit color filter structure). In this case, the holes are also formed in the drain sections. An opaque ceramic substrate and a glass or heat resistant resin substrate having low transmittance cannot be used.

Next, a light shielding layer 100′ serving as a black mask layer is formed in the contact holes communicating with the drains of the display MOSTFTs and on the color filter by metal patterning. For example, molybdenum is deposited to a thickness of 200 to 250 nm by sputtering, and then patterned in a predetermined shape so as to shield the display MOSTFTs from light (the on-chip black structure).

Next, a planarizing film 92 made of a transparent resin is formed, and the ITO transparent electrodes 93 are formed in the through holes formed in the planarizing film so as to be connected to the light shielding layer 100′.

In this way, by forming the color filter 99 and the black mask 100′ on the display array section, the aperture ratio of the liquid crystal display panel can be improved, and low power consumption of a display module including a back light can be realized.

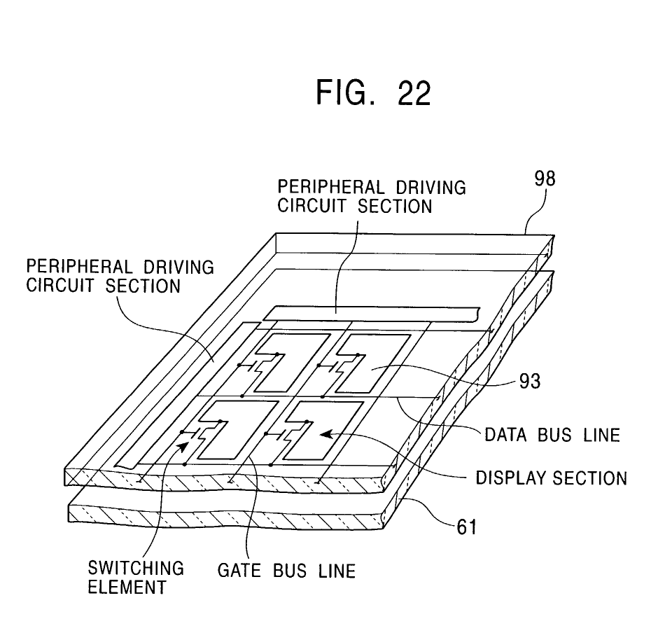

FIG. 22 schematically shows the entire construction of an active matrix liquid crystal display device (LCD) in which the above-described top gate-type MOSTFTs are incorporated to form a type integrated with driving circuits. The active matrix LCD mainly comprises a flat panel structure in which the main substrate 61 (constituting an active matrix substrate) and the counter substrate 98 are bonded together through the spacer (not shown), a liquid crystal (not shown) being sealed between both substrates 61 and 98. The display section comprising the pixel electrodes 93 arranged in a matrix and switching elements for driving the pixel electrodes, and peripheral circuits connected to the display section, such as peripheral driving circuits, video signal processing circuit, a memory, etc., are provided on the surface of the main substrate 61.

Each of the switching elements of the display section comprises a top gate-type MOSTFT having a LDD structure comprising the above nMOS or pMOS, or CMOS. In the peripheral driving circuit sections, the nMOS or pMOS, or CMOS of the top gate-type MOSTFT, or a mixture thereof is formed as a circuit component. One of the peripheral driving circuit sections comprises a horizontal driving circuit for supplying a data signal to drive the MOSTFT of each of the pixels for each horizontal line, and the other peripheral driving circuit section comprises a vertical driving circuit for driving the gate of the MOSTFT of each of the pixels for each scanning line. Both driving circuit sections are provided are generally provided on both sides of the display section. The driving circuits may be either a point-sequential analog system or a line-sequential digital system.

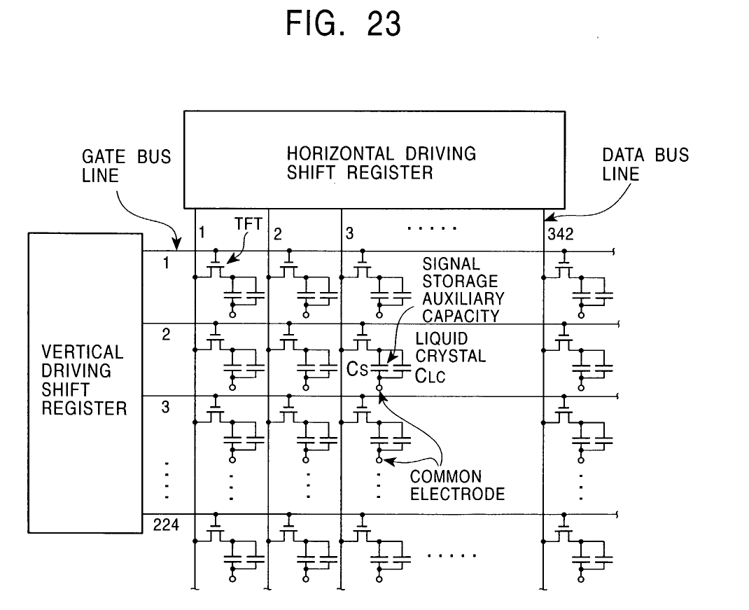

As shown in FIG. 23, the above-described MOSTFT is disposed at each of the intersections of gate bus lines and data bus lines, which across at a right angles, so that image information is written in a liquid crystal capacity (C_{LC}) through the MOSTFT, and electric charge is maintained until next information is supplied. In this case, the charge is not sufficiently maintained only by the channel resistance of MOSTFT, and thus a storage capacity (auxiliary capacity) (Cₛ) may be added in parallel with the liquid crystal capacity, for complementing a decrease in the liquid crystal voltage due to a leakage current. For the MOSTFTs for the LCD, the characteristics required for MOSTFTs used for the pixel section (display section) are different from the characteristics required for MOSTFTs used for the peripheral driving circuits. Particularly, for the MOSTFTs in the pixel sections, it is an important problem to control an off-current and secure an on-current. Therefore, in the display section, the LDD-structure MOSTFTs described below are provided in a structure in which an electric field is less applied between the gate and drain, thereby decreasing the effective electric field and the off-current, and a change in characteristics. However, this structure is complicated from the viewpoint of the process, and thus causes the problem of increasing the element size and decreasing the on-current. Thus, an optimum design according to the purpose of use is required.

Examples of usable liquid crystals include a TN liquid crystal (a nematic liquid crystal used for an active matrix driving TN mode), and liquid crystals of various modes such as STN (super twisted nematic), GH (guest host), PC (phase change), FLC (ferroelectric liquid crystal), AFLC (antiferroelectric liquid crystal), PDLC (polymer dispersed liquid crystal), etc.

<Example 2 of Manufacture of LCD>

A description will be made of an example of manufacture of a LCD (liquid crystal display) using a polycrystalline silicon MOSTFT formed by the low-temperature process according to this embodiment (this example can be applied to the display section of the organic EL and FED described below).

In this example, unlike in the above example 1, low-strain-point glass such as aluminosilicate glass, borosilicate glass or the like is used as the substrate 61, and the same steps as shown in FIGS. 19(1) and (2) are performed. Namely, a polycrystalline silicon film 67 is formed on the substrate 61 by the catalytic CVD and laser annealing of the present invention, and then islanded to form nMOSTFT sections of the display region, and nMOSTFT sections and pMOSTFT sections of the peripheral driving circuit region. In this case, at the same time, the regions such as diodes, capacitors, inductors, resistors, etc. are formed. Although the process for MOSTFTs is described below, of course, the processes for other elements are the same as this.

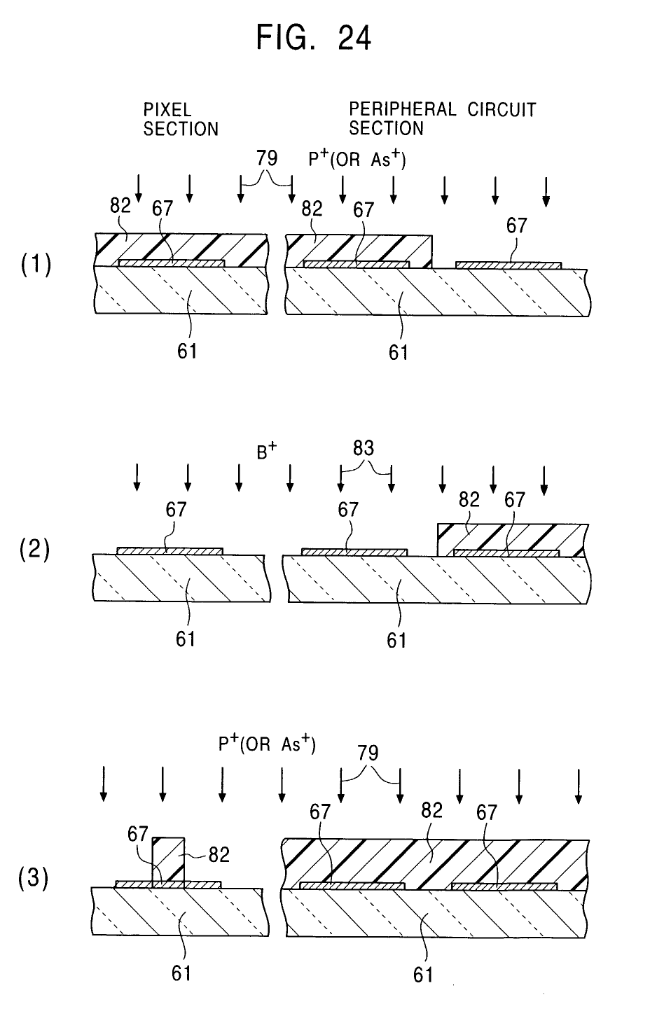

Next, as shown in FIG. 24(1), in order to optimize Vₜₕ by controlling the carrier impurity concentration of each MOSTFT gate channel region, the nMOSTFT sections of the display region and the nMOSTFT sections of the peripheral driving circuit region are covered with a photoresist 82, and the pMOSTFT sections of the peripheral driving circuit region are doped with a n-type impurity, for example, a phosphorus or arsenic ion 79 with a dose of, for example, 1×10¹² atoms/cm² by ion implantation or ion doping to set the donor concentration to 2×10¹⁷ atoms/cc. Furthermore, as shown in FIG. 24(2), the pMOSTFT sections of the peripheral driving circuit region are covered with a photoresist 82, and the nMOSTFT sections of the display region and the nMOSTFT sections of the peripheral driving circuit region are doped with a p-type impurity, for example, a boron ion 83 with a dose of, for example, 5×10¹¹ atoms/cm² by ion implantation or ion doping to set the acceptor concentration to 1×10¹⁷ atoms/cc.

Next, as shown in FIG. 24(3), in order to form n⁻-type LCC (Lightly Doped Drain) sections on the nMOSTFT sections of the display region, for improving the switching property, the nMOSTFT gate sections of the display region and all pMOSTFT and nMOSTFT sections of the peripheral driving circuit region are covered with a photoresist 82, and the exposed nMOSTFT source and drain regions of the display region are doped with a n-type impurity, for example, a phosphorus ion 79 with a dose of, for example, 1×10¹³ atoms/cm² by ion implantation or ion doping to set the donor concentration to 2×10¹⁸ atoms/cc, forming the n⁻-type LCC sections.

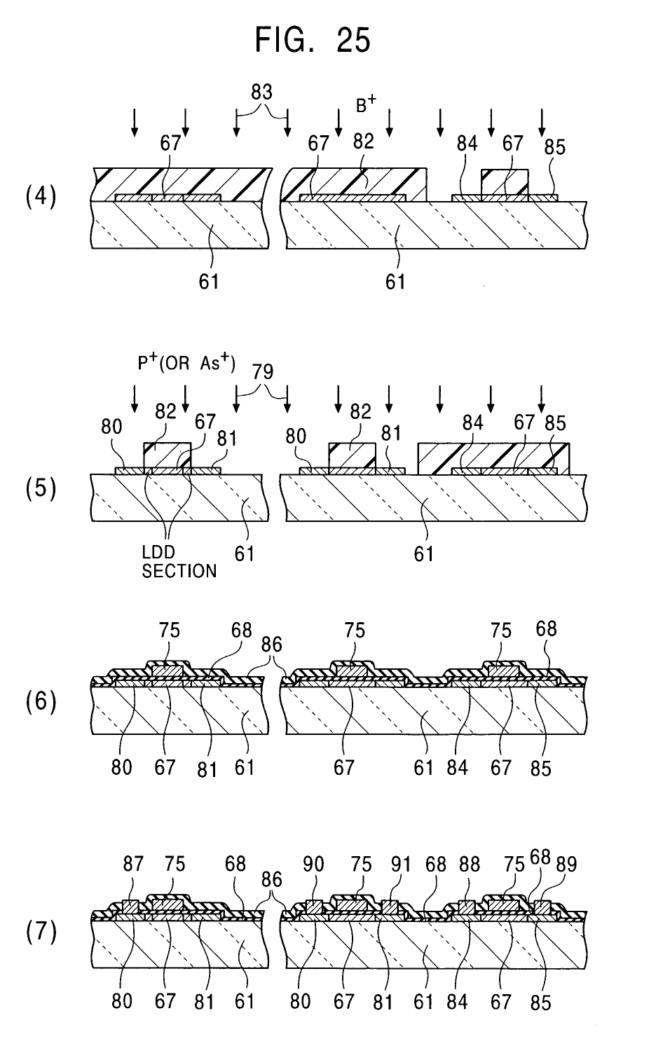

Next, as shown in FIG. 25(4), the nMOSTFT gate sections of the display region and all nMOSTFT sections of the peripheral driving circuit region are covered with the photoresist 82, the pMOSTFT gate sections of the peripheral driving circuit region are covered with the photoresist 82, and the exposed source and drain regions are doped with a p-type impurity, for example, a boron ion 83 with a dose of, for example, 1×10¹⁵ atoms/cm² by ion implantation or ion doping to set the acceptor concentration to 2×10²⁰ atoms/cc, forming the p⁺-type source sections 84 and drain sections 85.

Next, as shown in FIG. 25(5), the pMOSTFT sections of the peripheral driving circuit region are covered with the photoresist 82, the nMOSTFT gate sections and the LDD sections of the display region and the nMOSTFT gate sections of the peripheral driving circuit region are covered with the photoresist 82, and the exposed nMOSTFT source and drain regions of the display region and the peripheral driving circuit region are doped with a n-type impurity, for example, a phosphorus or arsenic ion 79 with a dose of, for example, 1×10¹⁵ atoms/cm² by ion implantation or ion doping to set the acceptor concentration to 2×10²⁰ atoms/cc, forming the n⁺-type source sections 80 and drain sections 81.

Next, as shown in FIG. 25(6), a silicon oxide film of 40 to 50 nm in thickness, a silicon nitride film of 10 to 20 nm in thickness, and a silicon oxide film of 40 to 50 nm in thickness are formed by plasma CVD, TEOS plasma CVD, catalytic CVC, or the like to form a laminated film as the gate insulating film 68. Then, the n- or p-type impurities are activated by RTA treatment with a halogen lamp or the like, for example, at about 1000° C. for 10 to 20 seconds to obtain each of the set carrier impurity concentrations.

Then, an aluminum film containing 1% of Si is formed to a thickness of 400 to 500 nm over the entire surface by sputtering, and the gate electrodes 75 of all MOSTFTs and data lines are formed by general-purpose photolithography and etching. Then, a silicon oxide film of 100 to 200 nm in thickness, a phosphine silicate glass film (PSG) of 200 to 300 nm in thickness, and a silicon nitride film of 50 to 200 nm in thickness are formed by plasma CVD, catalytic CVC, or the like to form a laminated film as an insulating film 68.

Then, holes are formed in the source and drain sections of all MOSTFTs of the peripheral driving circuit region and the source sections of display nMOSTFTs by general-purpose photolithography and etching. The silicon nitride film is treated with plasma etching with CF₄ or the like, and the silicon oxide film and the phosphine silicate glass film are etched with a fluoric acid etchant or the like.

Next, as shown in FIG. 25(7), an aluminum film containing 1% of Si is formed to a thickness of 400 to 500 nm over the entire surface by sputtering, and the source and drain electrodes 88, 89, 90 and 91 of all MOSTFTs of the peripheral driving circuits are formed by general-purpose photolithography and etching. At the same time, the source electrodes 87 of the display MOSTFTs and data lines are formed by general-purpose photolithography and etching.

Although not shown in the drawing, then, a silicon oxide film of 100 to 200 nm in thickness, a phosphine silicate glass film (PSG) of 200 to 300 nm in thickness, and a silicon nitride film of 100 to 300 nm in thickness are formed over the entire surface by plasma CVD, catalytic CVC, or the like, and then hydrogenated and sintered at about 400° C. for 1 hour in a forming gas. Then, contact holes are formed in the drain sections of the display nMOSTFTs.

In the above process, when a hydrogen-containing silicon nitride film (thickness 500 to 600 nm) for passivation is laminated by plasma CVD, hydrogen in the silicon nitride film for passivation can be diffused by hydrogenation at 420° C. for about 30 minutes in a nitrogen of forming gas to improve the interfacial quality, and the carrier mobility can be improved by improving crystallinity at the unbonded terminals of the polycrystalline silicon film. Since the silicon nitride film captures hydrogen, a structure in which the polycrystalline silicon film is sandwiched between silicon nitride films is preferred for increasing the effect of hydrogenation. Namely, like in this embodiment, the structure, glass substrate/Na ion inhibiting and protecting silicon nitride film+silicon oxide film/polycrystalline silicon film/gate insulating film (silicon oxide film)/gate electrode/silicon oxide film and passivation silicon nitride film, is preferred (this applies to other examples). In this case, the aluminum alloy film containing 1% of Si and silicon of the source and drain regions are sintered by hydrogenation to form ohmic contacts.

In the case of the transmissive LCD, the silicon oxide film, the phosphine silicate glass (PSG) film and the silicon nitride film are removed from the apertures of the pixel regions, while in the reflective LCD, the silicon oxide film, the phosphine silicate glass (PSG) film and the silicon nitride film need not be removed from the apertures of the pixel regions (this applies to the above- or below-described LCD).

In the transmissive type, like in the same step as shown in FIG. 21(10), an acryl transparent resin planarizing film of 2 to 3 μm in thickness is formed over the entire surface by spin coating or the like, and holes are formed in the transparent resin on the drain sections of the display MOSTFTs by general-purpose photolithography and etching. Then, an ITO film is formed in a thickness of 130 to 150 nm over the entire surface by sputtering, and the ITO electrodes in contact with the drain sections of the display MOSTFTs are formed by general-purpose photolithography and etching. Furthermore, heat treatment is performed (at 200 to 250° C. for 1 hour in a forming gas) to decrease the contact resistance and improve the ITO transparency.

In the reflective type, a photosensitive resin film of 2 to 3 μm in thickness is formed over the entire surface by spin coating or the like, and an uneven pattern is formed in at least the pixel sections by general-purpose photolithography and etching, and re-flowed to form irregular reflection sections. At the same time, holes are formed in the photoresisive resin in the drain sections of the display nMOSTFTs. Then, an aluminum film sputtered film containing 1% of Si and having a thickness of 300 to 400 nm is formed over the entire surface, and the aluminum film is removed from portions, except the pixel section, by general-purpose photolithography and etching to form the irregular aluminum reflecting sections connected to the drain electrodes of the display nMOSTFTs. Then, sintering is performed at 300° C. for 1 hour in a forming gas.

After the gate channel, source and drain regions of the MOSTFTs are formed, laser annealing of the present invention is performed to locally increase the temperature of the low-crystalline silicon film and promote crystallization, thereby forming the high-quality polycrystalline silicon film having high mobility. At the same time, phosphorus, arsenic or boron ions implanted into the gate channel, source and drain regions are activated to improve productivity in some cases.

<Bottom Gate-Type or Dual Gate-Type MOSTFT>

As the LCD containing the MOSTFTS, an example of a transmissive LCD comprising bottom gate-type or dual gate-type MOSTFTs in place of the top gate type is descried below (this applies to a reflective LCD).

As shown in FIG. 26(B), the bottom gate-type MOSTFTs are provided in the display section and the peripheral section, or as shown in FIG. 24(C), the dual gate-type MOSTFTs are provided in the display section and the peripheral section. Of the bottom gate-type MOSTFTs and the dual gate-type MOSTFTs, particularly the dual gate-type MOSTFTs can improve the driving ability by upper and lower gate sections, and are thus suitable for high-speed switching. Also, either of the upper and lower gate sections is selectively used to enable the dual gate-type MOSTFTs to function as the top gate type or bottom gate type.

In the bottom gate-type MOSTFT shown in FIG. 26(B), reference numeral 102 denotes a gate electrode made of heat resistant Mo/Ta or the like, reference numeral 103 denotes a silicon nitride film, and reference numeral 104 denotes a silicon oxide film, these films forming a bottom gate insulating film. Furthermore, the channel regions are formed on the gate insulating film by using the same polycrystalline silicon film 67 as the top gate-type MOSTFTs. In the dual gate-type MOSTFT shown in FIG. 26(C), the bottom gate section is the same as that of the bottom gate-type MOSTFT, but the top gate section comprises a gate insulating film including a silicon oxide film and a silicon nitride film, and a top gate electrode 75 formed on the gate insulating film. <Manufacture of Bottom Gate-Type MOSTFT>

First, a sputtered film of a heat-resistant Mo/Ta alloy is formed in a thickness of 300 to 400 nm over the entire surface of the glass substrate 61, and taper-etched at 20 to 45 degrees by general-purpose photolithography and etching to form bottom gate electrodes 102 at least in the TFT formation regions as well as gate lines. The glass material is selected in the same manner as the above-described top gate type.

Next, a silicon nitride film 103 and a silicon oxide film 104 serving as a gate insulating film and a protective film, an amorphous silicon-containing microcrystal silicon film 67A containing or not containing tin are formed by vapor phase growth such as plasma CVD, catalytic CVD, or the like. This film 67A is further annealed with the laser in the same manner as described above according to the present invention to form a polycrystalline silicon film 67. The conditions of the vapor phase growth method are same as those for the top gate type. The bottom gate insulating film and the protective silicon nitride film are provided in expectation of the function to stop Na ions from the glass substrate, but these films need not be provided for synthetic quartz glass.

Next, the pMOSTFT and nMOSTFT regions are formed in islands by general-purpose photolithography and etching in the same manner as described above (only one of the p and n types is shown in the drawing), and in order to optimize Vₜₕ by controlling the carrier impurity concentration of each channel region, an appropriate amount of n-type or p-type impurity is mixed by ion implantation or ion doping. Furthermore, in order to form the source and drain region of each MOSTFT, an appropriate amount of n-type or p-type impurity is mixed by ion implantation or ion doping. Then, each impurity is activated by RTA annealing or the like.

The subsequent processes are the same as described above.

<Manufacture of Dual Gate-Type MOSTFT>

Like in the above bottom gate-type, a bottom gate electrode 102, bottom gate insulating films 103 and 104, and a polycrystalline silicon film 67 containing or not containing tin are formed. The bottom gate insulating film and the protective silicon nitride film 103 are provided in expectation of the function to stop Na ions from the glass substrate, but these films need not be provided for synthetic quartz glass.

Next, the pMOSTFT and nMOSTFT regions are formed in islands by general-purpose photolithography and etching in the same manner as described above, and in order to optimize Vₜₕ by controlling the carrier impurity concentration of each channel region, an appropriate amount of n-type or p-type impurity is mixed by ion implantation or ion doping. Furthermore, in order to form the source and drain region of each MOSTFT, an appropriate amount of n-type or p-type impurity is mixed by ion implantation or ion doping.

Then, a silicon oxide film and a silicon nitride film are deposited to form a top gate insulating film 106. The conditions of vapor phase growth are the same as described above. Then, each impurity is activated by RTA annealing or the like.

Then, an aluminum sputtered film containing 1% of Si and having a thickness of 300 to 400 nm is formed over the entire surface, and the top gate electrodes 75 of all MOSTFTs and gate lines are formed by general-purpose photolithography and etching. Thereafter, a silicon oxide film of 100 to 200 nm in thickness, a phosphine silicate glass (PSG) of 200 to 300 nm in thickness, and a silicon nitride film of 100 to 200 nm in thickness are formed by plasma CVD, catalytic CVD, or the like to form a multilayer insulating film 86 comprising these films. Next, holes are formed in the source and drain electrode sections of all MOSTFTs of the peripheral driving circuits, and the source electrode sections of the nMOSTFTs of the display region by general-purpose photolithography and etching.

Next, an aluminum sputtered film containing 1% of Si and having a thickness of 400 to 500 nm is formed over the entire surface, and aluminum electrodes 87 and 88 of the sources and drains of all MOSTFTs of the peripheral driving circuits, aluminum electrodes 89 of the nMOSTFTs of the display section, source line and wiring are formed by general-purpose photolithograph and etching. Then, sintering is performed at 400° C. for 1 hour in a forming gas.

As described above, in this embodiment, like in the first embodiment, Vₜₕ can easily be controlled with high carrier mobility in the gate channel, source and drain regions of the MOSTFTs in the display section and the peripheral driving circuit section of the LCD by the vapor phase growth such as catalytic CVD or plasma CVD and laser annealing of the present invention, and a polycrystalline silicon film with low resistance and a high operation speed can be formed. A liquid crystal display device using the top gate-, bottom gate- or dual gate-type MOSTFT formed by the polycrystalline silicon film can be formed in a structure in which the LDD structure display section with high switching property and low leakage current is integrated with the peripheral circuits such as a high-performance driving circuit, a video signal processing circuit, a memory, etc., thereby permitting the realization of an inexpensive liquid crystal panel with high image quality, high definition, a narrow frame, and high efficiency.

Also, formation at a low temperature (300 to 400° C.) can be performed, and thus low-strain-point glass which facilitates scaling up can be used to decrease the cost. Furthermore, by forming a color filter and a black mask on the array section, the aperture ratio and luminance of the liquid crystal display panel can be improved, and a color filter substrate need not be provided, thereby realizing a decrease in cost due to improvement in productivity.

<Example 3 of Manufacture of LCD>

FIGS. 27 to 29 shows another example of the manufacture of an active matrix LCD.

First, as shown in FIG. 27(1), a photoresist is formed in a predetermined pattern at least in the TFT formation regions of a main surface of an insulating substrate 61 made of borosilicate glass, quartz glass, transparent crystallized glass, or the like, and a plurality of recesses having steps 223, and a proper shape and dimensions are formed in the insulating substrate 61 by irradiation with F⁺ ion of, for example, CF₄ plasma and general-purpose photolithography and etching such as reactive ion etching (RIE) using the photoresist as a mask.

The steps 223 serve as seeds in the subsequent graphoepitaxial growth of monocrystalline silicon described below, and may have a depth d of 0.01 to 0.03 μm, a width w of 1 to 5 μm, and a length (the direction perpendicular to the drawing) of 5 to 10 μm, and a right angle (bottom angle) formed by the bottom side and the side surface. In order to prevent diffusion of Na ions from the glass substrate, a silicon nitride film of 50 to 200 nm in thickness and a silicon oxide film of 300 to 400 nm in thickness may be previously continuously formed on the surface of the insulating film 61, and a plurality of steps having a predetermined shape and dimensions may be formed in the silicon oxide film.

Next, as shown in FIG. 27(2), the photoresist is removed, and then a low-crystalline silicon film 67A containing or not containing tin or nickel is formed in a thickness of, for example, 100 nm over the entire surface including the steps 223 of the main surface of the insulating substrate 61 by catalytic CVD or plasma CVD.

Next, as shown in FIG. 27(3), the low-crystalline silicon thin film 67A is irradiated with a laser beam 210 by laser annealing of the present invention. During melting and cooing in annealing, a monocrystalline silicon thin film 67 can be formed not only in the recesses but also in its peripheral regions in the lateral direction by graphoepitaxial growth using the bottom corners of the recesses 223 as seeds. By repeating laser annealing and deposition of the low-crystalline semiconductor thin film, a monocrystalline semiconductor thick film of μm unit may be formed (this applies hereinafter).

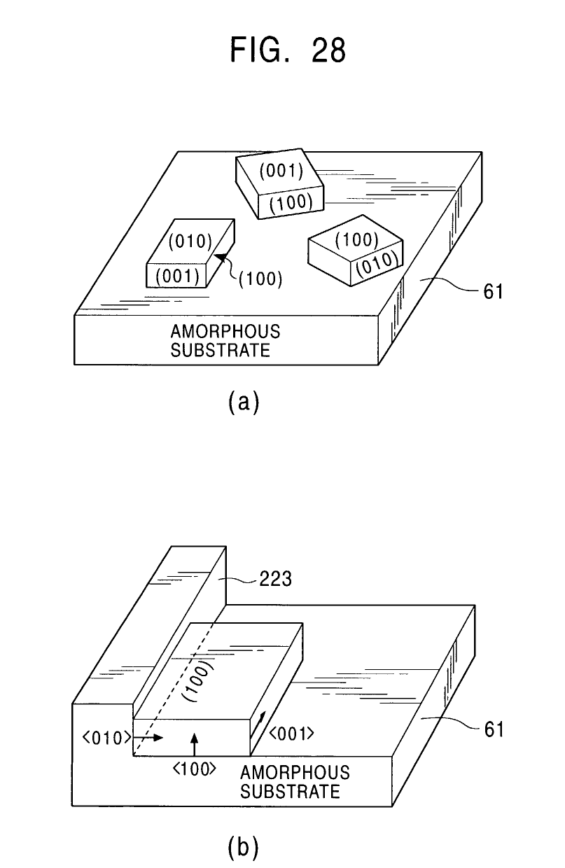

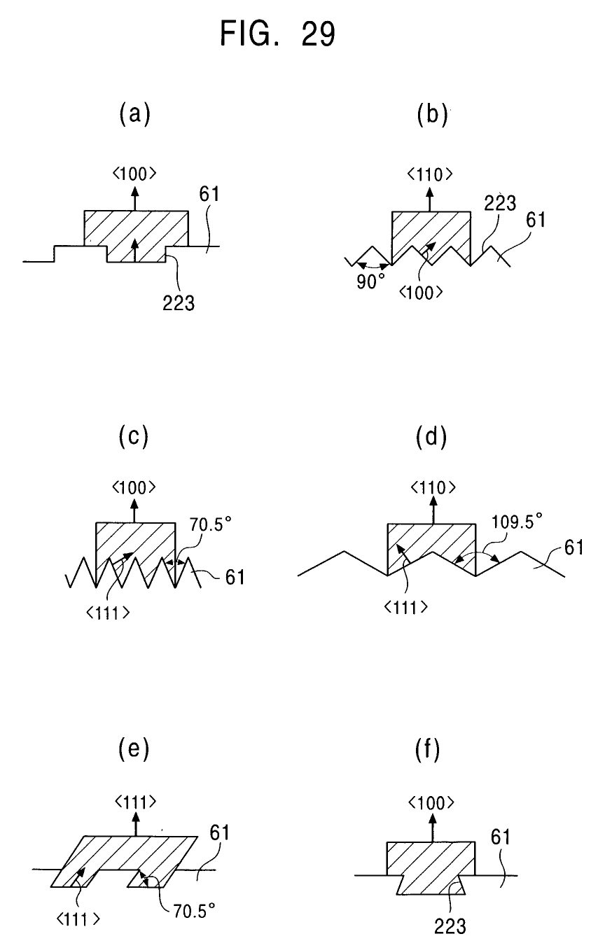

In this way, the monocrystalline silicon thin film 67 is formed by graphoepitaxial growth in a state in which the (100) plane is in contact with the substrate. In this case, the steps 223 serve as the seeds of epitaxial growth with high energy of laser annealing, which is referred to as graphoepitaxial growth, to promote the growth, thereby obtaining the monocrystalline silicon thin film 67 having higher crystallinity and a thickness of about 50 nm. In this epitaxial growth, as shown in FIG. 28, when vertical walls of the steps 223 or the like are formed in the amorphous substrate (glass) 61, and an epitaxial layer is formed on the steps 223, random plane orientation shown in FIG. 28(a) is changed to crystal growth of the (100) plane along the planes of the steps 23, as shown in FIG. 28(b). Also, by changing the shape of the steps 223 to any of the various shapes shown in FIGS. 29(a) to (f), crystal orientation of the grown layer can be controlled. In forming a MOS transistor, the (100) plane is most frequently used. Namely, the sectional shape of the steps 223 may by a shape in which the angle (bottom angle) at the bottom corner is a right angle, or a shape in which the side is inclined inward or outward, and the steps 223 preferably have a plane in a specified direction in which crystal growth easily takes place. The bottom angle of the steps 223 is preferably a right angle of 90° or less, and the corners of the bottom preferably have a slight curvature ratio.

After the monocrystalline silicon film 67 is formed on the insulating substrate 61 by graphoepitaxial growth in laser annealing of the present invention as described above, for example, the top gate-type MOSTFT using the monocrystalline silicon thin film 67 (thickness 50 nm) as an active layer is manufactured by the same method as described above.

As the insulating substrate 61, a heat-resistant resin substrate of polyimide or the like may be used, and the steps 223 having a predetermined shape and dimensions are formed at least in the TFT formation regions of the insulating substrate 61, followed by the same processing as described above. For example, a mold having a projection, for example, having the predetermined dimensions and shape including 0.03 to 0.05 μm, a width of 5 μm, a length of 10 μm is stamped on a polyimide substrate having, for example, a thickness of 100 μm to form recesses having the dimensions and shape reverse to the mold. Alternatively, a heat-resistant resin film (thickness 5 to 10 μm) of polyimide or the like is formed on a metal plate of stainless steel as a reinforcing material by coating, screen printing, or the like, and a mold having predetermined dimensions an shape including a height of 0.03 to 0.05 μm, a width of 5 μm, and a length of 10 μm is stamped on the film to form recesses having dimensions and shape substantially reverse to the mold at least in the TFT formation regions. The same subsequent steps as described above are performed to form the monocrystalline silicon film, MOSTFTs, etc.

As described above, in this embodiment, the recesses having the steps 223 having the predetermined shape and dimensions are provided in the insulating substrate 61, and graphoepitaxial growth is effected by laser annealing of the present invention using the steps 223 as seeds to obtain the monocrystalline silicon thin film 67 with high carrier mobility, thereby permitting the manufacture of a LCD comprising a built-in driver having high performance.

<Example 4 of Manufacture of LCD>

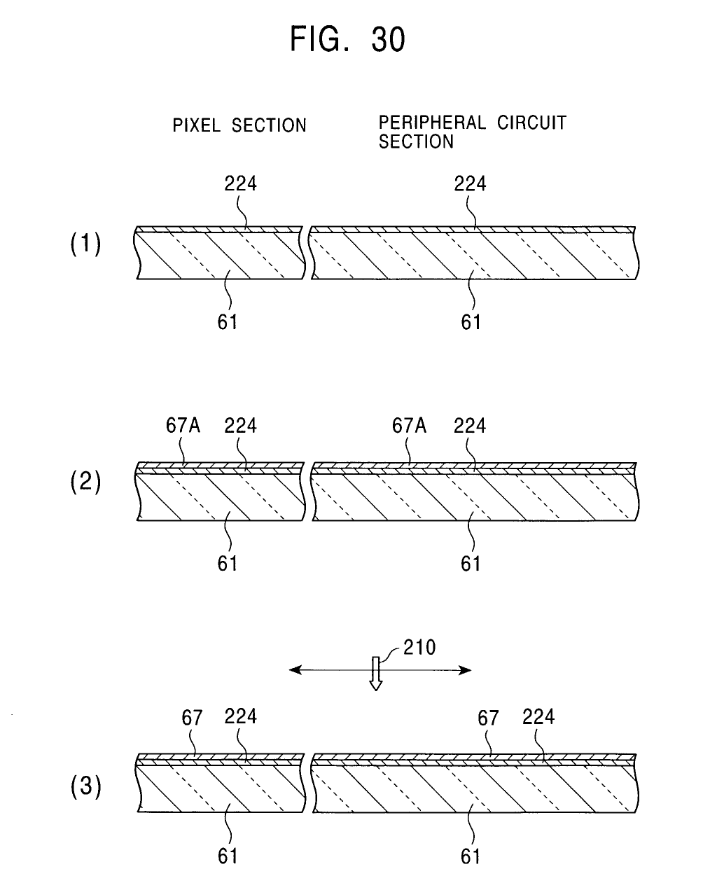

FIG. 30 shows a further example of the manufacture of an active matrix LCD.

First, as shown in FIG. 30(1), a material layer having good lattice matching with monocrystal silicon, for example, a crystalline sapphire thin film 224, is formed in a thickness of 10 to 200 nm at least in the TFT formation regions of a main surface of an insulating substrate 61 made of borosilicate glass, aluminosilicate glass, quartz glass, transparent crystallized glass, or the like. The crystalline sapphire thin film 224 is formed by oxidizing and crystallizing trimethylaluminum gas with an oxidizing gas (oxygen and moisture) by high-density plasma CVD method, a catalytic CVD method, or the like.

Then, as shown in FIG. 30(2), a low-crystalline silicon film 67A is formed in a thickness of, for example, 100 nm on the crystalline sapphire thin film 224 by catalytic CVD, plasma CVD, or the like.

Next, as shown in FIG. 30(3), the low-crystalline silicon thin film 67A is irradiated with a laser beam 210 by laser annealing of the present invention. By melting and slow cooing, a monocrystalline silicon thin film 67 is formed by graphoepitaxial growth using the crystalline sapphire thin film 224 as a seed. Namely, since the crystalline sapphire thin film 224 exhibits good lattice matching with monocrystalline silicon, monocrystalline silicon is effectively hetero-epitaxially grown by laser annealing of the present invention in the state in which for example, the (100) plane is in contact with the substrate. In this case, when the above-described steps 223 are formed so that the crystalline sapphire thin film 224 is formed on a plane including the steps 223, the monocrystalline silicon thin film 67 with higher crystallinity can be obtained by hetero epitaxial growth including graphoepitaxial growth using the steps 223. By repeating laser annealing and deposition of the low-crystalline semiconductor thin film, a monocrystalline semiconductor thick film of μm unit may be formed.

In this way, the monocrystalline silicon thin film 67 is deposited to a thickness of about 50 nm on the insulating substrate 61 by hetero epitaxial growth during laser annealing of the present invention, and then, for example, the top gate-type MOSTFTs using the monocrystalline silicon thin film 67 as an active layer are manufactured by the same method as described above.

As described above, in this embodiment, the monocrystalline silicon thin film 67 with high carrier mobility can be obtained by hetero epitaxial growth in laser annealing of the present invention using, as a seed, the crystalline sapphire thin film 224 provided on the insulating substrate 61, thereby permitting the manufacture of a LCD comprising a built-in driver having high performance.

Also, the material layer such as the crystalline sapphire thin film 224 functions as a diffusion barrier to various atoms, and thus impurity diffusion from the insulating film 61 can be controlled. Since the crystalline sapphire thin film functions as a stopper to Na ions, at least the silicon nitride film of the protective film can be omitted when the crystalline sapphire film is sufficiently thick.

A layer of at least one material selected from the group consisting of a spinel structure, calcium fluoride, strontium fluoride, barium fluoride, boron phosphide, yttrium oxide, and zirconium oxide, which have the same function as the crystalline sapphire film, may be formed instead of the crystalline sapphire film.

### Third Embodiment

In this embodiment, the present invention is applied to an organic or inorganic electroluminescence (EL) display device, for example, an organic EL display device. An example of the structure and an example of manufacture of the organic EL display device are described below. Although, in this embodiment, the top gate-type MOSTFT is used as an example, the bottom gate-type or dual gate-type MOSTFT may be used.

<Example I of Structure of Organic EL Element>

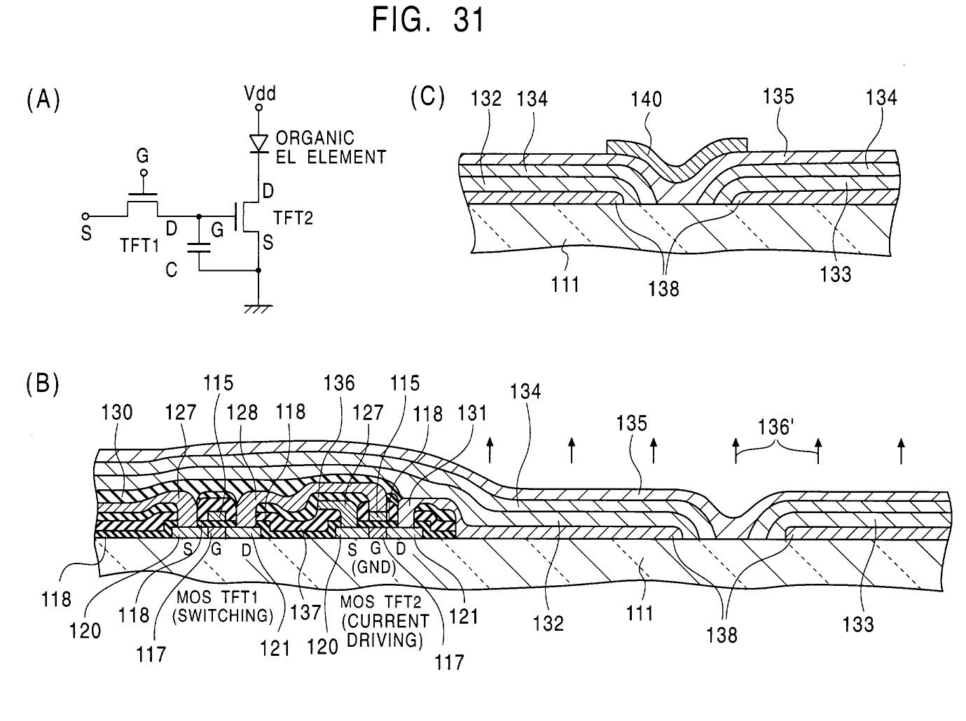

As shown in FIGS. 31(A) and (B), in Example I of the structure, gate channel regions 117, source regions 120 and drain regions 121 of switching MOSTFT 1 and current driving MOSTFT 2 are formed by using a polycrystalline silicon film (or a monocrystalline silicon film) with high crystallinity and a large grain diameter. (Although the polycrystalline silicon film is described below as an example, the monocrystalline silicon film can be used in the same manner.) Also, gate electrodes 115 are formed on a gate insulating film 118, and source electrodes 127 and drain electrodes 128 and 131 are formed on the source and drain regions. The drain of the MOSTFT 1 and the gate of the MOSTFT 2 are connected through the drain electrode 128, and capacitor C is formed between the source electrode 127 of the MOSTFT 2 and the drain of the MOSTFT 1 and the gate of the MOSTFT 2 through an insulating film 126. Furthermore, the drain electrode 131 of the MOSTFT 2 is extended to a cathode 138 of an organic EL element. In this case, a LDD section may be formed in the switching MOSTFT 1 in order to improve the switching property.

Each of the MOSTFTs is covered with an insulating film 130, and the organic EL element, for example, a green organic luminous layer 132 (or a blue organic luminous layer 133, or a red organic luminous layer not shown in the drawing) is formed on the insulating film so as to cover the cathode. Also, an anode (first layer) 134 is formed to cover the organic luminous layer, and a common anode (second layer) 135 is formed over the entire surface. A peripheral driving circuit, a video signal processing circuit, a memory circuit, etc. each comprising a MOSTFT are manufactured in the same manner as the above-described liquid crystal display device.

In the organic EL display section having this structure, the organic EL luminous layer is connected to the drain of the current driving MOSTFT 2, and the cathode (Li—Al, Mg—Ag, or the like) 138 is deposited on the surface of the glass substrate 111, anodes (an ITO film or the like) 134 and 135 being provided on the cathode 138, achieving top light emission 136′. When the MOSTFTs are covered with the cathode, the emission area is increased, and the cathode serves as a light shielding film to prevent emitted light from being incident on the MOSTFTs, thereby preventing a leakage current and deterioration in TFT properties.

Also, when a black mask (chromium, chromium dioxide, or the like) 140 is formed in the periphery of each pixel, as shown in FIG. 31(C), a light leakage (cross talk, or the like) can be prevented, and the contrast can be improved.

In any of the method using color luminous layers of the three colors, green, blue and red in the pixel display section, the method of using a color conversion layer, and the method using a color filter for a while luminescent layer, a good full-color organic EL display device can be realized. Even in the method of spin-coating a polymeric compound as each color luminescent material, or the method of heat-depositing a metal complex in a vacuum, a full-color organic EL section having a long life, high precision, high quality and high reliability can be formed with high productivity, decreasing the coast (this applies hereinafter).

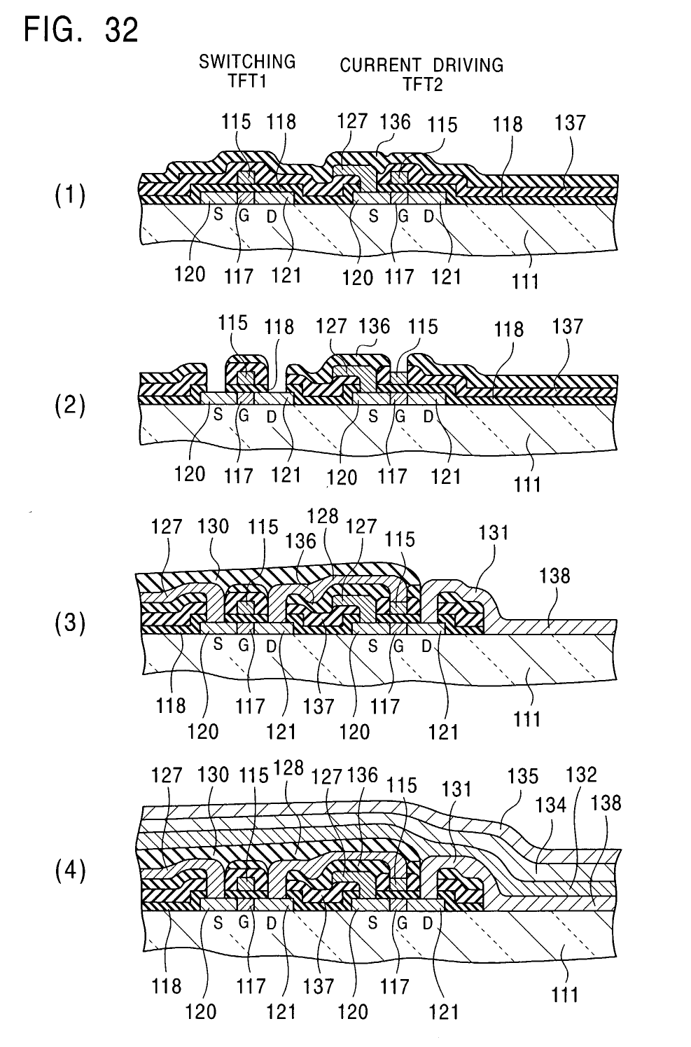

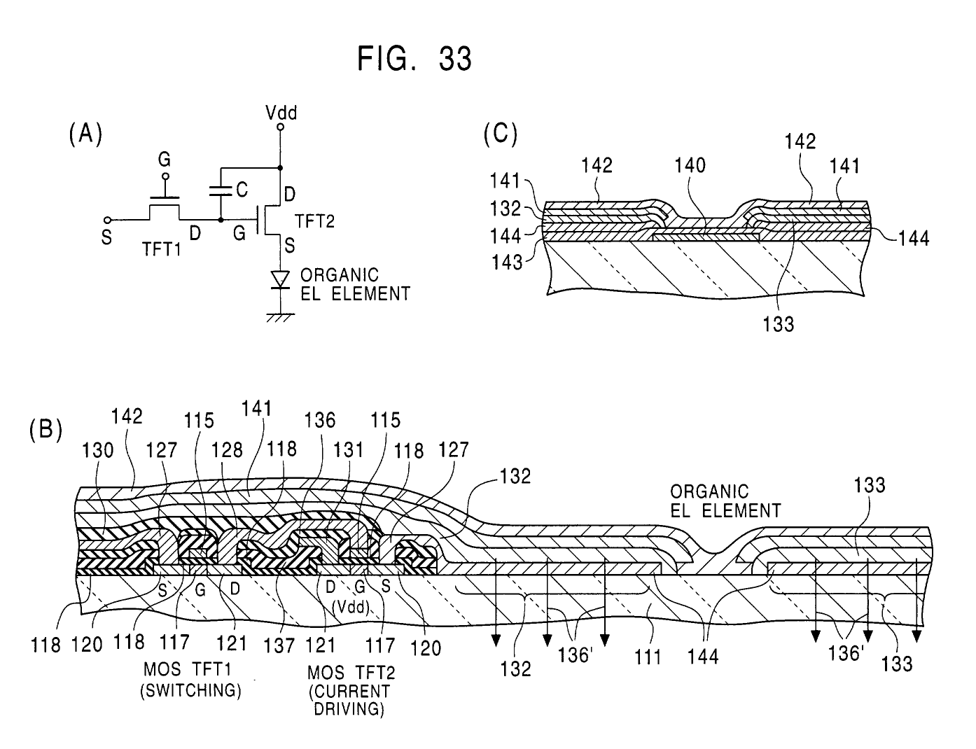

Next, the process for manufacturing the organic EL element will be described. First, as shown in FIG. 32(1), the source regions 120, the channel regions 117 and the drain regions 121 each comprising a polycrystalline silicon film are formed through the above-described steps, and the gate insulating film 118 is formed. Then, the gate electrodes 115 of the MOSTFTs 1 and 2 are formed on the insulating film 118 by sputtering deposition of a Mo—Ta alloy or the like and general-purpose photolithography and etching, and a gate line connected to the gate electrode of the MOSTFT 1 is formed by sputtering deposition and general-purpose photolithography and etching (this applies hereinafter). After an overcoat film (silicon oxide or the like) 137 is then formed by the vapor phase growth method such as catalytic CVD or the like (this applies hereinafter), the source electrode 127 of the MOSTFT 2 and a ground line are formed, and an overcoat film (silicon oxide/silicon nitride laminated film) 136 is further formed. Then, n- or p-impurities as doping ions are activated by RTA (Rapid Thermal Anneal) treatment (for example, at about 1000° C. for 30 seconds) with a halogen lamp or the like.

Then, as shown in FIG. 32(2), holes are formed in the source and drain sections of the MOSTFT 1 and the gate section of the MOSTFT 2, and then as shown in FIG. 32(3), the drain electrode of the MOSTFT 1 is connected to the source electrode of the MOSTFT 2 with Al wiring 128 containing 1% of Si by sputtering Al containing 1% of Si and general-purpose photolithography and etching. At the same time, the source electrode of the MOSTFT 1 and a source line composed of Al containing 1% of Si and connected to the source electrode are formed. Then, an overcoat film (silicon oxide/phosphine silicate glass/silicon nitride) 130 is formed, and a hole is formed in the drain section of the MOSTFT 2. Then, the cathode 138 of luminescent section connected to the drain section of the MOSTFT 2 is formed.

Then, as shown in FIG. 32(4), the organic luminescent layer 132 and the anodes 134 and 135 are formed.

In a conventional active matrix organic EL display device integrated with a peripheral driving circuit, pixels are specified by X-direction signal lines and Y-direction signal lines, and the switching MOSTFT of each of the pixels is turned on to hold image data in a signal holding capacitor. Thus, the current controlling MOSTFT is turned on to pass a bias current through the organic EL element from a power supply line according to the image data to emit light. However, in an amorphous silicon MOSTFT, Vₜₕ varies to easily change the current value, thereby easily causing variations in image quality. Furthermore, a current permitting a drive in high-speed response is limited due to the low carrier mobility, and a p-channel cannot be easily formed to cause difficulties in forming a small-scale CMOS circuit configuration.

However, as described above based on the present invention, a polycrystalline silicon TFT having ease of the formation of a relatively large area and high reliability and high carrier mobility, and permitting the construction of a CMOS circuit can be realized.

In the above description, each of a green (G) luminescent organic EL layer, a blue (B) luminescent organic EL layer and a red (R) luminescent organic EL layer is formed in a thickness of 100 to 200 nm. For these layers, a vacuum heating deposition method is used for a low-molecular compound, and a method of arranging R, G and B luminescent polymers by a coating method such as dipping coating, spin coating, or the like, or an ink jet method is used for a high molecular compound. For a metal complex, a material which can be sublimated is deposited by vacuum heating deposition.

Types of the organic EL layers include a single layer type, a two-layer type, and a three-layer type, but the three-layer type comprising a low molecular compound is described below as an example.

Single-layer type: anode/bipolar luminescent layer/cathode

Two-layer type: anode/hole transport layer/electron transport luminescent layer/cathode or anode/hole transport luminescent layer/electron transport layer/cathode

Three-layer type: anode/hole transport layer/luminescent layer/electron transport layer/cathode or anode/hole transport luminescent layer/carrier block layer/electron transport luminescent layer/cathode

In the element shown in FIG. 31(B), by using a known luminescent polymer instead of the organic luminescent layer, a passive matrix or active matrix driving luminescent polymer display device (LEPD) can be formed (this applies hereinafter).

<Example II of Structure of Organic EL Element>

As shown in FIGS. 33(A) and (B), in Example II of the structure, gate channel regions 117, source regions 120 and drain regions 121 of a switching MOSTFT 1 and a current driving MOSTFT 2 are formed by using a polycrystalline silicon film with high crystallinity and large grain diameter formed by the above-described method based on the present invention. Also, gate electrodes 115 are formed on a gate insulating film 118, and source electrodes 127 and drain electrodes 128 and 131 are formed on the source and drain regions. The drain of the MOSTFT 1 and the gate of the MOSTFT 2 are connected through the drain electrode 128, and capacitor C is formed between the drain electrode 131 of the MOSTFT 2 and the drain of the MOSTFT 1 and the gate of the MOSTFT 2 through an insulating film 126. Furthermore, the source electrode 127 of the MOSTFT 2 is extended to a anode 144 of a organic EL element. In this case, a LDD section may be formed in the switching MOSTFT 1 in order to improve the switching property.

Each of the MOSTFTs is covered with an insulating film 130, and the organic EL element, for example, a green organic luminous layer 132 (or a blue organic luminous layer 133, or a red organic luminous layer not shown in the drawing) is formed on the insulating film so as to cover the anode. Also, a cathode (first layer) 141 is formed to cover the organic luminous layer, and a common cathode (second layer) 142 is formed over the entire surface.

In the organic EL display section having this structure, the organic EL luminescent layer is connected to the source of the current driving MOSTFT 2, and the organic EL luminescent layer is formed to cover the anode 144 deposited the surface of the glass substrate 111, the cathode 141 being formed to cover the organic EL luminescent layer. Also, a cathode 142 is formed over the entire surface to achieve bottom light emission 136′. Furthermore, the cathode is provided between the organic EL luminescent layers and provided to cover the MOSTFTs. Namely, for example, the green luminescent organic EL layer is formed over the entire surface by vacuum heating deposition or the like, and then the green luminescent organic EL sections are formed by photolithography and dry etching. Similarly, the blue and red luminescent organic EL sections are continuously formed, and finally the cathode (electron injection layer) 141 is formed over the entire surface by a magnesium/silver alloy or a magnesium/lithium alloy. Since the cathode (electron injection layer) 142 is further formed over the entire surface, particularly, the cathode 142 deposited over the entire surface prevents moisture from entering between the organic EL layers to prevent deterioration in the organic EL layers weak against moisture and oxidation of the electrodes, thereby achieving a long life, high quality and high reliability (this applies to Example I of the structure shown in FIG. 29 because the entire surface is covered with the anode). Also, the heat radiation effect is improved by the cathodes 141 and 142, and thus a structural change (melting or recrystallization) in the organic EL thin film due to heat generation is decreased to achieve a long life, high quality and high reliability. Furthermore, a full-color organic EL layer with high precision and high quality can be formed with high productivity, thereby decreasing the cost.

When a black mask (chromium, chromium dioxide, or the like) 140 is formed in the periphery of each pixel, as shown in FIG. 33(C), a light leakage (cross talk, or the like) can be prevented, and the contrast can be improved. The black mask 140 is covered with an insulating silicon oxide film 143 (which may be made of the same material as the gate insulating film 181 at the same time).

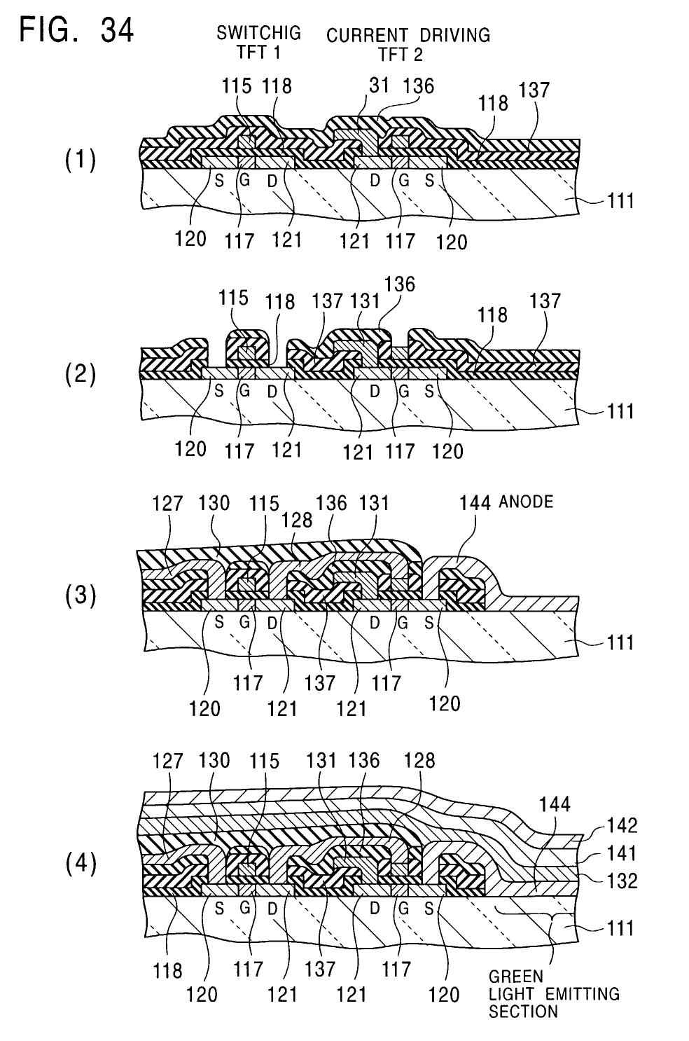

Next, the process for manufacturing the organic EL element will be described. First, as shown in FIG. 34(1), the source regions 120, the channel regions 117 and the drain regions 121 each comprising a polycrystalline silicon film are formed through the above-described steps, and the gate insulating film 118 is formed by the vapor phase growth method such as catalytic CVD or the like. Then, the gate electrodes 115 of the MOSTFTs 1 and 2 are formed on the insulating film 118 by sputtering deposition of a Mo—Ta alloy or the like and general-purpose photolithography and etching, and a gate line connected to the gate electrode of the MOSTFT 1 is formed by sputtering deposition and general-purpose photolithography and etching. After an overcoat film (silicon oxide or the like) 137 is then formed by the vapor phase growth method such as catalytic CVD or the like, the drain electrode 131 of the MOSTFT 2 and a V_{dd} line are formed, and an overcoat film (silicon oxide/silicon nitride laminated film) 136 is further formed by the vapor phase growth method such as catalytic CVD or the like. Then, carrier impurities injected by ion implantation are activated by RTA (Rapid Thermal Anneal) treatment (for example, at about 1000° C. for 10 to 30 seconds) with a halogen lamp or the like.

Then, as shown in FIG. 34(2), holes are formed in the source and drain sections of the MOSTFT 1 and the gate section of the MOSTFT 2 by general-purpose photolithography and etching, and then as shown in FIG. 34(3), the drain electrode of the MOSTFT 1 is connected to the source electrode of the MOSTFT 2 with Al wiring 128 containing 1% of Si by sputtering deposition of Al containing 1% of Si and general-purpose photolithography and etching. At the same time, a source line composed of Al containing 1% of Si and connected to the source electrode of the MOSTFT 1 is formed. Then, an overcoat film (silicon oxide/phosphine silicate glass/silicon nitride) 130 is formed, and a hole is formed in the source section of the MOSTFT 2 by general-purpose photolithography and etching. Then, the anode 144 of the luminescent section connected to the source of the MOSTFT 2 is formed by sputtering ITO and general-purpose photolithography and etching.

Then, as shown in FIG. 34(4), the organic luminescent layer 132 and the cathodes 141 and 142 are formed as described above.

The material and method for forming each of the organic EL layers described above can be applied to the example shown in FIG. 33, and the example shown in FIG. 31.

When a low-molecular compound is used for the green luminescent organic EL layer, the organic EL layer is formed, by continuous vacuum heating deposition, on an ITO transparent electrode formed as an anode (hole injection layer) on the glass substrate in contact with the source of the current driving MOSTFT.

1) A hole transport layer is composed of an amine compound (for example, a triarylamine derivative, arylamine oligomer, aromatic tertiary amine, or the like).

2) A luminescent layer is composed of a green luminescent material such as tris(8-hydroxyxylyno) Al complex (Alq), or the like.

3) An electron transport layer is composed of a 1,3,4-oxadiazole derivative (OXD), a 1,2 4-triazone derivative (TAZ), or the like.

4) An electron injection layer serving as a cathode is preferably made of a material having a work function of 4 eV or more.

For example, a magnesium/silver alloy of 10:1 (atomic ratio) having a thickness of 10 to 30 nm, or an aluminum/lithium (concentration 0.5 to 1%) having a thickness of 10 to 30 nm can be used.

In this case, 1 to 10 atomic % of silver is added to magnesium in order to improve adhesion to the organic interface, and 0.5 to 1% of lithium is applied to aluminum in order to stabilize.

In order to form a green pixel section, the green pixel section is masked with a photoresist, the aluminum/lithium alloy of the electron injection layer serving as the cathode is removed by plasma etching with CCl₄ gas. Then, the low-molecular compounds and the photoresist of the electron transport layer, the luminescent layer and the hole transport layer are continuously removed by oxygen plasma etching to form the green pixel section. In this case, the aluminum/lithium alloy is present below the photoresist, and thus etching of the photoresist causes no problem. The low-molecular compound layers of the electron transport layer, the luminescent layer and the hole transport layer are formed in larger areas than the ITO transparent electrode of the hole injection layer so as to prevent electric short-circuit with the electron injection layer (magnesium/silver alloy) serving as the cathode formed over the entire surface in a subsequent step.

When a low-molecular compound is used for the blue luminescent organic EL layer, the organic EL layer is formed, by continuous vacuum heating deposition, on an ITO transparent electrode formed as an anode (hole injection layer) on the glass substrate in contact with the drain of the current driving MOSTFT.

1) A hole transport layer is composed of an amine compound (for example, a triarylamine derivative, arylamine oligomer, aromatic tertiary amine, or the like).

2) A luminescent layer is composed of a blue luminescent material such as a distyryl derivative, for example, DTVBi, or the like.

3) An electron transport layer is composed of a 1,3,4-oxadiazole derivative (TAZ), a 1,2 4-triazone derivative (TAZ), or the like.

4) An electron injection layer serving as a cathode is preferably made of a material having a work function of 4 eV or more.

For example, a magnesium/silver alloy of 10:1 (atomic ratio) having a thickness of 10 to 30 nm, or an aluminum/lithium (concentration 0.5 to 1%) having a thickness of 10 to 30 nm can be used.

In this case, 1 to 10 atomic % of silver is added to magnesium in order to improve adhesion to the organic interface, and 0.5 to 1% of lithium is applied to aluminum in order to stabilize.

In order to form a blue pixel section, the blue pixel section is masked with a photoresist, the aluminum/lithium alloy of the electron injection layer serving as the cathode is removed by plasma etching with CCl₄ gas. Then, the low-molecular compounds and the photoresist of the electron transport layer, the luminescent layer and the hole transport layer are continuously removed by oxygen plasma etching to form the blue pixel section. In this case, the aluminum/lithium alloy is present below the photoresist, and thus etching of the photoresist causes no problem. The low-molecular compounds layers of the electron transport layer, the luminescent layer and the hole transport layer are formed in larger areas than the ITO transparent electrode of the hole injection layer so as to prevent electric short-circuit with the electron injection layer (magnesium/silver alloy) serving as the cathode formed over the entire surface in a subsequent step. In this case, the blue luminescent organic layers laminated on the green pixel sections and the red pixel sections are removed at the same time as etching.

When a low-molecular compound is used for the red luminescent organic EL layer, the organic EL layer is formed, by continuous vacuum heating deposition, on an ITO transparent electrode formed as the anode (hole injection layer) on the glass substrate in contact with the drain of the current driving TFT.

1) A hole transport layer is composed of an amine compound (for example, a triarylamine derivative, arylamine oligomer, aromatic tertiary amine, or the like).

2) A luminescent layer is composed of a red luminescent material such as Eu(Eu(DBM)₃(Phen)), or the like.

3) An electron transport layer is composed of a 1,3,4-oxadiazole derivative (OXD), a 1,2 4-triazone derivative (TAZ), or the like.

4) An electron injection layer serving as a cathode is preferably made of a material having a work function of 4 eV or more.

For example, a magnesium/silver alloy of 10:1 (atomic ratio) having a thickness of 10 to 30 nm, or an aluminum/lithium (concentration 0.5 to 1%) having a thickness of 10 to 30 nm can be used.

In this case, 1 to 10 atomic % of silver is added to magnesium in order to improve adhesion to the organic interface, and 0.5 to 1% of lithium is applied to aluminum in order to stabilize.

In order to form a red pixel section, the red pixel section is masked with a photoresist, the aluminum/lithium alloy of the electron injection layer serving as the cathode is removed by plasma etching with CCl₄ gas. Then, the low-molecular compounds and the photoresist of the electron transport layer, the luminescent layer and the hole transport layer are continuously removed by oxygen plasma etching to form the red pixel sections. In this case, the aluminum/lithium alloy is present below the photoresist, and thus etching of the photoresist causes no problem. The low-molecular compounds layers of the electron transport layer, the luminescent layer and the hole transport layer are formed in larger areas than the ITO transparent electrode of the hole injection layer so as to prevent electric short-circuit with the electron injection layer (magnesium/silver alloy) serving as the cathode formed over the entire surface in a subsequent step. In this case, the red luminescent organic layers laminated on the green pixel section and the blue pixel section are removed at the same time as etching. Then, the common cathode 142 is formed by the same method using the same material as the cathodes 141.

### Fourth Embodiment

In this embodiment, the present invention is applied to a field emission display device (FED). Examples the structure and manufacture of this display device are described below. Although, in this embodiment, a top gate-type MOSTFT is described as an example, bottom gate-type and dual gate-type MOSTFTs may be used as described above.

<Example I of Structure of FED>

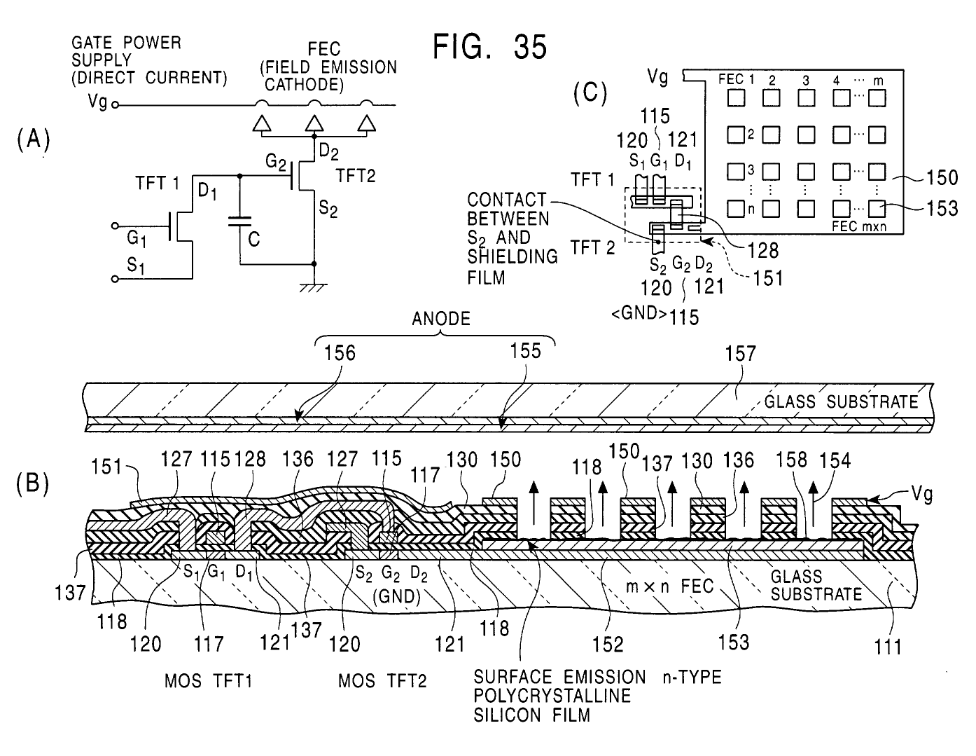

As shown in FIGS. 35(A), (B) and (C), in Example I of the structure, gate channel regions 117, source regions 120 and drain regions 121 of switching MOSTFTs 1 and current driving MOSTFTs 2 are formed on a glass substrate 111 by the above-described method based on the present invention using a polycrystalline silicon film having high crystallinity and a large grain diameter. Also, gate electrodes 115 are formed on a gate insulating film 118, and source electrodes 127 and drain electrodes 128 are formed on the source and drain regions. The drain of the MOSTFT 1 and the gate of the MOSTFT 2 are connected through the drain electrode 128, and capacitor C is formed between the source electrode 127 of the MOSTFT 2 and the drain of the MOSTFT 1 and the gate of the MOSTFT 2 through an insulating film 136. Furthermore, the drain region 121 of the MOSTFT 2 is extended to FEC (field emission cathode) of a FED element to function as an emitter region 152. In this case, a LDD section may be formed in the switching MOSTFT 1 in order to improve the switching property.

Each of the MOSTFTs is covered with an insulating film 130, and a metal shielding film 151 for grounding is formed by the same step using the same material as a FEC gate leading electrode 150 to cover each MOSTFT. In each of the FECs, a n-type polycrystalline silicon film 151 serving as a field emission emitter is formed on the emitter region 152 comprising a polycrystalline silicon film, and the insulating films 118, 137, 136 and 130 are patterned to form apertures for forming m×n emitters. Furthermore, the gate leading electrode 150 is deposited on the insulating films. Also, a substrate 157 such as a glass substrate or the like, on which a fluorescent material 156 with a back metal 155 is formed as an anode is provided for the FECs, the space between the FECs and the substrate 157 being kept in high vacuum.

In the FECs having this structure, a n-type polycrystalline silicon film 153 grown on a polycrystalline silicon film 152 formed based on the present invention is exposed at the bottom of in the apertures of the gate leading electrode 150 to function as the surface emission thin film emitters emitting electrons 154. Namely, the polycrystalline silicon film 152 serving as an underlying layer of the emitters comprises large grains (grain size of several 100 nm or more), and thus the n-type polycrystalline silicon film 153 is grown using the polycrystalline silicon film 152 as a seed by catalytic CVD or the like to grow the polycrystalline silicon film 153 having a larger gain diameter. Therefore, fine irregularities 158 advantageous for electron emission are preferably formed in the surface.

Therefore, since the emitters are of a surface emission type comprising a thin film, and thus the emitters can easily be formed. Also, emitter performance can be improved, and the lifetime can be increased.

Since a metal shielding film 151 at a ground potential is formed on all active elements (including MOSTFTs of the peripheral driving circuits and the pixel display sections, and diodes) (in the same step using the same material as the gate leading electrode 150 (Nb, Ti/Mo, or the like)), the following advantages (1) and (2) can be obtained, and a filed emission display (FED) device with high quality and high reliability can be realized.

(1) The gas contained in an airtight container is positively ionized by electrons emitted from the emitters 153 and charged-up on the insulating layer to form an inversion layer unnecessary to the MOSTFTs below the insulating layer due to the positive charge, and an excessive current flows through an unnecessary current path comprising the inversion layer to cause a runaway of the emitter current. However, the metal shielding film 151 is formed on the insulating film on the MOSTFTs to decrease the potential to the grounding potential, and thus charging up can be prevented to prevent a runaway of the emitter current.

(2) A fluorescent material emits light due to collision of the electrons emitted from the emitters 153, the emitted light produces electrons and holes in the gate channels of the MOSTFTs, causing a leakage current. However, the metal shielding film 151 is formed on the insulating film on the MOSTFTs, and thus light incidence on the TFTs is prevented to cause no operation error in the TFTs.

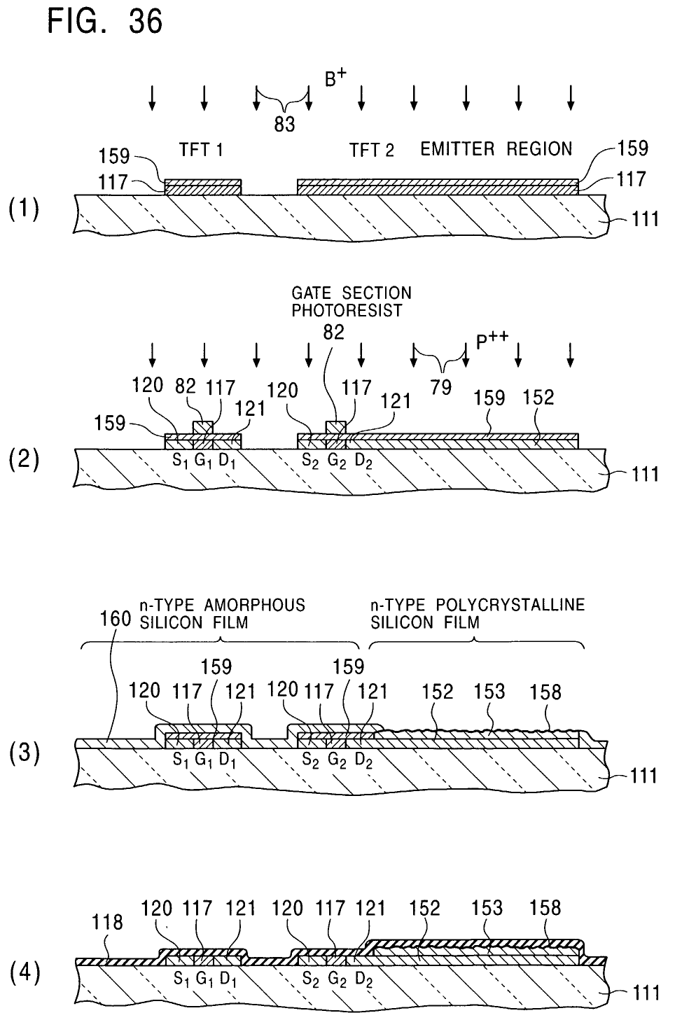

The process for manufacturing the FED is described below. First, as shown in FIG. 36(1), the polycrystalline silicon film 117 is formed over the entire surface through the above-described steps, and then islanded in the MOSTFT 1 and MOSTFT 2, and the emitter region by general-purpose photolithography and etching. Then, a protective silicon oxide film 159 is formed over the entire surface by plasma CVD, catalytic CVD, or the like.

Next, in order to optimize Vₜₕ by controlling the carrier impurity concentration of the gate channel of each of MOSTFTs 1 and 2, the entire surface is doped with a boron ion 83 with a dose of 5×10¹¹ atoms/cm² by ion implantation or ion doping to set the acceptor concentration to 1×10¹⁷ atoms/cc.

Furthermore, as shown in FIG. 36(2), the source and drain sections of the MOSTFTs 1 and 2 and the emitter regions are doped with a phosphorus ion 79 with a dose of 1×10¹⁵ atoms/cm² by ion implantation or ion doping using a photoresist 82 as a mask to set the donor concentration to 2×10²⁰ atoms/cc, forming the source regions 120, the drain regions 121 and the emitter region 152. Then, the protective silicon oxide film is removed from the emitter region by general-purpose photolithography and etching. In this case, a LDD region having a donor concentration of (1 to 5)×10¹⁸ atoms/cc may be formed in the MOSTFT 1 to improve the switching property.

Next, as shown in FIG. 36(3), the n-type polycrystalline silicon film 153 having the surface with fine irregularities 158 is formed in a thickness of 1 to 5 μm in the emitter regions by catalytic CVD or bias catalytic CVD using, as a seed, the polycrystalline silicon film 152 constituting the emitter region and a mixture of monosilane and PH₃ as a dopant at an appropriate ratio (for example, 10²⁰ atoms/cc). At the same time, another silicon oxide film 159, and a n-type amorphous silicon film 160 of 1 to 5 μm in thickness on the glass substrate 111 are formed.

Next, as shown in FIG. 36(4), the amorphous silicon film 160 is etched off with hydrogen active species (active hydrogen ions) in the above-described catalytic AHA treatment, and the silicon oxide film 159 is etched off. Then, the gate insulating film (silicon oxide film) 118 is formed by catalytic CVD or the like.

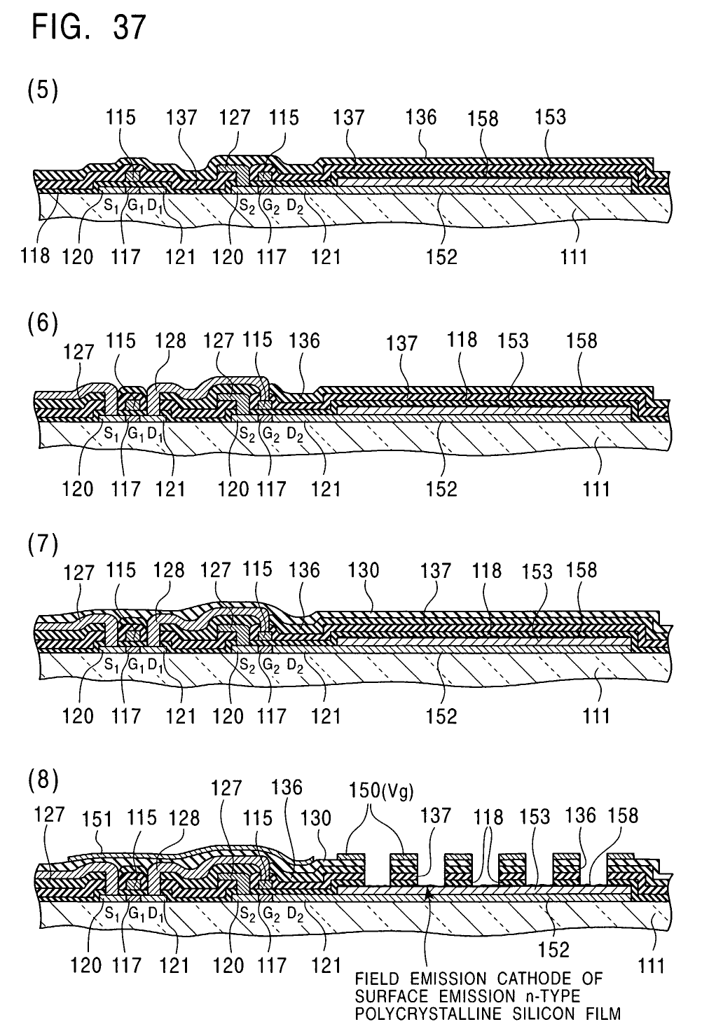

Next, as shown in FIG. 37(5), the gate electrodes 115 of MOSTFTs 1 and 2, and a gate line connected to the gate electrode of the MOATFT 1 are formed by sputtering a heat-resistant metal such as a MO—Ta alloy or the like. After an overcoat film (silicon oxide or the like) 137 is then formed, the n-type and p-type doping impurities are activated by RTA (Rapid Thermal Anneal) using a halogen lamp, and holes are formed in the source and drain sections of the MOSTFT 2. Then, the source electrode 127 of the MOSTFT 2 and a ground line are formed by sputtering a heat-resistant metal such as a MO—Ta alloy or the like. Then, an overcoat film (silicon oxide/silicon nitride laminated film) 136 is formed by plasma CVD, catalytic CVD, or the like.

Then, as shown in FIG. 37(6), holes are formed in the source and drain sections of the MOSTFT 1 and the gate section of the MOSTFT 2, and the gate of the MOSTFTs 2 is connected to the drain of the MOSTFT 1 with Al wiring 128 containing 15 of Si. At the same time, the source electrode of the MOSTFT 1 and the source line 127 connected to the source are formed. Then, hydrogenation and sintering are performed at 400° C. for 30 minutes in a forming gas.

Next, as shown in FIG. 37(7), an overcoat film (silicon oxide/phosphine silicate glass/silicon nitride laminated film) 130 is formed, and then an aperture is formed in a GND line. Then, as shown in FIG. 37(8), the gate leading electrode 150 and the metal shielding film 151 are formed by Nb deposition and etching, and apertures are formed in the field emission cathodes to expose the emitters 153. Then, cleaning is performed with plasma or hydrogen active species (active hydrogen ions) of AHA treatment.

Conventional field emission display (FED) devices are roughly divided into simple matrix driving and active matrix driving. Examples of field emission electron sources (Field Emitter) include a spinto-type molybdenum emitter, a cone-type silicon emitter, a MIM tunnel emitter, a porous silicon emitter, a diamond emitter, a surface conduction emitter, and the like. With any one of these emitters, the emitters can be integrated on the planar substrate. In the simple matrix driving system, a field emitter array arranged in a XY matrix is used as one pixel, and the discharge amount of each pixel is controlled to display an image. In the active matrix driving system, the currents emitted from emitters formed in the drains of the MOSTFTs are controlled by control gates. This is compatible with the process for manufacturing usual silicon LSI, and thus a complex processing circuit can easily be formed in the periphery of the field emission display. However, a silicon monocrystal substrate is used, and thus the substrate cost is increased to cause difficulties in forming a large area of a wafer size or more. Furthermore, it is proposed that a conductive polycrystalline silicon film is produced on the surface of a cathode electrode by low-pressure CVD, and an emitter comprising a crystalline diamond film is produced on the surface of the silicon film by plasma CVD, or the like. However, the deposition temperature in low-pressure CVD is as high as 630° C., and thus a glass substrate cannot be used, thereby difficulties in decreasing cost. Also, the polycrystalline silicon film formed by low-pressure CVD has a small grain diameter, and thus the crystalline diamond film formed on the silicon film has also a small grain diameter, deteriorating the properties of the emitter. Furthermore, reaction energy in plasma CVD is insufficient, and thus a good crystalline diamond film cannot easily be obtained. A transparent electrode or a metal cathode electrode of Al, Ti, Cr, or the like has poor bonding property with the conductive polycrystalline silicon film, and thus good electron emission properties cannot be obtained.

On the other hand, the large-grain polycrystalline silicon film formed based on the present invention can be formed on the glass substrate and used for the emitter region connected to the drain of the current driving TFT. By using the polycrystalline silicon film as a seed, an emitter comprising a n-type (or n⁺-type) large-grain polycrystalline silicon film (which can be grown as a monocrystalline silicon film) (or the polycrystalline diamond film described below) is formed by catalytic CVD, and then an amorphous structure silicon film or amorphous structure diamond film (referred to as “diamond like carbon DLC”) is reduction-etched by catalytic AHA treatment to form a high crystallinity/large grain emitter having innumerable irregularities in its surface. Therefore, an emitter having a high efficiency of electron emission can be formed, and junction between the drain and emitter is improved to achieve emitter properties with high efficiency. Therefore, the above-described problems of conventional devices can be solved (this applies hereinafter).

When the emitter region of each pixel display section is divided into a plurality of portions so that the MOSTFT of a switching element is connected to each portion, even if one of the MOSTFTs is damaged, the other MOSTFTs can be operated. Thus, one of the pixel display sections necessarily emits electrons, thereby improving quality and yield, and decreasing the cost (this applies hereinafter). Although the MOSTFTs having an electric open defect cause no problem, the MOSTFTs causing electric short-circuit are generally separated by laser repair to improve yield. However, the construction based on the present invention can comply with this laser repair, thereby improving yield and decreasing cost (this applies hereinafter).

<Example II of Structure of FED>

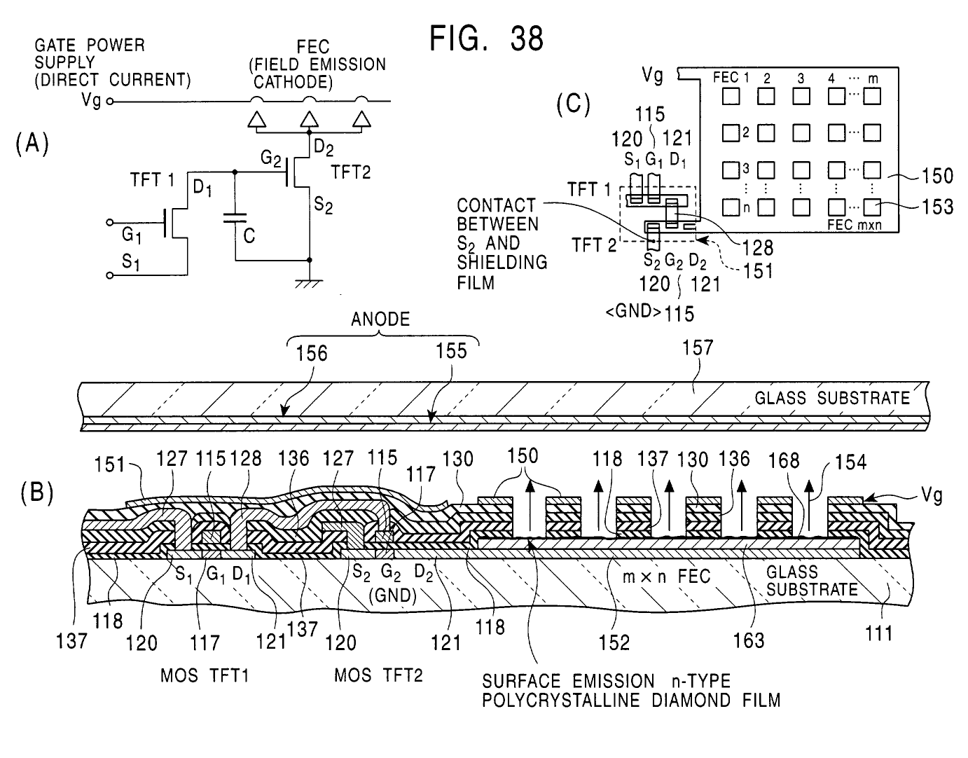

As shown in FIGS. 38(A), (B) and (C), in Example II of the structure, like in Example I of the structure, gate channel regions 117, source regions 120 and drain regions 121 of a switching MOSTFT 1 and a current driving MOSTFT 2 are formed on a glass substrate 111 by the above-described method based on the present invention using a polycrystalline silicon film having high crystallinity and a large grain diameter. Also, gate electrodes 115 are formed on a gate insulating film 118, and source electrodes 127 and drain electrodes 128 are formed on the source and drain regions. The drain of the MOSTFT 1 and the gate of the MOSTFT 2 are connected through the drain electrode 128, and capacitor C is formed between the source electrode 127 of the MOSTFT 2 and the drain of the MOSTFT 1 and the gate of the MOSTFT 2 through an insulating film 136. Furthermore, the drain region 121 of the MOSTFT 2 is extended to FEC (field emission cathodes) of a FED element to function as an emitter region 152. In this case, a LDD section may be formed in the switching MOSTFT 1 in order to improve the switching property.

Each of the MOSTFTs is covered with an insulating film 130, and a metal shielding film 151 for grounding is formed by the same step using the same material as a FEC gate leading electrode 150 to cover each MOSTFT. In each of the FECs, a n-type polycrystalline diamond film 163 serving as a field emission emitter is formed on the emitter region 152 comprising a polycrystalline silicon film, and the insulating films 118, 137, 136 and 130 are patterned to form apertures for forming m×n emitters. Furthermore, the gate leading electrode 150 is deposited on the insulating films.

Also, a substrate 157 such as a glass substrate or the like, on which a fluorescent material 156 with a back metal 155 is formed as an anode is provided for the FECs, the space between the FECs and the substrate 157 being kept in high vacuum.

In the FECs having this structure, a n-type polycrystalline diamond film 163 grown on a polycrystalline silicon film 152 formed based on the present invention is exposed at the bottom of in the apertures of the gate leading electrode 150 to function as the surface emission thin film emitters emitting electrons 154. Namely, the polycrystalline silicon film 152 serving as an underlying layer of the emitters comprises large grains (grain size of several 100 nm or more), and thus the n-type polycrystalline diamond film 163 is grown using the polycrystalline silicon film 152 as a seed by catalytic CVD or the like to grow the polycrystalline diamond film 153 having a larger gain diameter. Therefore, fine irregularities 168 advantageous for electron emission are preferably formed in the surface.

Therefore, since the emitters are of a surface emission type comprising a thin film, and thus the emitters can easily be formed. Also, emitter performance can be improved, and the lifetime can be increased.

Since a metal shielding film 151 at a ground potential is formed on all active elements (including MOSTFTs of the peripheral driving circuits and the pixel display sections, and diodes) (by the same step using the same material as the gate leading electrode 150 (Nb, Ti/Mo, or the like)), the same effects as described above can be obtained. Namely, the metal shielding film 151 is formed on the insulating film on the MOSTFTs to decrease the potential to the grounding potential, and thus charging up can be prevented to prevent a runaway of the emitter current. Also, the metal shielding film 151 is formed on the insulating film on the MOSTFTs, and thus light incidence on the TFTs is prevented to cause no operation error in the TFTs. Thus, a field emission display (FED) device having high quality and high reliability can be realized.

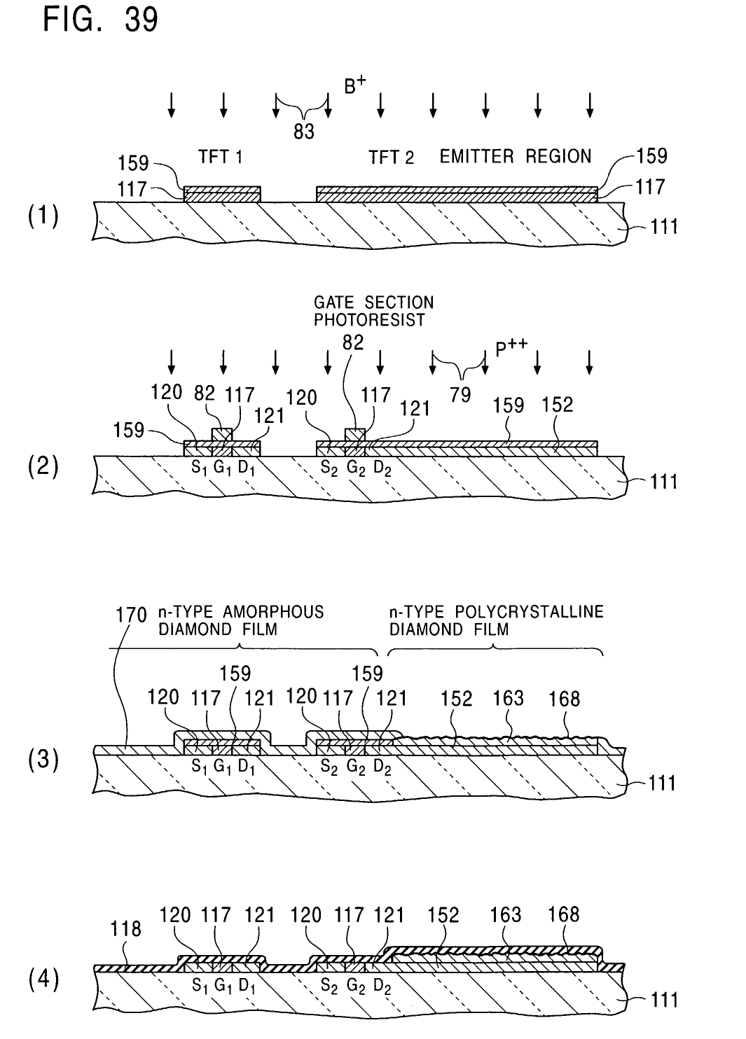

The process for manufacturing the FED is described below. First, as shown in FIG. 39(1), the polycrystalline silicon film 117 is formed over the entire surface through the above-described steps, and then islanded in the MOSTFT 1 and MOSTFT 2, and the emitter region by general-purpose photolithography and etching. Then, a protective silicon oxide film 159 is formed over the entire surface by plasma CVD, catalytic CVD, or the like.

Next, in order to optimize Vₜₕ by controlling the carrier impurity concentration of the gate channel of each of the MOSTFTs 1 and 2, the entire surface is doped with a boron ion 83 with a dose of 5×10¹¹ atoms/cm² by ion implantation or ion doping to set the acceptor concentration to 1×10¹⁷ atoms/cc.

Furthermore, as shown in FIG. 39(2), the source and drain sections of the MOSTFTs 1 and 2 and the emitter region are doped with a phosphorus ion 79 with a dose of 1×10¹⁵ atoms/cm² by ion implantation or ion doping using a photoresist 82 as a mask to set the donor concentration to 2×10²⁰ atoms/cc, forming the source regions 120, the drain regions 121 and the emitter region 152. Then, the protective silicon oxide film is removed from the emitter region by general-purpose photolithography and etching.

Next, as shown in FIG. 39(3), the n⁺-type polycrystalline diamond film 163 having the surface with fine irregularities 168 is formed on the emitter region by catalytic CVD or bias catalytic CVD using, as a seed, the polycrystalline silicon film 152 constituting the emitter region and a mixture of monosilane, methane (CH₄) and a n-type dopant at an appropriate ratio. At the same time, another silicon oxide film 159, and a n⁺-type amorphous diamond film 170 on the glass substrate 111 are formed. For example, the emitter region 163 comprising the n⁺-type polycrystalline diamond film is formed by catalytic CVD using the large-grain polycrystalline silicon film 152 as a seed. In this case, an appropriate amount of n-type impurity gas (phosphine PH₃ as phosphorus, arshin AH₃ as arsenic, stibine SbH₃ as antimony), for example, phosphine PH₃, is added to methane (CH₄) to form the n⁺-type polycrystalline diamond film 163 with a dose of 5×10²⁰ to 1×10²¹ atoms/cc having a thickness of 1000 to 5000 nm. Although the n⁺-type amorphous diamond film 170 is formed on the other protective silicon oxide film, the amorphous diamond film is referred to as a “DLC film (Diamond Like Carbon)”.

Next, as shown in FIG. 39(4), the amorphous diamond film 170 is etched off with hydrogen active species (active hydrogen ions) in the above-described catalytic AHA treatment, and the silicon oxide film 159 is etched off. Then, the gate insulating film (silicon oxide film) 118 is formed by catalytic CVD or the like. In this catalytic AHA treatment, the amorphous diamond film is reduction-etched with high-temperature hydrogen molecules/hydrogen atoms/active hydrogen ions, and at the same time, the amorphous components of the n⁺-type polycrystalline diamond film 163 formed in the emitter regions are reduction-etched to form the n⁺-type polycrystalline diamond film 163 having a high degree of crystallization. By this reduction etching, the emitter region 163 comprising the n⁺-type polycrystalline diamond film having countless irregularities in its surface is formed. Therefore, the n⁺-type amorphous diamond film formed on the other protective silicon oxide film is also reduction-etched and removed. The catalytic CVD and AHA treatment are preferably continuously performed from the viewpoint of prevention of contamination and productivity.

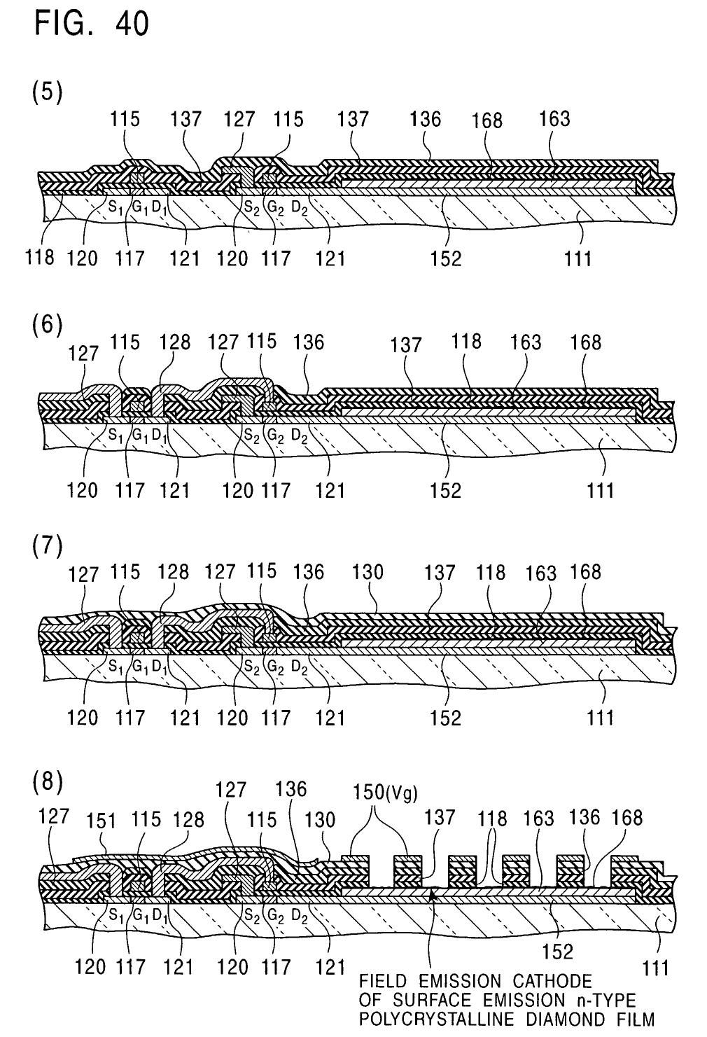

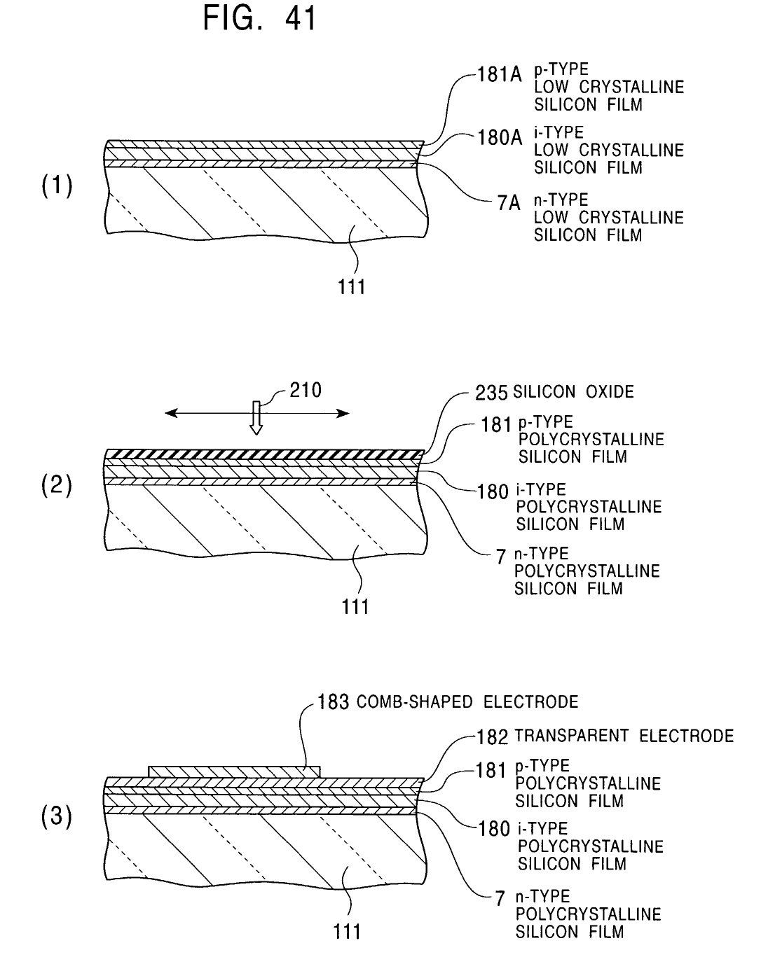

Next, as shown in FIG. 40(5), gate electrodes 115 of MOSTFTs 1 and 2, and a gate line connected to the gate electrode of the MOSTFT 1 are formed by sputtering a heat-resistant metal such as a MO—Ta alloy or the like. After an overcoat film (silicon oxide or the like) 137 is then formed, the n-type and p-type doping impurities are activated by RTA (Rapid Thermal Anneal) using a halogen lamp, and holes are formed in the source and drain sections of the MOSTFT 2. Then, the source electrode 127 of the MOSTFT 2 and a ground line are formed by sputtering a heat-resistant metal such as a MO—Ta alloy or the like. Then, an overcoat film (silicon oxide/silicon nitride laminated film) 136 is formed by plasma CVD, catalytic CVD, or the like.

Then, as shown in FIG. 40(6), holes are formed in the source and drain sections of the MOSTFT 1 and the gate section of the MOSTFTs 2, and the gate of the MOSTFT 2 is connected to the drain of the MOSTFT 1 with Al wiring 128 containing 15 of Si. At the same time, the source electrode of the MOSTFT 1 and the source line 127 connected to the source are formed.

Next, as shown in FIG. 40(7), an overcoat film (silicon oxide/phosphine silicate glass/silicon nitride laminated film) 130 is formed, and then an aperture is formed in a GND line. Then, hydrogenation and sintering are performed in a foaming gas at 400° C. for 30 minutes. Then, as shown in FIG. 40(8), the gate leading electrode 150 and the metal shielding film 151 are formed by Nb deposition and etching, and apertures are formed in the field emission cathodes to expose the emitters 163. Then, cleaning is performed with hydrogen active species (active hydrogen ions) of AHA treatment. Namely, in general-purpose photolithography and etching, the titanium/molybdenum (Ti/Mo) film or niobium (Nb) film is removed by wet etching with an acid etchant, the silicon oxide film and PSG film are removed by wet etching with a fluoric acid etchant, and the silicon oxide film is removed with etching with plasma or CF₄ or the like. Furthermore, the polycrystalline diamond film 163 of the field emission cathodes (emitters) is cleaned by catalytic AHA treatment to remove organic contaminants, moisture, oxygen/nitrogen/carbon dioxide, etc. adhering to the fine irregularities of the film surface by catalytic AHA treatment with high-temperature hydrogen molecules/hydrogen atoms/active hydrogen ions, or the like to improve the efficiency of electron emission.

In the above description, examples of carbon-containing compounds used as a raw material gas for deposition the polycrystalline diamond film 163 include the following.

1) Paraffin hydrocarbons such as methane, ethane, propane, butane, etc.

2) acetylene hydrocarbons such as acetylene, allylene, etc.

3) Olefin hydrocarbons such as ethylene, propylene, butylene, etc.

4) Diolefin hydrocarbons such as butadiene, etc.

5) Alicyclic hydrocarbons such as cyclopropane, cyclobutane, cyclopentane, cyclohexane, etc.

6) Aromatic hydrocarbons such as cyclobutadiene, benzene, toluene, xylene, naphthalene, etc.

7) Ketones such as acetone, diethyl ketone, benzophenone, etc.

8) Alcohols such as methanol, ethanol, etc.

9) Amines such as trimethylamine, triethylamine, etc.

10) Materials composed of only carbon, such as graphite, coal, coke, etc.

These compounds can be used singly or in a combination or at least two compounds.

Examples of usable inert gases include argon, helium, neon, krypton, xenon, radon, and the like. Examples of dopants include compounds and single materials each including boron, lithium, nitrogen, phosphorus, sulfur, chlorine, arsenic, selenium, beryllium, or the like. The dose may be 10²⁰ atoms/cc.

### Fifth Embodiment

In this embodiment, the present invention is applied as a photo-electric conversion device to a solar cell. An example of manufacture of the device is described below.

First, as shown in FIG. 41(1), a n-type low-crystalline silicon film 7A (thickness 100 to 200 nm) is formed on a metal substrate 111 made of stainless steel by plasma CVD, catalytic CVD, or the like. In this case, 1×10^{19 to} 1×10²⁰ atoms/cc of an n-type dopant such as PH₃ is mixed in monosilane.

Then, an i-type low-crystalline silicon film 180A (thickness 2 to 5 μm) is laminated by plasma CVD, catalytic CVD, or the like. Successively, a p-type low-crystalline silicon film 181A (thickness 100 to 200 nm) is formed by plasma CVD, catalytic CVD, or the like. In this case, 1×10¹⁹ to 1×10²⁰ atoms/cc of a p-type dopant such as B₂H₆ is mixed in monosilane.

Then, as shown in FIG. 41(2), a cover insulating film 235 (silicon oxide film, silicon nitride film, silicon oxynitride film or silicon oxide/silicon nitride laminated film) is formed in a thickness of 50 to 100 nm by plasma CVD or catalytic CVD.

In this state, the low-crystalline silicon films 7A, 180A and 181A are modified to polycrystalline silicon films 7, 180 and 181 by laser annealing with laser beam irradiation 210, and at the same time, the impurities in each film are activated.

Next, as shown in FIG. 42(3), the cover insulating film 235 is removed, and hydrogenation is performed in a forming gas at 400° C. for 1 hour. Then, a transparent (ITO (Indium Tin oxide), IZO (Indium Zinc Oxide), or the like) 182 is formed in a thickness of 100 to 150 nm over the entire surface, and a comb-shaped electrode 183 is formed in a thickness of 100 to 150 nm in a predetermined region on the transparent electrode 182 by using a metal mask.

As described above, an appropriate amount, for example, 1×10¹⁸ to 1×10²⁰ atoms/cc of catalytic element such as Ni, Sn or the like may be added to each of the low-crystalline silicon films 7A, 180A and 181A to promote crystallization. In the zone purification method or multi-zone purification method, of course, such a catalytic element preferably does not remain in the polycrystalline silicon films.

In a solar cell of this embodiment, a photo-electric conversion thin film having high mobility and high efficiency of conversion can be formed by a large-grain polycrystalline silicon film based on the present invention, and thus a good surface texture and back texture structures are formed, thereby forming a photo-electric conversion thin film having a high light-capturing effect and high efficiency of conversion. This can also be advantageously used for the thin film photo-electric conversion devices of not only the solar cell but also an electrophotographic photosensitive drum, etc.

The above-described embodiments of the present invention can be changed to various embodiments based on the technical idea of the present invention.

For example, various conditions such as the number of times of the vapor phase growth such as plasma CVD or the like, and laser annealing of the present invention, the laser beam irradiation time, the substrate temperature, etc. may be changed, and the material of the substrate used is not limited to the above described materials.

Although the present invention is preferably applied to MOSTFTs of internal circuits of a display section, peripheral driving circuits, a video signal processing circuit, and memory, etc. a polycrystalline semiconductor or monocrystalline semiconductor film of the present invention can also be used for forming active regions of elements such as diodes, and passive regions such as resistors, capacitors, wiring, inductors, etc.

As described above, in the present invention, a low-crystalline semiconductor thin film is formed on a substrate, and then heated in a molten, semi-molten or non-molten state by annealing with a optical harmonic modulated UV or/and DUV and cooled to promote crystallization of the low-crystalline semiconductor thin film, thereby forming a polycrystalline or monocrystalline semiconductor thin film. Therefore, the following remarked functions and effects (1) to (12) can be obtained.

(1) The low-crystalline semiconductor thin film such as an amorphous silicon film or the like is heated in a molten state, a semi-molten state or non-molten state by irradiation with a high-output UV or/and DUV laser beam formed by optical harmonic generation using a non-linear optical effect, and cooled to crystallize the thin film. Namely, high irradiation energy is applied to the low-crystalline semiconductor thin film by annealing with an optical harmonic modulated UV or/and DUV laser to heat the semiconductor thin film in a molten, semi-molten or non-molted state and cool the thin film to obtain the polycrystalline silicon or monocrystalline semiconductor thin film, such as a polycrystalline silicon film, having a large grain diameter, high carrier mobility and high quality, thereby significantly improving productivity to permit a significant decrease in cost.

(2) In laser annealing of the present invention, a catalytic element such as Ni or the like after its work of promoting crystallization, which is previously added for promoting crystallization, and other impurity elements are segregated in a high-temperature melting zone by a so-called zone purification method in which the heating zone is moved, and thus these elements can easily be removed. Therefore, the elements do not remain in the film, and thus the polycrystalline semiconductor thin film having a large grain diameter, high carrier mobility and high quality can easily be obtained. Furthermore, by a so-called multi-zone purification method comprising continuously repeating a melting zone and a cooling zone by irradiation with a plurality of laser beams, the polycrystalline semiconductor thin film having a larger grain diameter and higher quality can be obtained. This high purification method causes no deterioration in semiconductor properties, and thus improves stability and reliability of the element formed. Also, a simple process such as the zone purification method or multi-zone purification method comprising annealing with an optical harmonic modulated UV or/and DUV laser can efficiently remove the catalytic element after it work of promoting crystallization and other elements to decrease the number of the steps, permitting a decrease in cost.

(3) Since the crystal grains of polycrystalline silicon or the like are oriented in the laser scanning direction, irregularity and stress of the crystal grain boundaries can be decreased when TFTs are in this direction, and a polycrystalline silicon film or the like having high mobility can be formed.

(4) A low-crystalline silicon film or the like is laminated on a polycrystalline silicon film or the like, which is crystallized by the zone purification method or multi-zone purification method comprising annealing with an optical harmonic modulated UV or/and DUV laser, and laser annealing is again performed to crystallize the silicon film. This method is repeated to permit the lamination of polycrystalline silicon films having a thickness of μm unit, a large grain diameter, high carrier mobility and high quality. This enables the formation of not only MOSLSI but also a bipolar LSI, a CMOS sensor, a CCD area/linear sensor, a solar cell, etc. with high performance and high quality.

(5) The wavelength, irradiation strength and irradiation time, etc. of the optical harmonic modulated UV or/DUV laser can easily be controlled, and the optical harmonic modulated UV or/DUV laser can be converged and shaped in a linear, rectangular or square shape to freely set the laser beam diameter, the laser scanning pitch, etc., thereby permitting an attempt to improve the irradiation strength, i.e., melting efficiency, and throughput, decreasing cost. Furthermore, by a heating and cooling method comprising (i) scanning a fixed substrate with a laser beam by galvanometer scanning, or (ii) moving the substrate relative to a fixed laser beam in a step and repeat manner using a high-precision stepping motor, and a method of synchronously scanning the substrate with a plurality of lasers, a large area (for example, 1 m×1 m) can be annealed within a short time. Therefore, a polycrystalline silicon film or the like having any desired crystal grains and purity can be obtained over a large area, thereby improving productivity and decreasing the cost.

(6) The UV or/and DUV laser formed by harmonic generation using a non-linear optical crystal is mainly formed from a high-output semiconductor laser excited YAG (Nd:YAG; neodymium-added yttrium aluminum garnet) laser as a fundamental wave, and thus has safety and ease of maintenance. Therefore, an inexpensive small laser device producing stable high output with low power consumption is realized.

(7) Any desired light at a wavelength of 200 to 400 nm, at which for example, an amorphous silicon film exhibits high absorption efficiency, can be selected for optical harmonic modulated UV or/and DUV laser annealing, and thus high-output single-wavelength laser beam annealing can be performed, thereby decreasing variation in the energy distribution on the irradiation surface, variation in the obtained crystallized semiconductor film, and variation in the element properties of each TFT. Therefore, the cost can be decreased with high throughput and high productivity.

(8) The wavelength and irradiation strength of the optical harmonic modulated UV or/and DUV used in the present invention can be controlled by appropriately selecting the fundamental wave and the non-linear optical crystal, and a combination thereof. For example, a wavelength of 200 to 400 nm at which an amorphous silicon film exhibits high absorption efficiency is arbitrarily selected to enable irradiation with a high-output-single-wavelength laser beam.

(9) Furthermore, the irradiation laser beam can be freely converged and shaped in a linear, rectangular or square shape for laser beam irradiation to decrease variation in the energy distribution of the irradiation plane, variation in the obtained crystallized semiconductor film, and variation in the element properties of each TFT, thereby realizing a decrease in cost with high throughput and high productivity.

(10) For example, when the low-crystalline semiconductor thin film is crystallized by heating with a UV laser beam at a first harmonic generation wavelength of 355 nm and cooling, an infrared laser beam having a fundamental wave at a wavelength of 1064 nm, or a visible light laser beam at a second harmonic wavelength of 532 nm, or a mixed laser beam containing the infrared laser beam and the visible light laser beam can be simultaneously applied to heat the low-crystalline semiconductor thin film and the glass substrate, thereby sufficiently heating the thin film and the substrate. Therefore, slow cooling can be promoted to easily secure crystallization. Also, the fundamental wave and the second harmonic can be efficiently used without being discarded to decrease power consumption as a whole.

(11) Annealing with the optical harmonic modulated UV or/DUV laser can be performed at a low temperature (200 to 400° C.), and thus low-strain-point glass and a high resistant resin can be used to permit an attempt to decrease the weight and cost.

(12) In bottom gate- and dual gate-type MOSTFTs as well as a top gate-type MOSTFT, a polycrystalline or monocrystalline semiconductor film having high carrier mobility can be obtained, permitting the manufacture of a semiconductor device and an electrooptic device having a high speed and high current density, and the manufacture of a solar cell with high efficiency. For example, a silicon semiconductor device, a silicon semiconductor integrated circuit device, a field emission display (FED) device, a silicon-germanium semiconductor device, a silicon-germanium semiconductor integrated circuit device, a liquid crystal display device, an electroluminescence (organic/inorganic) display device, a luminescent polymer display device, a light emitting diode display device, an optical sensor device, a CCD area/linear sensor device, a CMOS sensor device, a solar cell device, etc. can be manufactured.

1. A method of forming a semiconductor thin film in forming a polycrystalline or monocrystalline semiconductor thin film on a substrate, the method comprising the first step of forming a low-crystalline semiconductor thin film on the substrate, and the second step of heating the low-crystalline semiconductor thin film in a molten, semi-molten or non-molten state by laser annealing with ultraviolet rays (UV) or/and deep ultraviolet rays (DUV) and cooling the thin film to promote crystallization of the low-crystalline semiconductor thin film.

2. A method of manufacturing a semiconductor device in manufacturing a semiconductor device comprising a polycrystalline or monocrystalline semiconductor thin film on a substrate, the method comprising the first step of forming a low-crystalline semiconductor thin film on the substrate, and the second step of heating the low-crystalline semiconductor thin film in a molten state, a semi-molten state or non-molten state by laser annealing with ultraviolet rays (UV) or/and deep ultraviolet rays (DUV) and cooling the thin film to promote crystallization of the low-crystalline semiconductor thin film.

3. A method according to claim 1 or 2, comprising repeating the first step and the second step.

4. A method according to claim 1 or 2, wherein a ultraviolet (UV) or/and deep ultraviolet (DUV) laser beam is produced by optical harmonic generation using a nonlinear optical effect and used for laser annealing.

5. A method according to claim 4, wherein a mixture of the laser beam produced by optical harmonic generation with a fundamental wave before optical harmonic generation is used.

6. A method according to claim 4, wherein laser annealing is performed by a zone purification method comprising irradiating the substrate by scanning with the laser beam moved relative to the substrate, or a multi-zone purification method comprising scanning the substrate by scanning with a plurality of laser beams.

7. A method according to claim 6, wherein the laser or the substrate moved while the substrate or the laser is fixed.

8. A method according to claim 4 or 5, wherein the substrate is irradiated with a long-wavelength component of the laser beam before a short-wavelength component or at a position in front of the irradiation position of the short-wavelength component.

9. A method according to claim 1 or 2, wherein a hot gas is blown on the substrate during laser annealing.

10. A method according to claim 1 or 2, wherein an appropriate amount of at least one catalytic element is contained in the low-crystalline semiconductor thin film, and the second step is performed in the state containing the catalytic element.

11. A method according to claim 1 or 2, wherein the low-crystalline semiconductor thin film is changed to a large-grain polycrystalline semiconductor thin film by laser annealing.

12. A method according to claim 1 or 2, comprising forming a stepped recess having a predetermined shape and dimensions in a predetermined element formation region on the substrate, forming the low-crystalline semiconductor thin film containing or not containing at least one catalytic element on the substrate including the recess, and performing graphoepitaxial growth by laser annealing using a bottom corner of the step as a seed to modify the low-crystalline semiconductor thin film to a monocrystalline semiconductor thin film.

13. A method according to claim 1 or 2, comprising forming a material layer having good lattice matching with a monocrystal semiconductor in a predetermined element formation region on the substrate, forming the low-crystalline semiconductor thin film containing or not containing at least one catalytic element on the material layer, and performing hetero epitaxial growth by laser annealing using the material layer as a seed to modify the low-crystalline semiconductor thin film to a monocrystalline semiconductor thin film.

14. A method according to claim 1 or 2, wherein the first step and the second step are continuously or successively performed by an integrated apparatus for at least both steps.

15. A method according to claim 3, comprising treating the polycrystalline semiconductor thin film by plasma discharge with hydrogen or a hydrogen-containing gas or treatment with hydrogen active species produced in catalytic reaction to clean the surface of the polycrystalline semiconductor thin film and/or remove a low-oxidation film before second laser annealing, forming the low-crystalline semiconductor thin film, and then performing laser annealing.

16. A method according to claim 1 or 2, wherein the laser annealing is performed in a low-pressure hydrogen or low-pressure hydrogen-containing gas, or a vacuum.

17. A method according to claim 1 or 2, wherein the substrate is heated to a temperature lower than its strain point during laser annealing.

18. A method according to claim 1 or 2, comprising forming a protecting insulating film on the low-crystalline semiconductor thin film, and then performing laser annealing in the air or atmospheric pressure nitrogen with the protective insulating film formed.

19. A method according to claim 1 or 2, comprising irradiating the low-crystalline semiconductor thin film formed on the substrate or covered with the protective insulating film with a laser beam from the upper surface, the lower surface or simultaneously the upper and lower surfaces during laser annealing by laser beam irradiation (however, the substrate is transparent (transmitting light at a wavelength of 400 nm or less) except in the case of irradiation from the upper surface).

20. A method according to claim 19, wherein comprising islanding the low-crystalline semiconductor thin film or the low-crystalline semiconductor thin film coated with the protective insulating film.

21. A method according to claim 19, wherein laser beam irradiation is performed in atmospheric-pressure nitrogen or the air.

22. A method according to claim 19, wherein laser beam irradiation is performed in a low-pressure hydrogen gas, a low-pressure hydrogen gas-containing gas or a vacuum.

23. A method according to claim 1 or 2, wherein laser annealing is performed under the action of a magnetic field and/or an electric field.

24. A method according to claim 1 or 2, wherein the low-crystalline semiconductor film comprises an amorphous silicon film, a microcrystal silicon-containing amorphous silicon film, a microcrystal silicon (amorphous silicon-containing microcrystal silicon) film, a polycrystalline silicon film containing amorphous silicon and microcrystal silicon, an amorphous germanium film, an amorphous germanium film containing microcrystal germanium, a microcrystal germanium (microcrystal germanium containing amorphous germanium) film, a polycrystalline germanium film containing amorphous germanium and microcrystal germanium, an amorphous silicon germanium film represented by SiₓGe₁₋ₓ (0<x<1), an amorphous carbon film, an amorphous carbon film containing microcrystal carbon, a microcrystal carbon (microcrystal carbon containing amorphous carbon) film, a polycrystalline carbon film containing amorphous carbon and microcrystal carbon, an amorphous silicon carbon film represented by SiₓC₁₋ₓ (0<x<1), or an amorphous gallium arsenic film represented by GaₓAs₁₋ₓ (0<x<1).

25. A method according to claim 1 or 2, wherein the polycrystalline or monocrystalline semiconductor thin film is used for forming channel, source and drain regions of a thin film insulating gate-type field effect transistor, or a diode, wiring, a resistor, a capacitor or an electron emitter.

26. A method according to claim 25, wherein the low-crystalline semiconductor thin film is patterned (islanded) and then annealed with the laser to form channel, source and drain regions of a thin film insulating gate-type field effect transistor, or a diode, wiring, a resistor, a capacitor or an electron emitter.

27. A method according to claim 1 or 2, wherein the thin film is formed for a silicon semiconductor device, a silicon semiconductor integrated circuit device, a silicon-germanium semiconductor device, a silicon-germanium semiconductor integrated circuit device, a compound semiconductor device, a compound semiconductor integrated circuit device, a silicon carbide semiconductor device, a silicon carbide semiconductor integrated circuit device, a polycrystalline diamond semiconductor device, a polycrystalline diamond semiconductor integrated circuit device, a liquid crystal display device, an organic or inorganic electroluminescence (EL) display device, a filed emission display (FED) device, a luminescence polymer display device, a light emitting diode display device, a CCD area/linear sensor device, a CMOS or MOS sensor device, and a solar cell device.

28. A method according to claim 27, wherein the polycrystalline or monocrystalline semiconductor thin film is used for forming channel, source and drain regions of a thin film insulating gate-type field effect transistor constituting at least one of an internal circuit and a peripheral circuit during manufacture of a semiconductor device, an electrooptic display device, or a solid-state image device comprising the circuits.

29. A method according to claim 28, wherein a cathode or anode is formed below an organic or inorganic electroluminescence layer for each color so as to be connected to the drain or source of the thin film insulating gate-type field effect transistor.

30. A method according to claim 29, wherein the cathode covers active elements including the thin film insulating gate-type field effect transistor and the diode, or the cathode or anode is deposited over the entire surface of the organic or inorganic electroluminescence layer for each color and between the layers for respective colors.

31. A method according to claim 29, wherein a black mask layer is formed between the organic or inorganic electroluminescence layers for respective colors.

32. A method according to claim 28, wherein an emitter of a field emission display device comprises a n-type polycrystalline semiconductor film or a polycrystalline diamond film grown on the polycrystalline or monocrystalline semiconductor thin film and connected to the drain of the thin film insulating gate-type field effect transistor through the polycrystalline or monocrystalline semiconductor thin film.

33. A method according to claim 32, wherein a metal shielding film at a ground potential is formed on active elements including the thin film gate-type field effect transistor and the diode through an insulating film.

34. A method according to claim 33, wherein the metal shielding film is formed by the same step using the same material as a gate leading electrode of the field emission display device.

35. An apparatus for forming a polycrystalline or monocrystalline semiconductor thin film on a substrate, the apparatus comprising first means for forming a low-crystalline semiconductor thin film on the substrate, and second means for heating the low-crystalline semiconductor thin film in a molten, semi-molten or non-molten state by laser annealing with ultraviolet rays (UV) or/and deep ultraviolet rays (DUV) and cooling the thin film to promote crystallization of the low-crystalline semiconductor thin film.

36. An apparatus for manufacturing a semiconductor device comprising a polycrystalline or monocrystalline semiconductor thin film on a substrate, the apparatus comprising first means for forming a low-crystalline semiconductor thin film on the substrate, and second means for heating the low-crystalline semiconductor thin film in a molten state, a semi-molten state or non-molten state by laser annealing with ultraviolet rays (UV) or/and deep ultraviolet rays (DUV) and cooling the thin film to promote crystallization of the low-crystalline semiconductor thin film.

37. An apparatus according to claim 35 or 36, wherein the first means and the second means are repeated.

38. An apparatus according to claim 35 or 36, wherein a ultraviolet (UV) or/and deep ultraviolet (DUV) laser beam is produced by optical harmonic generation using a nonlinear optical effect and used for laser annealing.

39. An apparatus according to claim 38, wherein a mixture of the laser beam produced by optical harmonic generation with a fundamental wave before optical harmonic generation is used.

40. An apparatus according to claim 38, wherein laser annealing is performed by a zone purification method comprising irradiating the substrate by scanning with the laser beam moved relative to the substrate, or a multi-zone purification method comprising scanning the substrate by relatively scanning with a plurality of laser beams.

41. An apparatus according to claim 40, wherein the laser or the substrate moved while the substrate or the laser is fixed.

42. An apparatus according to claim 38 or 39, wherein the substrate is irradiated with a long-wavelength component of the laser beam before a short-wavelength component or at a position in front of the irradiation position of the short-wavelength component.

43. An apparatus according to claim 35 or 36, wherein a hot gas is blown on the substrate during the laser annealing.

44. An apparatus according to claim 35 or 36, further comprising means for adding an appropriate amount of at least one catalytic element to the low-crystalline semiconductor thin film.

45. An apparatus according to claim 35 or 36, wherein the first and second means are incorporated in an integrated apparatus for at least both means and continuously or successively used.

46. An apparatus according to claim 37, further comprising means for treating the polycrystalline semiconductor thin film by plasma discharge with hydrogen or a hydrogen-containing gas or treatment with hydrogen active species produced in catalytic reaction to clean the surface of the polycrystalline semiconductor thin film and/or remove a low-oxidation film before second laser annealing.

47. An apparatus according to claim 35 or 36, wherein the laser annealing is performed in a low-pressure hydrogen or low-pressure hydrogen-containing gas, or a vacuum.

48. An apparatus according to claim 35 or 36, wherein the substrate is heated to a temperature lower than its strain point during the laser annealing.

49. An apparatus according to claim 35 or 36, wherein a protective insulating film is formed on the low-crystalline semiconductor thin film, and then the laser annealing is performed in the air or atmospheric pressure nitrogen with the protective insulating film formed.

50. An apparatus according to claim 35 or 36, wherein the low-crystalline semiconductor thin film formed on the substrate or covered with the protective insulating film is irradiated with a laser beam from the upper surface, the lower surface or simultaneously the upper and lower surfaces during laser annealing by laser beam irradiation (however, the substrate is transparent (transmits light at a wavelength of 400 nm or less) except in the case of irradiation from the upper surface).

51. An apparatus according to claim 50, wherein the low-crystalline semiconductor thin film or the low-crystalline semiconductor thin film coated with the protective insulating film is islanded.

52. An apparatus according to claim 50, wherein laser beam irradiation is performed in atmospheric-pressure nitrogen or the air.

53. An apparatus according to claim 50, wherein laser beam irradiation is performed in a low-pressure hydrogen gas, a low-pressure hydrogen gas-containing gas or a vacuum.

54. An apparatus according to claim 35 or 36, wherein the laser annealing is performed under the action of a magnetic field and/or an electric field.

55. An apparatus according to claim 35 or 36, wherein the low-crystalline semiconductor film comprises an amorphous silicon film, a microcrystal silicon-containing amorphous silicon film, a microcrystal silicon (amorphous silicon-containing microcrystal silicon) film, a polycrystalline silicon film containing amorphous silicon and microcrystal silicon, an amorphous germanium film, an amorphous germanium film containing microcrystal germanium, a microcrystal germanium (microcrystal germanium containing amorphous germanium) film, a polycrystalline germanium film containing amorphous germanium and microcrystal germanium, an amorphous silicon germanium film represented by SiₓGe₁₋ₓ (0<x<1), an amorphous carbon film, an amorphous carbon film containing microcrystal carbon, a microcrystal carbon (microcrystal carbon containing amorphous carbon) film, a polycrystalline carbon film containing amorphous carbon and microcrystal carbon, an amorphous silicon carbon film represented by SiₓC₁₋ₓ (0<x<1), or an amorphous gallium arsenic film represented by GaₓAs₁₋ₓ (0<x<1).

56. An apparatus according to claim 35 or 36, wherein the polycrystalline or monocrystalline semiconductor thin film is used for forming channel, source and drain regions of a thin film insulating gate-type field effect transistor, or a diode, wiring, a resistor, a capacitor or an electron emitter.

57. An apparatus according to claim 56, wherein the low-crystalline semiconductor thin film is patterned (islanded) and then annealed with the laser to form channel, source and drain regions of a thin film insulating gate-type field effect transistor, or a diode, wiring, a resistor, a capacitor or an electron emitter.

58. An apparatus according to claim 35 or 36, wherein the thin film is formed for a silicon semiconductor device, a silicon semiconductor integrated circuit device, a silicon-germanium semiconductor device, a silicon-germanium semiconductor integrated circuit device, a compound semiconductor device, a compound semiconductor integrated circuit device, a silicon carbide semiconductor device, a silicon carbide semiconductor integrated circuit device, a polycrystalline diamond semiconductor device, a polycrystalline diamond semiconductor integrated circuit device, a liquid crystal display device, an organic or inorganic electroluminescence (EL) display device, a filed emission display (FED) device, a luminescence polymer display device, a light emitting diode display device, a CCD area/linear sensor device, a CMOS or MOS sensor device, and a solar cell device.

59. An apparatus according to claim 58, wherein the polycrystalline or monocrystalline semiconductor thin film is used for forming channel, source and drain regions of a thin film insulating gate-type field effect transistor constituting at least one of an internal circuit and a peripheral circuit during manufacture of a semiconductor device, an electrooptic display device, or a solid-state image device comprising the circuits.

60. An apparatus according to claim 59, wherein a device comprising a cathode or anode which is formed below an organic or inorganic electroluminescence layer for each color so as to be connected to the drain or source of the thin film insulating gate-type field effect transistor is manufactured.

61. An apparatus according to claim 60, wherein a device comprising the cathode covering active elements including the thin film insulating gate-type field effect transistor and the diode, or the cathode or anode deposited over the entire surface of the organic or inorganic electroluminescence layer for each color and between the layers for respective colors is manufactured.

62. An apparatus according to claim 60, wherein a black mask layer is formed between the organic or inorganic electroluminescence layers for respective colors.

63. An apparatus according to claim 59, wherein an emitter of the field emission display device comprises a n-type polycrystalline semiconductor film or a polycrystalline diamond film grown on the polycrystalline or monocrystalline semiconductor thin film and connected to the drain of the thin film insulating gate-type field effect transistor through the polycrystalline or monocrystalline semiconductor thin film.

64. An apparatus according to claim 63, wherein a metal shielding film at a grounding potential is formed on active elements including the thin film gate-type field effect transistor and the diode through an insulating film.

65. An apparatus according to claim 64, wherein the metal shielding film is formed by the same step using the same material as a gate leading electrode of the field emission display device.

66. An electrooptic device comprising a cathode or anode provided below an organic or inorganic electroluminescence layer for each color to be connected to the drain or source of a thin film gate-type field effect transistor comprising the polycrystalline or monocrystalline semiconductor thin film according to claim 1 or 2, wherein the cathode covers active elements including the thin film gate-type field effect transistor and a diode, or the cathode or anode adheres to the whole surface of the organic or inorganic electroluminescence layer for each color and between the respective electroluminescence layers.

67. An electrooptic device according to claim 66, wherein a black mask is formed between the organic or inorganic electroluminescence layers for respective colors.

68. An electrooptic device comprising a field emission display (FED) having an emitter which comprises a n-type polycrystalline semiconductor film or polycrystalline diamond film connected to the drain of a thin film gate-type field effect transistor comprising the polycrystalline or monocrystalline semiconductor thin film according to claim 1 or 2 through the polycrystalline or monocrystalline semiconductor thin film, and grown on the polycrystalline or monocrystalline semiconductor thin film.

69. An electrooptic device according to claim 68, wherein a metal shielding film at a grounding potential is formed on active elements including the thin film gate-type field effect transistor and a diode through an insulating film.

70. An electrooptic device according to claim 69, wherein the metal shielding film is formed in the same step using the same material as a gate leading electrode of the thin film gate-type field emission display device.
